(19) United States
(12) Patent Application Publication
(10) Pub. No.: US 2023/0246048 A1
(43) Pub. Date: Aug. 3, 2023

(54) IMAGING ELEMENT

(71) Applicant: SONY SEMICONDUCTOR SOLUTIONS CORPORATION, KANAGAWA (JP)

(72) Inventors: TAKETO FUKURO, KUMAMOTO (JP); SHINICHIRO NOUDO, KUMAMOTO (JP); YUMA ONO, KUMAMOTO (JP); YOHEI CHIBA, KUMAMOTO (JP)

(21) Appl. No.: 17/999,873

(22) PCT Filed: Apr. 22, 2021
(86) PCT No.: PCT/JP2021/016274

§ 371 Date: Nov. 25, 2022

(30) Foreign Application Priority Data
Jun. 8, 2020 (JP) 2020-099706

(51) Int. Cl. H01L 27/146

(52) U.S. Cl. CPC H01L 27/14623; H01L 27/14645; H01L 27/14636; H01L 27/1464; H01L 27/14685

(57) ABSTRACT

Incident light transmitted through a semiconductor substrate is shielded at a boundary between pixels.

An imaging element is provided with a pixel, a front surface side light shielding unit, and a back surface side light shielding unit. The pixel is provided with a photoelectric conversion unit that is arranged in a semiconductor substrate on a front surface side of which a wiring region is formed and performs photoelectric conversion of incident light applied from a back surface side of the semiconductor substrate. The front surface side light shielding unit is embedded on the front surface side of the semiconductor substrate at the boundary between the pixels to shield the incident light. The back surface side light shielding unit is embedded on the back surface side of the semiconductor substrate at the boundary between the pixels and is formed to have such a depth that a bottom thereof is arranged between the front surface side of the semiconductor substrate and a bottom of the front surface side light shielding unit to shield the incident light.

### TECHNICAL FIELD

The present disclosure relates to an imaging element. Specifically, this relates to an imaging element in which a light shielding unit that shields incident light is arranged at a boundary between a plurality of pixels.

### BACKGROUND ART

Conventionally, an imaging element in which pixels each including a photoelectric conversion unit formed in a semiconductor substrate are arranged in a two-dimensional lattice shape is used. Among these imaging elements, a back-illuminated imaging element, which is an imaging element that images incident light applied on a back surface side of the semiconductor substrate may obtain high conversion efficiency as compared with that of a front-illuminated imaging element that images incident light applied on a front surface side of the semiconductor substrate. This is because the incident light may be incident on the semiconductor substrate without intervention of a wiring region arranged on the front surface side of the semiconductor substrate. In such back-illuminated imaging element, an imaging element in which a light shielding unit that shields the incident light obliquely incident from an adjacent pixel is arranged in the semiconductor substrate at a boundary between the pixels is used. By shielding the incident light from the adjacent pixel, it is possible to reduce occurrence of crosstalk. Here, the crosstalk is a phenomenon that an image signal output from a pixel is affected by optical noise such as the incident light from the adjacent pixel. When the crosstalk occurs, noise is mixed in the image signal, and an image quality is deteriorated.

As the imaging element including the light shielding unit, for example, an imaging element provided with a light shielding unit obtained by embedding metal in a vertical groove formed in a semiconductor substrate at a boundary between pixels has been proposed (refer to, for example, Patent Document 1).

### CITATION LIST

### Patent Document

Patent Document 1: Japanese Patent Application Laid-Open No. 2015-228510

### SUMMARY OF THE INVENTION

### Problems to be Solved by the Invention

The above-described conventional technology has a problem that shielding of the incident light transmitted through the semiconductor substrate is not sufficient. In the imaging element of the above-described conventional technology, it is not possible to shield incident light reflected by an insulating film and the like on a front surface side of the semiconductor substrate, and there is a problem that crosstalk occurs in an adjacent pixel.

The present disclosure is achieved in view of the above-described problem, and an object thereof is to shield the incident light transmitted through the semiconductor substrate at the boundary between the pixels.

### Solutions to Problems

The present disclosure is achieved for solving the above-described problem, and a first aspect thereof is an imaging element provided with a pixel provided with a photoelectric conversion unit that is arranged in a semiconductor substrate on a front surface side of which a wiring region is formed and performs photoelectric conversion of incident light applied from a back surface side of the semiconductor substrate, a front surface side light shielding unit that is embedded on the front surface side of the semiconductor substrate at a boundary between pixels and shields the incident light, and a back surface side light shielding unit that is embedded on the back surface side of the semiconductor substrate at the boundary between the pixels and is formed to have such a depth that a bottom of the back surface side light shielding unit is arranged between the front surface side of the semiconductor substrate and a bottom of the front surface side light shielding unit to shield the incident light.

Furthermore, in the first aspect, the front surface side light shielding unit may be formed by arranging a light shielding member in a front surface side groove, which is a groove formed on the front surface side of the semiconductor substrate.

Furthermore, in the first aspect, the light shielding member may include metal.

Furthermore, in the first aspect, an insulating film arranged between the front surface side groove and the light shielding member may be further included.

Furthermore, in the first aspect, an insulating film including a silicon compound arranged on the front surface side of the semiconductor substrate may be further included, and the groove may be formed to penetrate the insulating film.

Furthermore, in the first aspect, the back surface side light shielding unit may be formed into a shape to penetrate the semiconductor substrate.

Furthermore, in the first aspect, the back surface side light shielding unit may be formed by arranging a light shielding member in a back surface side groove, which is a groove formed on the back surface side of the semiconductor substrate.

Furthermore, in the first aspect, the light shielding member may include metal.

Furthermore, in the first aspect, an insulating film arranged between the back surface side groove and the light shielding member may be further included.

Furthermore, in the first aspect, the back surface side groove may be formed by performing wet etching on the back surface side of the semiconductor substrate.

Furthermore, in the first aspect, the back surface side groove may be formed by etching a filling member arranged to penetrate the semiconductor substrate from the back surface side.

Furthermore, in the first aspect, the filling member may include polycrystalline silicon.

Furthermore, in the first aspect, the back surface side light shielding unit may be formed to have a wider cross-sectional width at the bottom than a cross-sectional width at the bottom of the front surface side light shielding unit.

Furthermore, in the first aspect, the back surface side light shielding unit may include a groove-shaped recess at the bottom, and the front surface side light shielding unit may be formed to have a shape in which the bottom of the front surface side light shielding unit is fitted into the recess.

Furthermore, in the first aspect, two front surface side light shielding units may be included, and the back surface side light shielding unit may be arranged between the two front surface side light shielding units.

Furthermore, in the first aspect, a holding unit that holds a charge generated by the photoelectric conversion, an in-pixel front surface side light shielding unit that is embedded on the front surface side of the semiconductor substrate at a boundary between the photoelectric conversion unit and the holding unit and shields the incident light, and an in-pixel back surface side light shielding unit that is embedded on the back surface side of the semiconductor substrate at the boundary between the photoelectric conversion unit and the holding unit and is formed to have such a depth that a bottom of the in-pixel back surface side light shielding unit is arranged between the front surface side of the semiconductor substrate and a bottom of the in-pixel front surface side light shielding unit to shield the incident light may be further included.

Furthermore, a second aspect of the present disclosure is an imaging element provided with a pixel provided with a photoelectric conversion unit that is arranged in a semiconductor substrate on a front surface side of which a wiring region is formed and performs photoelectric conversion of incident light applied from a back surface side of the semiconductor substrate, a front surface side light shielding unit that is embedded on the front surface side of the semiconductor substrate at a boundary between pixels and shields the incident light, and a back surface side light shielding unit that is embedded on the back surface side of the semiconductor substrate at the boundary between the pixels and is formed to have a depth in contact with a bottom of the front surface side light shielding unit to shield the incident light.

Furthermore, in the second aspect, the back surface side light shielding unit may be in contact with the bottom of the front surface side light shielding unit via an insulating film.

Furthermore, a third aspect of the present disclosure is an imaging element provided with a pixel provided with a photoelectric conversion unit that is arranged in a semiconductor substrate on a front surface side of which a wiring region is formed and performs photoelectric conversion of incident light applied from a back surface side of the semiconductor substrate; a front surface insulating film, which is an insulating film arranged between the semiconductor substrate and the wiring region, a front surface insulating film light shielding unit that is arranged on the front surface insulating film at a boundary between pixels and shields the incident light, and a semiconductor substrate light shielding unit that is formed into a shape to penetrate the semiconductor substrate at the boundary between the pixels and in contact with a bottom of the front surface insulating film light shielding unit to shield the incident light.

Furthermore, in the third aspect, a lower layer insulating film, which is an insulating film arranged between the semiconductor substrate and the front surface insulating film may be further provided, and the semiconductor substrate light shielding unit may be provided with a first semiconductor substrate light shielding unit arranged in a penetrating groove formed in the semiconductor substrate, and a second semiconductor substrate light shielding unit arranged in a lower layer insulating film removed region formed by removing the lower layer insulating film in a vicinity of a bottom of the penetrating groove.

Furthermore, in the third aspect, the first semiconductor substrate light shielding unit may be obtained by arranging a light shielding member in the penetrating groove, and the second semiconductor substrate light shielding unit may be obtained by arranging a light shielding member in the lower layer insulating film removed region.

Furthermore, in the third aspect, the lower layer insulating film removed region may be formed by removing the lower layer insulating film by etching via the penetrating groove.

Furthermore, in the third aspect, an etching suppression unit that is arranged on the lower layer insulating film and suppresses the etching may be further provided.

Furthermore, in the third aspect, the etching suppression unit may include a same member as a member of the front surface insulating film.

Furthermore, in the third aspect, the lower layer insulating film may include polycrystalline silicon.

Furthermore, in the third aspect, the second semiconductor substrate light shielding unit may be formed to have a wider cross-sectional width than a cross-sectional width of the penetrating groove.

Furthermore, in the third aspect, an insulating film arranged between the penetrating groove and the light shielding member may be further included.

Furthermore, in the third aspect, the second semiconductor substrate light shielding unit may be formed to have a wider cross-sectional width than a cross-sectional width of the penetrating groove, and the insulating film may be formed into such a shape that a bottom of the insulating film is fitted into a recess formed in the second semiconductor substrate light shielding unit.

Furthermore, in the third aspect, a holding unit that holds a charge generated by the photoelectric conversion, an in-pixel front surface insulating film light shielding unit that is arranged on the front surface insulating film at a boundary between the photoelectric conversion unit and the holding unit and shields the incident light, and an in-pixel semiconductor substrate light shielding unit that is formed into a shape to penetrate the semiconductor substrate at the boundary between the photoelectric conversion unit and the holding unit and in contact with a bottom of the in-pixel front surface insulating film light shielding unit to shield the incident light may be further provided.

Furthermore, in the third aspect, the in-pixel semiconductor substrate light shielding unit may be formed to have a cross section narrower in width than a cross section of the semiconductor light shielding unit.

The aspects of the present disclosure brings about an effect that the light shielding unit is arranged in the semiconductor substrate at the boundary between the pixels and the insulating film on the front surface side of the semiconductor substrate.

### BRIEF DESCRIPTION OF DRAWINGS

FIG. 1 is a block diagram illustrating a configuration example of an imaging element according to an embodiment of the present disclosure.

FIG. 2 is a diagram illustrating a configuration example of a pixel according to a first embodiment of the present disclosure.

FIG. 3 is a cross-sectional view illustrating a configuration example of the pixel according to the first embodiment of the present disclosure.

FIG. 4 is a cross-sectional view illustrating a configuration example of a light shielding unit according to the first embodiment of the present disclosure.

FIG. 5 is a diagram illustrating an example of a manufacturing method of the imaging element according to the first embodiment of the present disclosure.

FIG. 6 is a diagram illustrating an example of the manufacturing method of the imaging element according to the first embodiment of the present disclosure.

FIG. 7 is a diagram illustrating an example of the manufacturing method of the imaging element according to the first embodiment of the present disclosure.

FIG. 8 is a diagram illustrating an example of the manufacturing method of the imaging element according to the first embodiment of the present disclosure.

FIG. 9 is a diagram illustrating an example of the manufacturing method of the imaging element according to the first embodiment of the present disclosure.

FIG. 10 is a cross-sectional view illustrating a configuration example of a light shielding unit according to a second embodiment of the present disclosure.

FIG. 11 is a cross-sectional view illustrating another configuration example of the light shielding unit according to the second embodiment of the present disclosure.

FIG. 12 is a cross-sectional view illustrating a configuration example of a pixel according to a third embodiment of the present disclosure.

FIG. 13 is a diagram illustrating an example of a manufacturing method of the imaging element according to the third embodiment of the present disclosure.

FIG. 14 is a diagram illustrating an example of the manufacturing method of the imaging element according to the third embodiment of the present disclosure.

FIG. 15 is a diagram illustrating an example of the manufacturing method of the imaging element according to the third embodiment of the present disclosure.

FIG. 16 is a diagram illustrating an example of the manufacturing method of the imaging element according to the third embodiment of the present disclosure.

FIG. 17 is a diagram illustrating an example of the manufacturing method of the imaging element according to the third embodiment of the present disclosure.

FIG. 18 is a cross-sectional view illustrating a configuration example of a light shielding unit according to a fourth embodiment of the present disclosure.

FIG. 19 is a diagram illustrating a configuration example of a pixel according to a fifth embodiment of the present disclosure.

FIG. 20 is a plane view illustrating a configuration example of the pixel according to the fifth embodiment of the present disclosure.

FIG. 21 is a cross-sectional view illustrating a configuration example of the pixel according to the fifth embodiment of the present disclosure.

FIG. 22 is a diagram illustrating an example of a manufacturing method of an imaging element according to the fifth embodiment of the present disclosure.

FIG. 23 is a diagram illustrating an example of the manufacturing method of the imaging element according to the fifth embodiment of the present disclosure.

FIG. 24 is a diagram illustrating an example of the manufacturing method of the imaging element according to the fifth embodiment of the present disclosure.

FIG. 25 is a cross-sectional view illustrating a configuration example of a light shielding unit according to a sixth embodiment of the present disclosure.

FIG. 26 is a cross-sectional view illustrating a configuration example of the light shielding unit according to a seventh embodiment of the present disclosure.

FIG. 27 is a cross-sectional view illustrating a configuration example of a pixel according to an eighth embodiment of the present disclosure.

FIG. 28 is a cross-sectional view illustrating a configuration example of a pixel according to a ninth embodiment of the present disclosure.

FIG. 29 is a cross-sectional view illustrating a configuration example of a light shielding unit according to the ninth embodiment of the present disclosure.

FIG. 30 is a cross-sectional view illustrating an example of light shielding according to the ninth embodiment of the present disclosure.

FIG. 31 is a diagram illustrating an example of the manufacturing method of the imaging element according to the ninth embodiment of the present disclosure.

FIG. 32 is a diagram illustrating an example of the manufacturing method of the imaging element according to the ninth embodiment of the present disclosure.

FIG. 33 is a diagram illustrating an example of the manufacturing method of the imaging element according to the ninth embodiment of the present disclosure.

FIG. 34 is a diagram illustrating an example of the manufacturing method of the imaging element according to the ninth embodiment of the present disclosure.

FIG. 35 is a diagram illustrating an example of the manufacturing method of the imaging element according to the ninth embodiment of the present disclosure.

FIG. 36 is a diagram illustrating an example of the manufacturing method of the imaging element according to the ninth embodiment of the present disclosure.

FIG. 37 is a cross-sectional view illustrating a configuration example of a light shielding unit according to a tenth embodiment of the present disclosure.

FIG. 38 is a diagram illustrating an example of the manufacturing method of the imaging element according to the tenth embodiment of the present disclosure.

FIG. 39 is a diagram illustrating an example of the manufacturing method of the imaging element according to the tenth embodiment of the present disclosure.

FIG. 40 is a diagram illustrating an example of the manufacturing method of the imaging element according to the tenth embodiment of the present disclosure.

FIG. 41 is a plane view illustrating a configuration example of a pixel according to an eleventh embodiment of the present disclosure.

FIG. 42 is a cross-sectional view illustrating a configuration example of the pixel according to the eleventh embodiment of the present disclosure.

FIG. 43 is a diagram illustrating an example of the manufacturing method of the imaging element according to the eleventh embodiment of the present disclosure.

FIG. 44 is a diagram illustrating an example of the manufacturing method of the imaging element according to the eleventh embodiment of the present disclosure.

FIG. 45 is a diagram illustrating an example of the manufacturing method of the imaging element according to the eleventh embodiment of the present disclosure.

FIG. 46 is a diagram illustrating an example of the manufacturing method of the imaging element according to the eleventh embodiment of the present disclosure.

FIG. 47 is a diagram illustrating an example of the manufacturing method of the imaging element according to the eleventh embodiment of the present disclosure.

FIG. 48 is a cross-sectional view illustrating a configuration example of a pixel according to a twelfth embodiment of the present disclosure.

FIG. 49 is a diagram illustrating an example of a manufacturing method of an imaging element according to the twelfth embodiment of the present disclosure.

FIG. 50 is a diagram illustrating an example of the manufacturing method of the imaging element according to the twelfth embodiment of the present disclosure.

FIG. 51 is a block diagram illustrating a schematic configuration example of a camera, which is an example of an imaging device to which the present technology may be applied.

### MODE FOR CARRYING OUT THE INVENTION

Next, modes for carrying out the present disclosure (hereinafter, referred to as embodiments) are described with reference to the drawings. In the following drawings, the same or similar parts are assigned with the same or similar reference signs. Furthermore, the embodiments are described in the following order.

1. First Embodiment

2. Second Embodiment

3. Third Embodiment

4. Fourth Embodiment

5. Fifth Embodiment

6. Sixth Embodiment

7. Seventh Embodiment

8. Eighth Embodiment

9. Ninth Embodiment

10. Tenth Embodiment

11. Eleventh Embodiment

12. Twelfth Embodiment

13. Application Example to Camera

### 1. First Embodiment

[Configuration of Imaging Element]

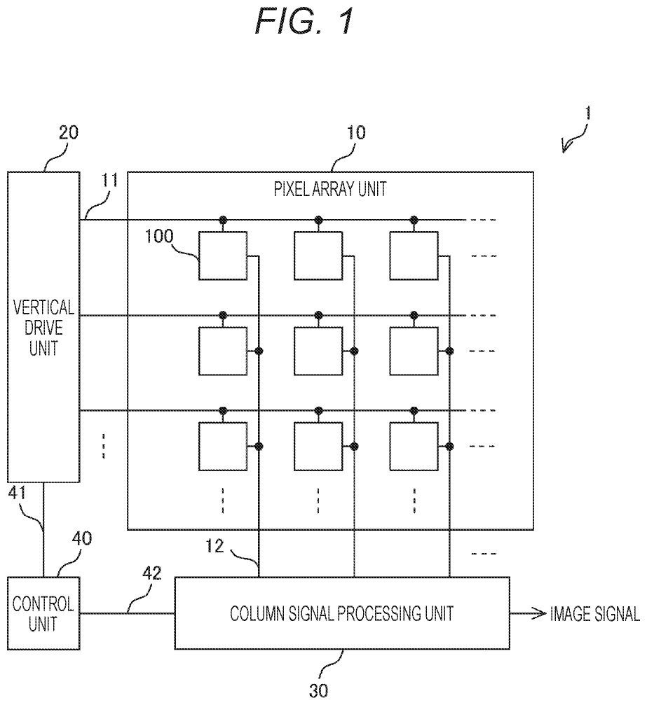

FIG. 1 is a block diagram illustrating a configuration example of an imaging element according to an embodiment of the present disclosure. An imaging element 1 in the drawing is provided with a pixel array unit 10, a vertical drive unit 20, a column signal processing unit 30, and a control unit 40.

The pixel array unit 10 is obtained by arranging pixels 100 in a two-dimensional lattice pattern. Here, the pixel 100 generates an image signal according to applied light. The pixel 100 includes a photoelectric conversion unit that generates a charge according to the applied light. Furthermore, the pixel 100 further includes a pixel circuit. The pixel circuit generates the image signal based on the charge generated by the photoelectric conversion unit. Generation of the image signal is controlled by a control signal generated by the vertical drive unit 20 to be described later. In the pixel array unit 10, signal lines 11 and 12 are arranged in an XY matrix pattern. The signal line 11, which is a signal line that transmits the control signal of the pixel circuit in the pixel 100, is arranged for each row of the pixel array unit 10 and is commonly wired to the pixels 100 arranged in each row. The signal line 12, which is a signal line that transmits the image signal generated by the pixel circuit of the pixel 100, is arranged for each column of the pixel array unit 10 and is commonly wired to the pixels 100 arranged in each column. The photoelectric conversion unit and the pixel circuit are formed in a semiconductor substrate.

The vertical drive unit 20 generates the control signal of the pixel circuit of the pixel 100. The vertical drive unit 20 transmits the generated control signal to the pixel 100 via the signal line 11 in the drawing. The column signal processing unit 30 processes the image signal generated by the pixel 100. The column signal processing unit 30 processes the image signal transmitted from the pixel 100 via the signal line 12 in the drawing. The processing by the column signal processing unit 30 corresponds to, for example, analog-digital conversion to convert an analog image signal generated by the pixel 100 into a digital image signal. The image signal processed by the column signal processing unit 30 is output as the image signal of the imaging element 1. The control unit 40 controls an entire imaging element 1. The control unit 40 controls the imaging element 1 by generating and outputting the control signal that controls the vertical drive unit 20 and the column signal processing unit 30. The control signal generated by the control unit 40 is transmitted to the vertical drive unit 20 and the column signal processing unit 30 via signal lines 41 and 42, respectively. Note that, the column signal processing unit 30 is an example of a processing circuit.

[Circuit Configuration of Pixel]

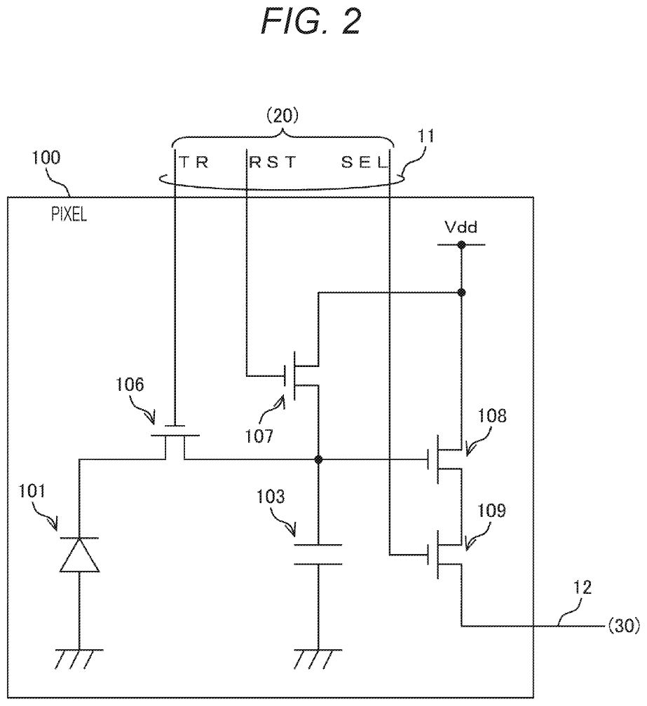

FIG. 2 is a diagram illustrating a configuration example of the pixel according to a first embodiment of the present disclosure. The drawing is a circuit diagram illustrating a configuration example of the pixel 100. The pixel 100 in the drawing is provided with a photoelectric conversion unit 101, a charge holding unit 103, and MOS transistors 106 to 109.

An anode of the photoelectric conversion unit 101 is grounded, and a cathode thereof is connected to a source of the MOS transistor 106. A drain of the MOS transistor 106 is connected to a source of the MOS transistor 107, a gate of the MOS transistor 108, and one end of the charge holding unit 103. The other end of the charge holding unit 103 is grounded. Drains of the MOS transistors 107 and 108 are connected to a power supply line Vdd in common, and a source of the MOS transistor 108 is connected to a drain of the MOS transistor 109. A source of the MOS transistor 109 is connected to the signal line 12. Gates of the MOS transistors 106, 107, and 109 are connected to a signal line TR, a signal line RST, and a signal line SEL, respectively. Note that, the signal line TR, the signal line RST, and the signal line SEL form the signal line 11.

The photoelectric conversion unit 101 generates the charge according to the applied light as described above. A photodiode may be used as the photoelectric conversion unit 101.

The MOS transistor 106 is a transistor that transfers the charge generated by photoelectric conversion of the photoelectric conversion unit 101 to the charge holding unit 103. The transfer of the charge by the MOS transistor 106 is controlled by a signal transmitted by the signal line TR. The charge holding unit 103 is a capacitor that holds the charge transferred by the MOS transistor 106. The MOS transistor 108 is a transistor that generates a signal based on the charge held by the charge holding unit 103. The MOS transistor 109 is a transistor that outputs a signal generated by the MOS transistor 108 to the signal line 12 as the image signal. The MOS transistor 109 is controlled by a signal transmitted by the signal line SEL.

The MOS transistor 107 is a MOS transistor that resets the charge holding unit 103 by discharging the charge held by the charge holding unit 103 to the power supply line Vdd. The reset by the MOS transistor 107 is controlled by a signal transmitted by the reset signal line RST, and is executed before the transfer of the charge by the MOS transistor 106. Note that, at the time of the reset, it is possible to also reset the photoelectric conversion unit 101 by bringing the MOS transistor 106 into conduction.

Imaging by the pixel 100 in the drawing may be performed as follows. First, the MOS transistors 106 and 107 are brought into conduction to reset the photoelectric conversion unit 101. After a predetermined exposure period elapses, the MOS transistor 107 is brought into conduction again to reset the charge holding unit 103. After the reset of the charge holding unit 103 is finished, the MOS transistor 106 is brought into conduction to transfer the charge generated by the photoelectric conversion unit 101 to the charge holding unit 103. Thereafter, the image signal is generated by the MOS transistor 108 on the basis of the charge transferred to and held by the charge holding unit 103, and is output to the signal line 12 by the MOS transistor 109.

By sequentially executing the exposure by the photoelectric conversion unit 101 and the output of the image signal after the exposure while shifting time for the pixels 100 arranged in each row of the pixel array unit 10, the image signal for one screen (frame) may be generated. Such an imaging method is referred to as a rolling shutter. By applying this imaging method, the configuration of the pixel 100 may be simplified. However, in the rolling shutter type imaging, imaging time for each row is shifted, distortion occurs in the frame when imaging a moving subject.

[Configuration of Pixel]

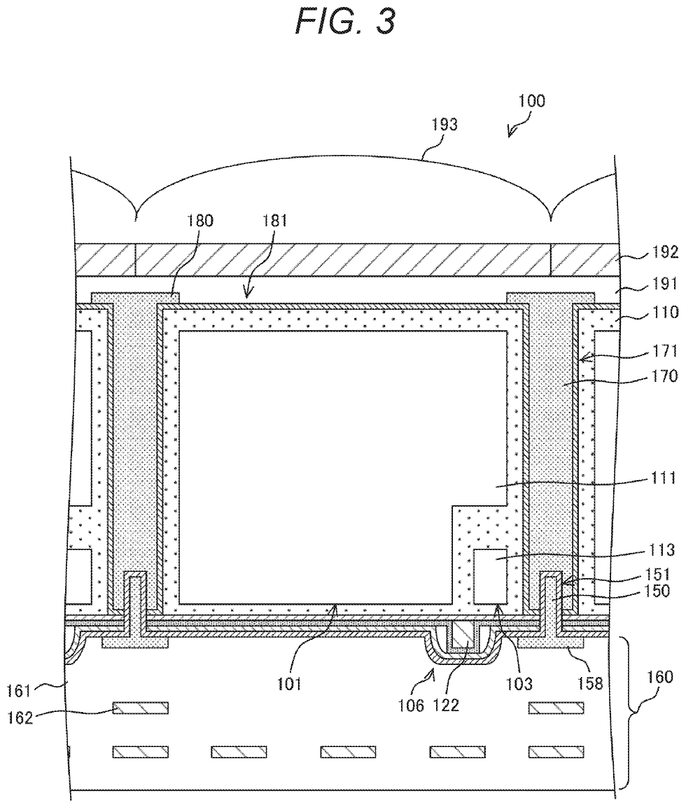

FIG. 3 is a cross-sectional view illustrating a configuration example of the pixel according to the first embodiment of the present disclosure. The drawing is a schematic cross-sectional view illustrating the configuration example of the pixel 100 according to the first embodiment of the present disclosure. The pixel 100 in the drawing is provided with a semiconductor substrate 110, a wiring region 160, light shielding films 158 and 180, a flattening film 191, a color filter 192, and an on-chip lens 193. Furthermore, a front surface side light shielding unit 150 and a back surface side light shielding unit 170 are arranged at a boundary between the pixels 100.

The semiconductor substrate 110 is a semiconductor substrate in which a semiconductor portion (diffusion layer) of the element arranged in the pixel 100 is formed as described above. The semiconductor substrate 110 may include, for example, silicon (Si). The semiconductor portion of the element is arranged in a well region formed in the semiconductor substrate 110. For convenience, the semiconductor substrate 110 in the drawing is assumed to be formed in a p-type well region. By arranging an n-type semiconductor region in the p-type well region, the semiconductor portion of the element may be formed. In the drawing, the photoelectric conversion unit 101, the MOS transistor 106, and the charge holding unit 103 are illustrated.

The photoelectric conversion unit 101 includes an n-type semiconductor region 111 in the drawing. Specifically, a photodiode formed by pn junction between the n-type semiconductor region 111 and the p-type well region around the same corresponds to the photoelectric conversion unit 101. Incident light incident from the back surface side of the semiconductor substrate 110 is photoelectrically converted in the n-type semiconductor region 111. An electron out of the charge generated by the photoelectric conversion is accumulated in the n-type semiconductor region 111 during the exposure period.

The charge holding unit 103 includes an n-type semiconductor region 113 in the drawing. The electrons accumulated in the n-type semiconductor region 111 during the exposure period are transferred to and held by the n-type semiconductor region 113 after a lapse of the exposure period. Furthermore, a gate 122 is arranged on a front surface side of the semiconductor substrate 110 in the vicinity of the semiconductor region 113. The gate 122 forms the gate of the MOS transistor 106 described above. Furthermore, the semiconductor regions 111 and 113 correspond to the source region and the drain region of the MOS transistor 106, respectively. The MOS transistor 106 is brought into conduction, so that the charges accumulated in the photoelectric conversion unit 101 may be transferred to the charge holding unit 103.

Note that, a p-type semiconductor region formed to have a relatively high impurity concentration may be formed on a front side surface of the semiconductor substrate 110. By arranging the semiconductor region, a surface level on the front surface side of the semiconductor substrate 110 may be pinned.

The gate 122 in the drawing may include, for example, polycrystalline silicon. Note that, an insulating film (an insulating film 131 to be described later) forming a gate insulating film is arranged between the gate 122 and the semiconductor substrate 110. Furthermore, an insulating film 132 and an insulating film 134 to be described later are stacked between the gate 122 and the wiring region 160.

The wiring region 160 is arranged on the front surface side of the semiconductor substrate 110 and includes a wiring layer 162 and an insulating layer 161. The wiring layer 162 is wiring that transmits an electric signal of an element such as the pixel 100. The wiring layer 162 may include, for example, copper (Cu). The insulating layer 161 insulates the wiring layer 162. The insulating layer 161 may include, for example, silicon oxide (SiO₂). The insulating layer 161 and the wiring layer 162 may have a multi-layer configuration. The drawing illustrates an example of the insulating layer 161 and the wiring layer 162 formed in two layers.

The light shielding film 158 is a light shielding film arranged between the semiconductor substrate 110 and the wiring region 160. The light shielding film 158 shields the incident light transmitted through the semiconductor substrate 110 to be incident on the wiring region 160. The light incident on the wiring region 160 is reflected by the wiring layer 162 and the like to be reflected light. When the reflected light is incident on the adjacent pixel 100, this causes noise. By arranging the light shielding film 158, generation of the reflected light may be reduced. The light shielding film 158 in the drawing illustrates an example of being arranged in the vicinity of the boundary between the pixels 100. The light shielding film 158 may include metal such as aluminum (Al), silver (Ag), gold (Au), Cu, platinum (Pt), molybdenum (Mo), chromium (Cr), titanium (Ti), nickel (Ni), tungsten (W), iron (Fe), Si, germanium (Ge), and tellurium (Te). Furthermore, an alloy containing these metals or a stacked film of these metals may also be used. Note that, the configuration of the light shielding film 158 is not limited to this example. For example, this may have a shape extended to a region where the gate 122 and the photoelectric conversion unit 101 are arranged.

The light shielding film 180 is a light shielding film that shields the back surface side of the semiconductor substrate 110 from light. The light shielding film 180 shields the incident light obliquely incident from the adjacent pixel 100. An opening 181 is arranged on the light shielding film 180. The photoelectric conversion unit 101 is irradiated with the incident light through the opening 181. The light shielding film 180 may include a metal material similar to that of the light shielding film 158.

The flattening film 191 is a film that flattens the back surface side of the semiconductor substrate 110. The flattening film 191 may include, for example, SiO₂.

The color filter 192 is an optical filter that transmits incident light of a predetermined wavelength out of the incident light. As the color filter 192, the color filter 192 that transmits any of red light, green light, and blue light may be arranged for each pixel 100. Furthermore, in addition to these color filters 192 of primary colors, the color filter 192 of a complementary color that transmits any of cyan light, yellow light, and magenta light may also be used. Furthermore, the color filter 192 that transmits infrared light may also be used.

The on-chip lens 193 is a lens that condenses the incident light. The on-chip lens 193 is formed into a hemispherical shape and arranged for each pixel 100 to condense the incident light in the semiconductor region 111 of the photoelectric conversion unit 101. The on-chip lens 193 may include an organic material such as a styrene resin, an acrylic resin, a styrene-acrylic resin, and a siloxane resin, for example. Furthermore, this may also include an inorganic material such as silicon nitride (SiN) and silicon oxynitride (SiON). Furthermore, titanium oxide (TiO) particles may be dispersed in the above-described organic material or polyimide-based resin.

The front surface side light shielding unit 150 is embedded on the front surface side of the semiconductor substrate 110 at the boundary between the pixels 100 to shield the incident light. The front surface side light shielding unit 150 may be formed by arranging a light shielding member in a front surface side groove 151, which is a groove formed on the front surface side of the semiconductor substrate 110. The light shielding member may include a metal material similar to that of the light shielding film 158 described above. Furthermore, the front surface side light shielding unit 150 may be coupled to the light shielding film 158. Therefore, it is possible to further reduce leakage of the incident light to the adjacent pixel 100 in the vicinity of the wiring region 160 at the boundary between the pixels 100. In this case, by forming the front surface side light shielding unit 150 using the same material as that of the light shielding film 158, the front surface side light shielding unit 150 and the light shielding film 158 may be simultaneously formed. Hereinafter, the front surface side light shielding unit 150 and the light shielding film 158 including W are assumed.

The back surface side light shielding unit 170 is embedded on the back surface side of the semiconductor substrate 110 at the boundary between the pixels 100 to shield the incident light. The back surface side light shielding unit 170 may be formed to have such a depth that a bottom thereof is arranged between the front surface side of the semiconductor substrate 110 and a bottom of the front surface side light shielding unit 150. The back surface side light shielding unit 170 may be formed by arranging a light shielding member in a back surface side groove 171, which is a groove formed on the back surface side of the semiconductor substrate 110. The light shielding member of the back surface side light shielding unit 170 may include a metal material similar to that of the light shielding film 158 described above. Furthermore, the back surface side light shielding unit 170 may be coupled to the light shielding film 180. In this case, by forming the back surface side light shielding unit 170 using the same material as that of the light shielding film 180, the back surface side light shielding unit 170 and the light shielding film 180 may be simultaneously formed. Hereinafter, the back surface side light shielding unit 170 and the light shielding film 180 including W are assumed.

[Configuration of Light Shielding Unit]

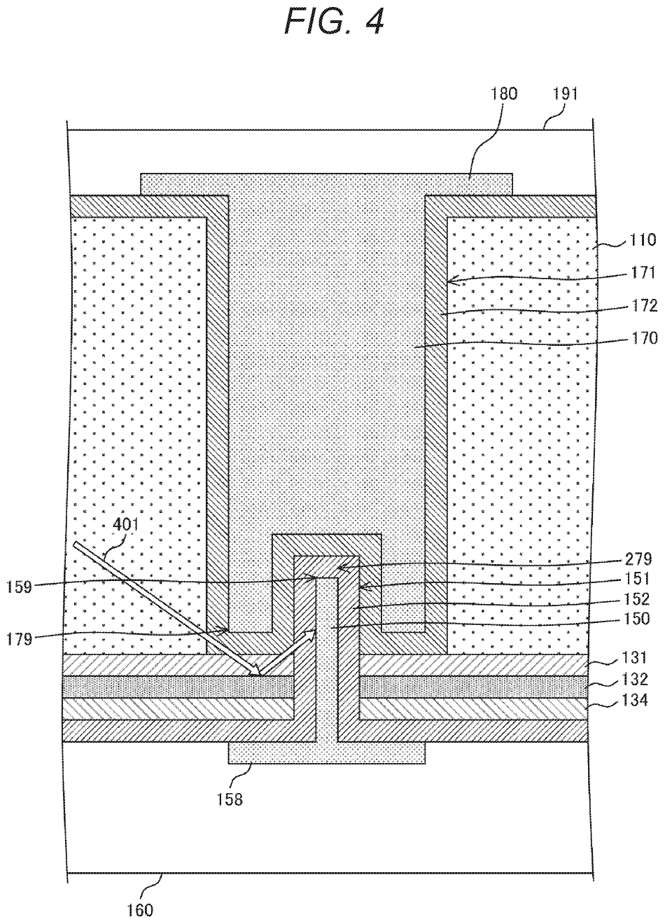

FIG. 4 is a cross-sectional view illustrating a configuration example of the light shielding unit according to the first embodiment of the present disclosure. The drawing is a schematic cross-sectional view illustrating a configuration example of the front surface side light shielding unit 150 and the back surface side light shielding unit 170 at the boundary between the pixels 100.

The insulating films 131, 132, and 134 are sequentially stacked to be arranged between the front surface side of the semiconductor substrate 110 and the wiring region 160. An SiO₂ film may be used as the insulating film 131. An SiN film may be used as the insulating film 132. An SiO₂ film may be used as the insulating film 134.

The front surface side light shielding unit 150 is arranged in the front surface side groove 151 formed on the front surface side of the semiconductor substrate 110. The front surface side groove 151 in the drawing is formed into a shape to penetrate the insulating films 134, 132, and 131 and to shave the front surface side of the semiconductor substrate 110 relatively shallowly. The front surface side light shielding unit 150 is arranged in the front surface side groove 151. Furthermore, an insulating film 152 is arranged between the front surface side groove 151 and the front surface side light shielding unit 150 in the drawing. The insulating film 152 may include, for example, SiO₂. Furthermore, the insulating film 152 is also arranged between the semiconductor substrate 110 and the wiring region 160. Note that, a fixed charge film may be arranged between the front surface side groove 151 and the insulating film 152. The fixed charge film is a film including a dielectric having a negative fixed charge. A hole accumulation region may be formed in the vicinity of an interface of the semiconductor substrate 110 by the negative fixed charge, and an influence of an interface level of the semiconductor substrate 110 may be reduced. The fixed charge film may include, for example, hafnium oxide (HfO₂), aluminum oxide (Al₂O₃), and tantalum oxide (Ta₂O₅).

The front surface side groove 151 may be formed by dry etching or wet etching using a chemical solution. The front surface side groove 151 may be formed to have a depth of 50 to 350 nm in the semiconductor substrate 110. Preferably, the front surface side groove 151 is formed to have a depth of 150 to 250 nm. As the front surface side groove 151 is made deeper, the front surface side light shielding unit 150 may be made deeper, and ability to shield the incident light together with the back surface side light shielding unit 170 described later may be improved. However, the deeper the front surface side groove 151 is formed, the more difficult the processing is, and the more saturated a characteristic of improving the light shielding ability is. Furthermore, the more minutely the front surface side groove 151 is processed, the more an occupied area of the front surface side light shielding unit 150 may be reduced. The front surface side groove 151 may be formed to have a width of, for example, 50 nm or less.

The back surface side light shielding unit 170 is arranged in the back surface side groove 171 formed on the back surface side of the semiconductor substrate 110. The back surface side groove 171 in the drawing illustrates an example of being arranged into a shape to penetrate the semiconductor substrate 110. In this case, the back surface side light shielding unit 170 is formed into a shape to substantially penetrate the semiconductor substrate 110. Furthermore, an insulating film 172 is arranged between the back surface side groove 171 and the back surface side light shielding unit 170 in the drawing. The insulating film 172 may include an SiO₂ film as is the case with the insulating film 152. Furthermore, the insulating film 172 is formed into a shape to cover the back surface side of the semiconductor substrate 110, and further insulates the back surface side of the semiconductor substrate 110. Furthermore, a fixed charge film may be arranged between the semiconductor substrate 110 including the back surface side groove 171 and the insulating film 172.

As illustrated in the drawing, the back surface side light shielding unit 170 may be formed to have such a depth that a bottom 179 of the back surface side light shielding unit 170 reaches a position between a bottom 159 of the front surface side light shielding unit 150 and the front surface side of the semiconductor substrate 110. Furthermore, a cross-sectional width at the bottom of the back surface side light shielding unit 170 may be made wider than a cross-sectional width at the bottom of the front surface side light shielding unit 150, and the back surface side light shielding unit 170 may be formed at a position including the bottom of the front surface side light shielding unit 150. Therefore, the bottom of the front surface side light shielding unit 150 may be formed into a shape fitted into a recess 279 formed at the bottom of the back surface side light shielding unit 170. That is, the bottoms of the front surface side light shielding unit 150 and the back surface side light shielding unit 170 may be intricated. Even in a case where the insulating film 152 and the insulating film 172 are arranged between the front surface side light shielding unit 150 and the back surface side light shielding unit 170, light reaching the adjacent pixel 100 via these insulating films may be greatly attenuated. A white arrow 401 in the drawing indicates a state in which light incident in the vicinity of the bottom of the back surface side light shielding unit 170 is shielded.

The back surface side groove 171 may be formed by etching the back surface side of the semiconductor substrate 110. Specifically, a groove that penetrates the semiconductor substrate 110 is formed by anisotropic dry etching such as a Bosch process. Thereafter, isotropic wet etching may be performed to widen the groove, and the semiconductor substrate 110 on a side surface of the groove damaged by the above-described dry etching may be removed.

Note that, it is possible to omit the front surface side light shielding unit 150, and form the back surface side groove 171 to have a depth to reach a region of the light shielding film 158 from the back surface side of the semiconductor substrate 110 to arrange the light shielding member, thereby forming the back surface side light shielding unit 170 coupled to the light shielding films 158 and 180. However, dry etching of the insulating film 132 including SiN and the light shielding film 158 including W is performed, which causes a problem that the damage of the semiconductor substrate 110 increases and a wall surface of the semiconductor substrate 110 is contaminated by W. A crystal defect is generated in the semiconductor substrate 110 due to the damage and the like. A dark current is generated by the charge captured by the crystal defect, and noise is generated in the image signal. Furthermore, damage of the semiconductor substrate 110 due to light emission of plasma at the time of dry etching also becomes a problem.

In order to prevent them, the back surface side groove 171 is limited in the region of the semiconductor substrate 110, and the front surface side light shielding unit 150 is formed in advance. Since the front surface side light shielding unit 150 is formed by arranging W in the front surface side groove 151, a step of the dry etching of W described above becomes unnecessary. Dry etching of the insulating film 132 and the semiconductor substrate 110 is performed when the front surface side groove 151 is formed, but the region of the semiconductor substrate 110 damaged when the front surface side groove 151 is formed is removed when the back surface side groove 171 is formed. In this manner, by using the front surface side light shielding unit 150 and the back surface side light shielding unit 170, it is possible to reduce the defect of the semiconductor substrate 110 that shields light at the boundary between the pixels 100.

[Manufacturing Method of Imaging Element]

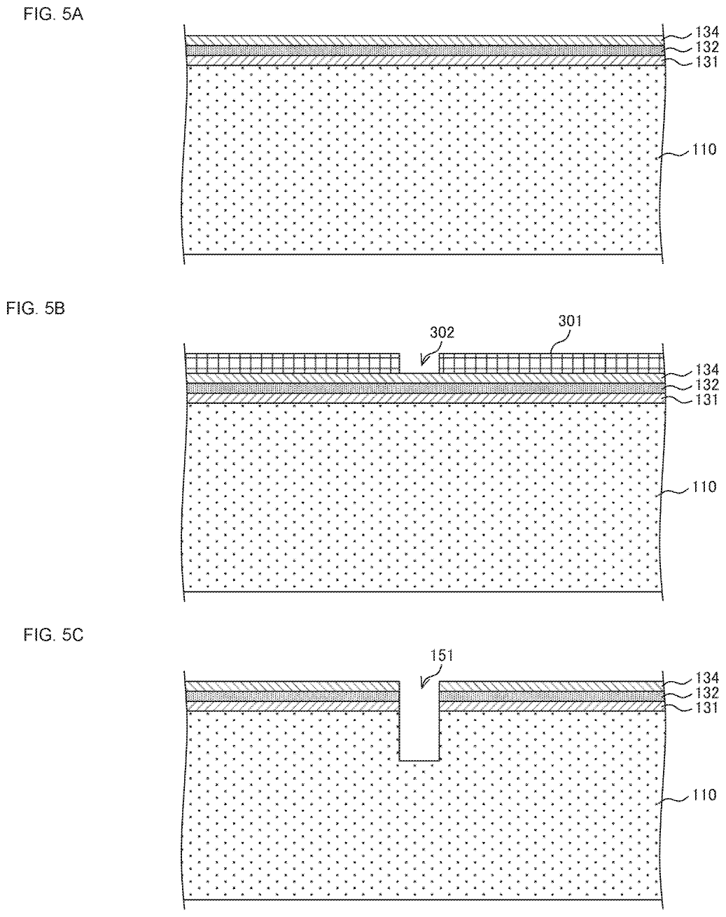

FIGS. 5 to 9 are diagrams illustrating an example of a manufacturing method of the imaging element according to the first embodiment of the present disclosure. FIGS. 5 to 9 are diagrams illustrating an example of a manufacturing step of the pixel 100 portion of the imaging element 1. First, the well region is formed on the front surface side of the semiconductor substrate 110 to form the semiconductor region 111 and the like. Next, the insulating film 131, the insulating film 132, and the insulating film 134 are stacked on the front surface side of the semiconductor substrate 110. At that time, the gate 122 (not illustrated) and a side wall insulating film (not illustrated) are formed (A of FIG. 5).

Next, a resist 301 is arranged on the front surface side of the semiconductor substrate 110. The resist 301 is provided with an opening 302 in a region where the front surface side groove 151 is formed (B of FIG. 5).

Next, using the resist 301 as a mask, the insulating films 131, 132, and 134 and the semiconductor substrate 110 are etched to form the front surface side groove 151. Dry etching may be applied to the etching (C of FIG. 5).

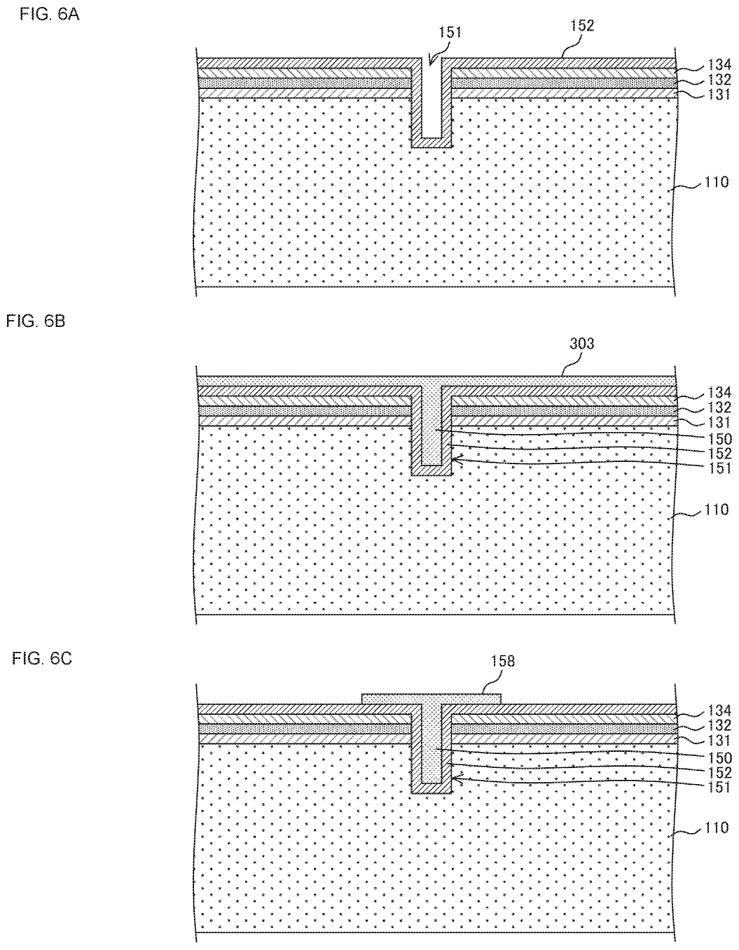

Next, the insulating film 152 is arranged on the front surface side of the semiconductor substrate 110 including the front surface side groove 151. SiO₂ may be used as the insulating film 152. The insulating film 152 may be formed by, for example, atomic layer deposition (ALD) (D of FIG. 6). Note that, the fixed charge film may be arranged before the insulating film 152 is arranged.

Next, a film 303 of a light shielding member is arranged on the front surface side of the semiconductor substrate 110. At that time, the film 303 of the light shielding member is also arranged in the front surface side groove 151, and the front surface side light shielding unit 150 is formed. W may be used as the light shielding member. The film 303 of the light shielding member may be formed by, for example, chemical vapor deposition (CVD) (E of FIG. 6). This step corresponds to a front surface side light shielding unit forming step.

Next, the film 303 of the light shielding member is processed to form the light shielding film 158. This may be performed by etching the film 303 of the light shielding member (F of FIG. 6).

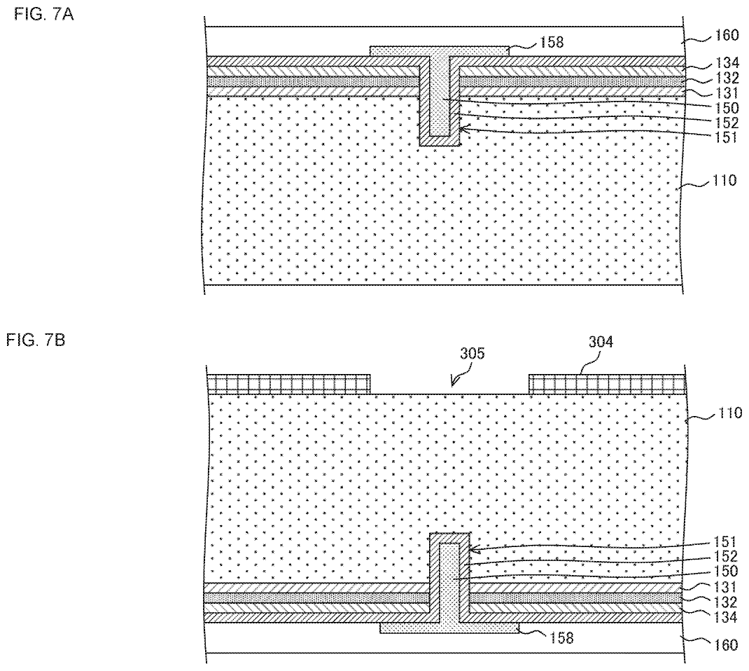

Next, the wiring region 160 is formed on the front surface side of the semiconductor substrate 110 (G of FIG. 7). Next, a support substrate (not illustrated) is bonded adjacent to the wiring region 160. Here, the support substrate is a substrate that supports a semiconductor wafer on which the imaging element 1 is formed.

Next, the semiconductor substrate 110 is inverted upside down, and the back surface side thereof is ground to thin the semiconductor substrate 110. Next, a resist 304 is arranged on the back surface side of the semiconductor substrate 110. The resist 304 is provided with an opening 305 in a region where the back surface side groove 171 is formed (H of FIG. 7).

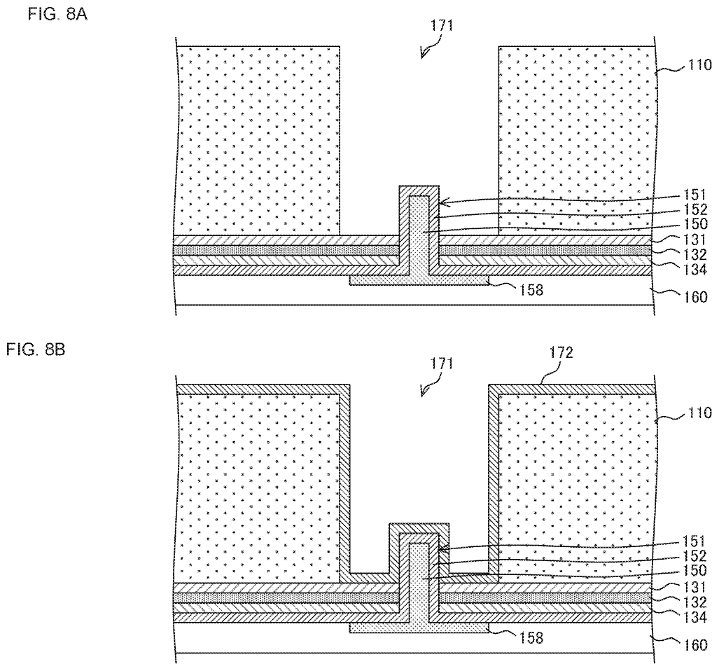

Next, using the resist 304 as a mask, the etching is performed and the back surface side groove 171 is formed. Anisotropic dry etching and isotropic wet etching may be applied together to the etching. At that time, it is preferable to perform etching under a condition of a high selection ratio with respect to SiO₂ forming the insulating films 131 and 152 (I of FIG. 8).

Next, the insulating film 172 is arranged on the back surface side of the semiconductor substrate 110 including the back surface side groove 171. SiO₂ may be used as the insulating film 172. The insulating film 152 may be formed by, for example, ALD (J of FIG. 6). Note that, the fixed charge film may be arranged before the insulating film 172 is arranged.

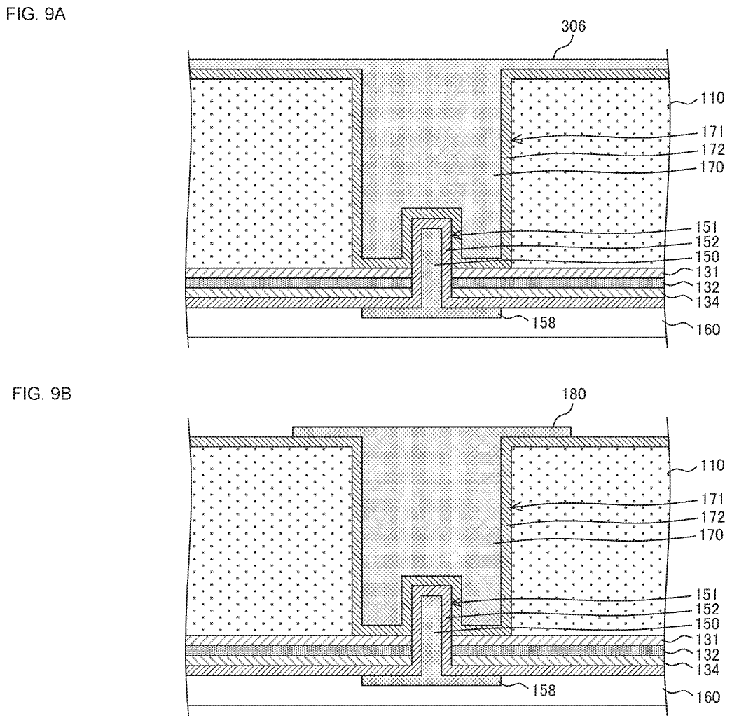

Next, a film 306 of a light shielding member is arranged on the back surface side of the semiconductor substrate 110. At that time, the film 306 of the light shielding member is also arranged in the back surface side groove 171, and the back surface side light shielding unit 170 is formed. W may be used as the light shielding member. The film 306 of the light shielding member may be formed by, for example, CVD (K of FIG. 9). This step corresponds to a front surface side light shielding unit forming step.

Next, the film 306 of the light shielding member is processed to form the light shielding film 180. This may be performed by etching the film 306 of the light shielding member (L of FIG. 9).

Next, the pixel 100 and the imaging element 1 may be formed by arranging the flattening film 191, the color filter 192, and the on-chip lens 193.

As described above, the imaging element 1 of the first embodiment of the present disclosure may shield the incident light incident from the adjacent pixel 100 by arranging the front surface side light shielding unit 150 and the back surface side light shielding unit 170 in the semiconductor substrate 110 at the boundary between the pixels 100. Occurrence of crosstalk may be reduced.

### 2. Second Embodiment

In the imaging element 1 of the first embodiment described above, one front surface side light shielding unit 150 is used. In contrast, an imaging element 1 of a second embodiment of the present disclosure is different from that of the first embodiment described above in using two front surface side light shielding units.

[Configuration of Light Shielding Unit]

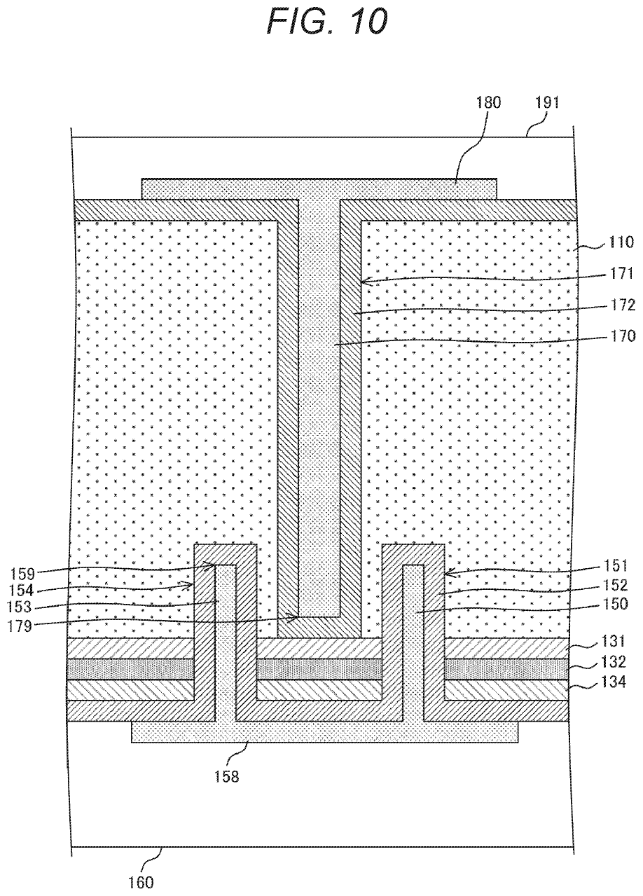

FIG. 10 is a cross-sectional view illustrating a configuration example of a light shielding unit according to the second embodiment of the present disclosure. Similarly to FIG. 4, the drawing is a schematic cross-sectional view illustrating the configuration example of the light shielding unit at a boundary between the pixels 100. The light shielding unit is different from the light shielding unit illustrated in FIG. 4 in that a front surface side light shielding unit 153 is further arranged on a front surface side of a semiconductor substrate 110, and a back surface side light shielding unit 170 is arranged between front surface side light shielding units 150 and 153.

The front surface side light shielding unit 153 in the drawing is a front surface side light shielding unit arranged in parallel with the front surface side light shielding unit 150. The front surface side light shielding unit 153 is obtained by arranging a light shielding member in a front surface side groove 154 formed on the front surface side of the semiconductor substrate 110, and is coupled to a light shielding film 158. Furthermore, an insulating film 152 is arranged between the front surface side groove 154 and the front surface side light shielding unit 153 in the drawing.

The back surface side light shielding unit 170 in the drawing is formed to have a narrower cross-sectional width than that of the back surface side light shielding unit 170 illustrated in FIG. 4, and is arranged between the front surface side light shielding units 150 and 153. In the light shielding unit in the drawing also, the back surface side light shielding unit 170 may be formed to have such a depth that a bottom 179 reaches a position between a bottom 159 of the front surface side light shielding units 150 and 153 and the front surface side of the semiconductor substrate 110. The bottom of the back surface side light shielding unit 170 is formed into a shape fitted into a recess formed by the two front surface side light shielding units 150 and 153, and the bottoms of the front surface side light shielding units 150 and 153 and the bottom of the back surface side light shielding unit 170 are intricated. It is possible to shield light incident in the vicinity of the bottom of the back surface side light shielding unit 170. Furthermore, the width of the front surface side light shielding unit 150 may be made narrow, and a region of the pixel 100 in the semiconductor substrate 110 may be made wide.

[Another Configuration of Light Shielding Unit]

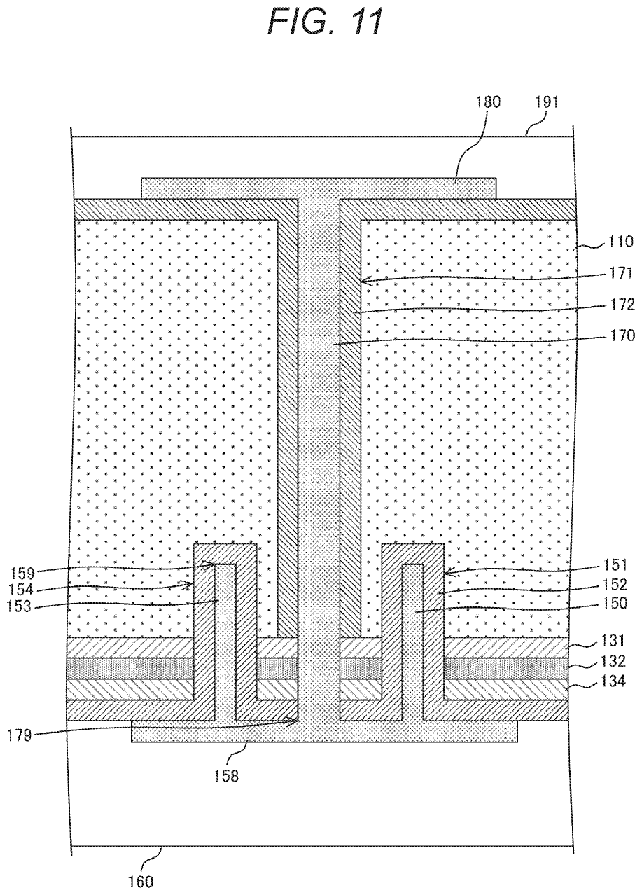

FIG. 11 is a cross-sectional view illustrating another configuration example of the light shielding unit according to the second embodiment of the present disclosure. Similarly to FIG. 10, the drawing is a schematic cross-sectional view illustrating the configuration example of the light shielding unit at the boundary between the pixels 100. The light shielding unit is different from the light shielding unit illustrated in FIG. 10 in that the back surface side light shielding unit 170 is formed into a shape in contact with the light shielding film 158.

The back surface side light shielding unit 170 in the drawing may be formed by a following step. In the semiconductor substrate 110 in which a back surface side groove 171 is formed on a back surface side of the semiconductor substrate 110 and an insulating film 172 is arranged therein, the insulating film 172 at a bottom of the back surface side groove 171 is removed by etching back. Etching back is further performed to sequentially remove an insulating film 131, an insulating film 132, an insulating film 134, and the insulating film 152, and the back surface side groove 171 is formed to have such a depth that the bottom thereof reaches the light shielding film 158, and a light shielding member is arranged therein. Therefore, the back surface side light shielding unit 170 coupled to the light shielding film 158 may be formed.

Since a configuration of the imaging element 1 other than this is similar to the configuration of the imaging element 1 described in the first embodiment of the present disclosure, the description thereof is omitted.

As described above, in the imaging element 1 of the second embodiment of the present disclosure, the back surface side light shielding unit 170 is arranged between the two front surface side light shielding units 150 and 153. The back surface side light shielding unit 170 may be formed to have a relatively narrow width, and a region of the pixel 100 in the semiconductor substrate 110 may be made wide. A region of the photoelectric conversion unit 101 may be expanded, and sensitivity may be improved.

### 3. Third Embodiment

In the imaging element 1 of the first embodiment described above, the back surface side light shielding unit 170 is arranged in the well region of the semiconductor substrate 110. In contrast, an imaging element 1 of a third embodiment of the present disclosure is different from that of the first embodiment described above in that a semiconductor region formed by solid phase diffusion is arranged adjacent to a back surface side light shielding unit 170.

[Configuration of Pixel]

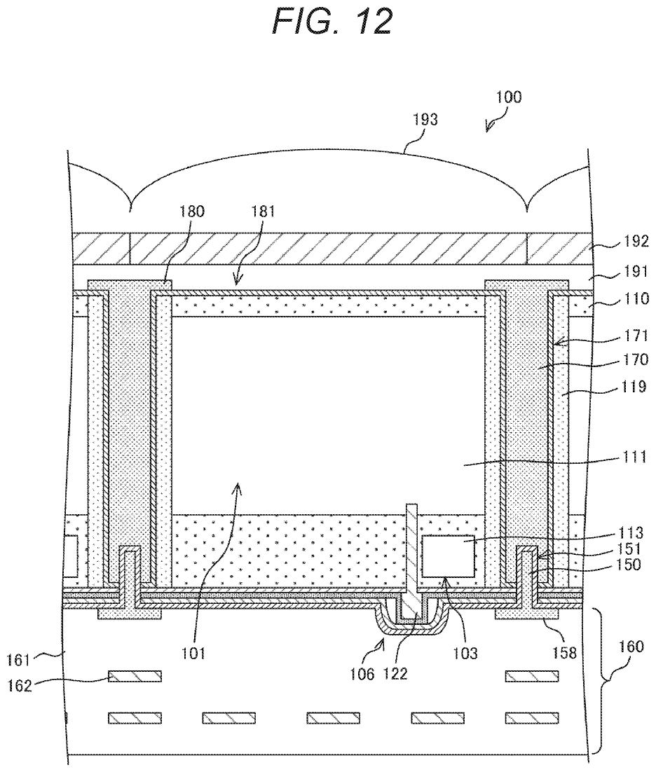

FIG. 12 is a diagram illustrating a configuration example of a pixel according to the third embodiment of the present disclosure. Similarly to FIG. 3, the drawing is a schematic cross-sectional view illustrating a configuration example of a pixel 100. The pixel 100 is different from the pixel 100 illustrated in FIG. 3 in that a solid phase diffusion layer 119 is arranged between a semiconductor region 111 and a back surface side light shielding unit 170, the semiconductor region 111 is separated from a front surface side of a semiconductor substrate, and a semiconductor region 113 is formed at a position overlapping the semiconductor region 111 in a vertical direction.

The solid phase diffusion layer 119 is a semiconductor region formed by diffusing impurities into a semiconductor substrate 110 by a solid phase diffusion method, and is a semiconductor region formed to have a conductivity type different from that of an n-type semiconductor region 111 and the like forming a photoelectric conversion unit 101. The solid phase diffusion layer 119 in the drawing illustrates an example of being formed to be a p-type. The solid phase diffusion layer 119 formed to be the p-type forms a pn junction with the n-type semiconductor region 111 and electrically isolates the photoelectric conversion unit 101 of the pixel 100. Furthermore, the solid phase diffusion layer 119 may be formed to have an impurity concentration higher than that of a p-type well region. Therefore, an electric field of the pn junction at an interface between the semiconductor region 111 and the solid phase diffusion layer 119 may be increased, and a capacitance of charges accumulated in the semiconductor region 111 may be improved.

Such solid phase diffusion layer 119 may be formed from a front surface side to a deep region of the semiconductor substrate 110. Furthermore, by arranging the solid phase diffusion layer 119 around the semiconductor region 111, a saturation charge amount of the photoelectric conversion unit 101 may be improved. As illustrated in the drawing, the semiconductor region 111 may be embedded from the front surface side to the deep region of the semiconductor substrate 110, and another semiconductor region such as the semiconductor region 113 may be arranged on the front surface side of the semiconductor substrate 110 at a position overlapping the semiconductor region 111.

Note that, a gate 122 of a MOS transistor 106 in the drawing is formed into a shape embedded at a position to reach the semiconductor region 111 from the front surface side of the semiconductor substrate 110, and is arranged at a position adjacent to the semiconductor region 113. At the time of conduction of the MOS transistor 106, the charge in the semiconductor region 111 is transmitted in a direction perpendicular to the semiconductor substrate 110. The MOS transistor having such a configuration is referred to as a vertical transistor. Note that, an isolation region (not illustrated) may be arranged between a region where elements other than the photoelectric conversion unit 101 are formed and the solid phase diffusion layer 119 on the front surface side of the semiconductor substrate 110. For example, shallow trench isolation (STI) may be used for the isolation region.

As described above, the solid phase diffusion layer 119 may be formed by the solid phase diffusion method. Specifically, a groove 157 (not illustrated) is formed in the semiconductor substrate 110 at the boundary between the pixels 100. A solid thin film containing a large amount of impurities is arranged on a side wall of the groove 157 and heated. Therefore, the impurities of the solid thin film diffuse into the semiconductor substrate 110, and the solid phase diffusion layer 119 may be formed in the semiconductor substrate 110 around the groove 157. As the solid thin film, a SiO₂ film containing a large amount of impurities may be used. Furthermore, boron (B) as an acceptor may be used as the impurities of the solid thin film. Note that, when an n-type solid phase diffusion layer 119 is formed, the solid thin film is allowed to contain phosphorus (P) as a donor. At the time of the solid phase diffusion, the semiconductor substrate 110 is heated to high temperature of about 1,000° C. Therefore, the solid phase diffusion needs to be performed before a wiring region 160 is formed.

After the solid phase diffusion layer 119 is formed, the solid thin film arranged in the groove 157 is removed. Next, an insulating film (insulating film 173) is arranged in the groove 157, and a filling member (filling member 118) such as polycrystalline Si is arranged therein. That is, the groove 157 is backfilled with the filling member 118. A front surface side light shielding unit 150 may be formed in a region of the filling member. Thereafter, the filling member is removed by etching from a back surface side of the semiconductor substrate 110. The groove from which the filling member 118 is removed may be used as a back surface side groove 171. That is, the groove 157 arranged so as to form the solid phase diffusion layer 119 may be diverted to the back surface side groove 171. The filling member 118 may include, for example, polycrystalline Si.

[Manufacturing Method of Imaging Element]

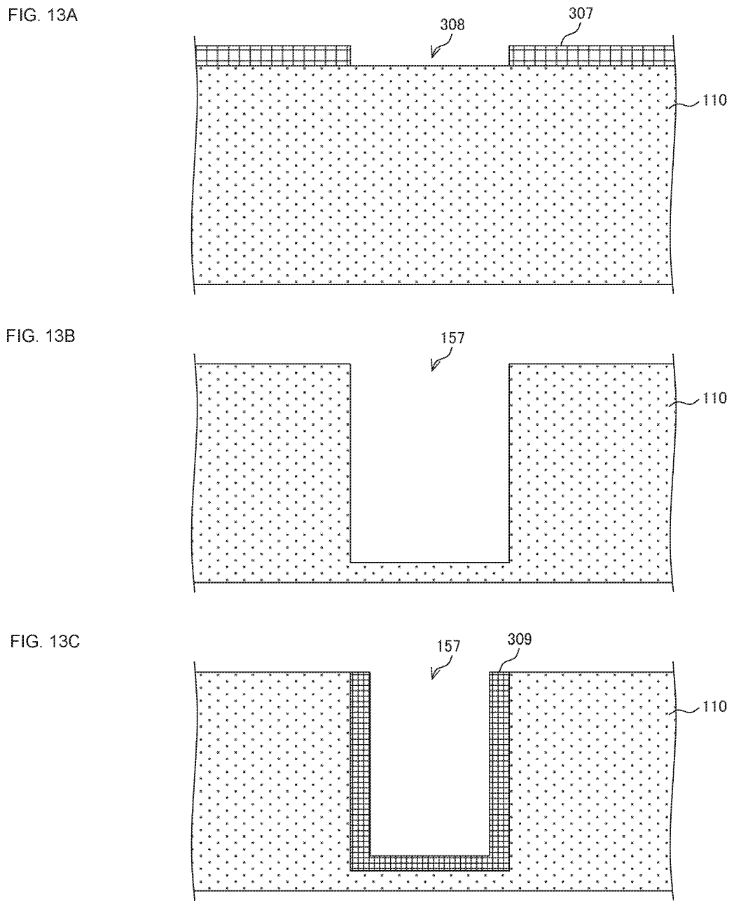

FIGS. 13 to 17 are diagrams illustrating an example of a manufacturing method of the imaging element according to the third embodiment of the present disclosure. FIGS. 13 to 17 are diagrams illustrating an example of a manufacturing step of the pixel 100 portion of the imaging element 1. First, a resist 307 is arranged on the front surface side of the semiconductor substrate 110. The resist 307 is provided with an opening 308 in a region where the solid phase diffusion layer 119 is formed (A of FIG. 13).

Next, using the resist 307 as a mask, the semiconductor substrate 110 is etched to form a groove 157. Dry etching may be applied to the etching (B of FIG. 13).

Next, a solid thin film 309 containing B is arranged on an inner wall of the groove 157. This may be performed by, for example, CVD (C of FIG. 13).

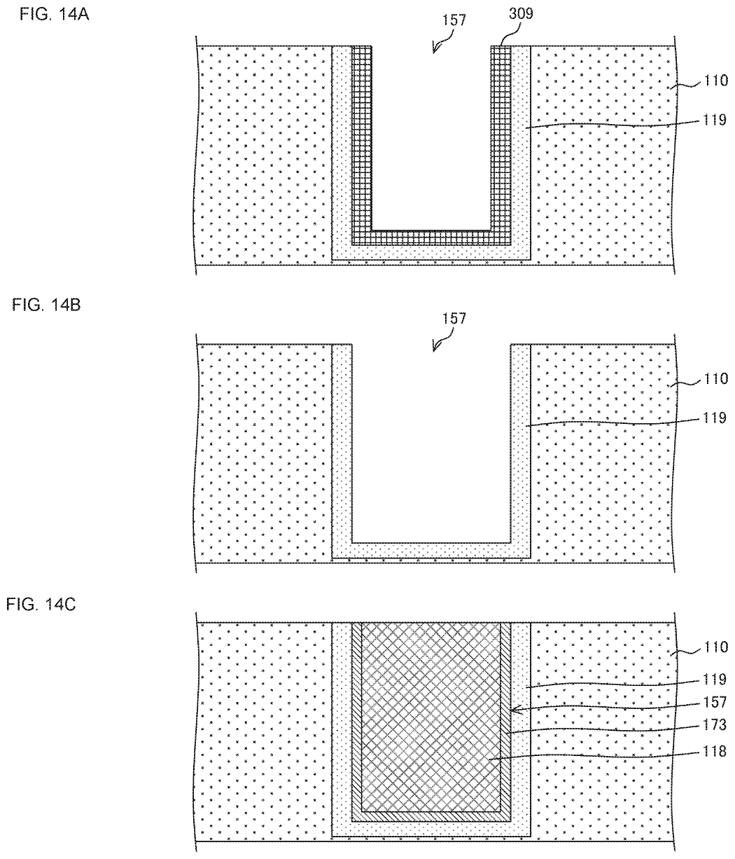

Next, the semiconductor substrate 110 is heated to perform the solid phase diffusion. Therefore, the solid phase diffusion layer 119 may be formed in the semiconductor substrate 110 adjacent to the groove 157 (D of FIG. 14).

Next, the solid thin film 309 is removed. This makes it possible to prevent the solid phase diffusion at subsequent steps (E of FIG. 14).

Next, the insulating film 173 is arranged in the groove 157. An SiO₂ film may be used for the insulating film 173. Furthermore, the insulating film 173 may be formed by CVD. Next, the filling member 118 is arranged on the front surface side of the semiconductor substrate 110 including the groove 157. Polycrystalline Si may be used as the filling member 118. Furthermore, the filling member 118 may be arranged by CVD. Next, the filling member 118 arranged on the front surface side of the semiconductor substrate 110 other than the groove 157 is removed by, for example, chemical mechanical polishing (CMP). Therefore, the filling member 118 may be arranged in the groove 157 (F of FIG. 14). Thereafter, the semiconductor region 111 and the like are formed in the semiconductor substrate 110.

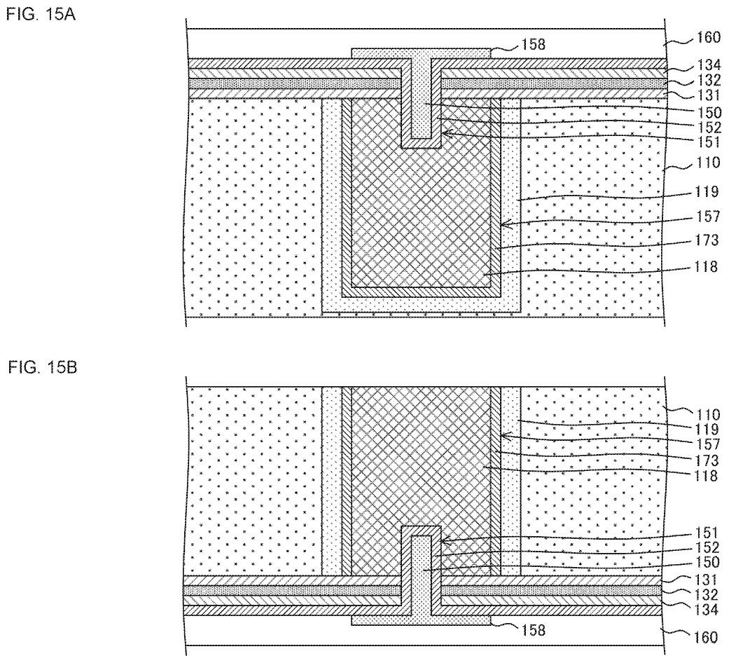

Next, steps from A of FIG. 5 to G of FIG. 7 are applied to form an insulating film 131, an insulating film 132, an insulating film 134, the gate 122 (not illustrated), the front surface side light shielding unit 150, an insulating film 152, and the wiring region 160 (G of FIG. 15).

Next, a support substrate not illustrated is bonded, the semiconductor substrate 110 is inverted upside down, and the back surface side thereof is ground to thin the semiconductor substrate 110. This grinding is performed until the filling member 118 is exposed to the back surface side of the semiconductor substrate 110 (H of FIG. 15).

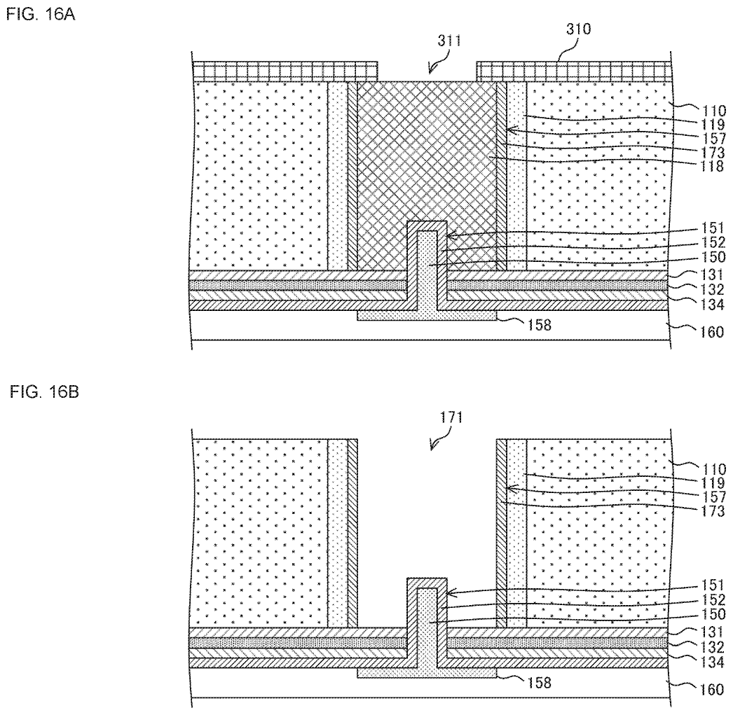

Next, a resist 310 is arranged on the back surface side of the semiconductor substrate 110. The resist 310 is provided with an opening 311 in a region adjacent to the filling member 118 (I of FIG. 16).

Next, the filling member 118 is removed using the resist 310 as a mask. This may be performed by wet etching. The wet etching is performed under a condition of a high selection ratio with respect to SiO₂ forming the insulating film 152 and the like. The backfilled filling member 118 is removed by etching from the back surface side of the semiconductor substrate 110, and the back surface side groove 171 is formed. Next, the resist 310 is removed (J of FIG. 16).

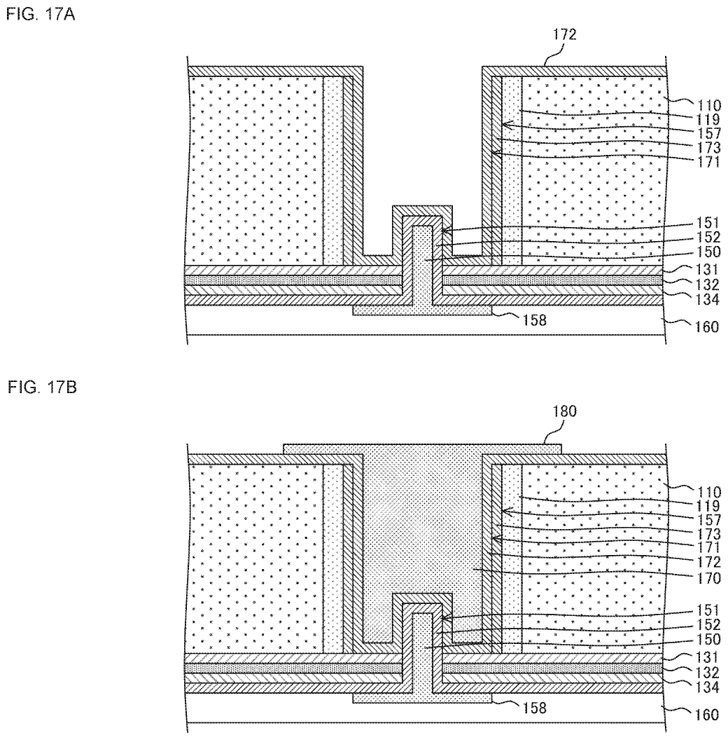

Next, an insulating film 172 is arranged on the back surface side of the semiconductor substrate 110 including the back surface side groove 171 (K of FIG. 17).

Next, a light shielding member is arranged in the back surface side groove 171 to form the back surface side light shielding unit 170, and form a light shielding film 180 (L of FIG. 17).

By the above-described steps, the solid phase diffusion layer 119, the front surface side light shielding unit 150, and the back surface side light shielding unit 170 may be formed.

Since a configuration of the imaging element 1 other than this is similar to the configuration of the imaging element 1 described in the first embodiment of the present disclosure, the description thereof is omitted.

As described above, in the imaging element 1 of the third embodiment of the present disclosure, the front surface side light shielding unit 150 and the back surface side light shielding unit 170 are arranged in the semiconductor substrate 110 in which the solid phase diffusion layer 119 is arranged in the vicinity of the boundary between the pixels 100. The groove 157 for forming the solid phase diffusion layer 119 may be used as the back surface side groove 171, and the manufacturing step may be simplified.

### 4. Fourth Embodiment

The imaging element 1 of the first embodiment described above is formed into the shape in which the bottom of the front surface side light shielding unit 150 is fitted into the recess formed on the bottom of the back surface side light shielding unit 170. In contrast, an imaging element 1 of a fourth embodiment of the present disclosure is different from that of the first embodiment described above in that a bottom of a back surface side light shielding unit 170 is formed into a shape in contact with a bottom of a front surface side light shielding unit 150.

[Configuration of Light Shielding Unit]

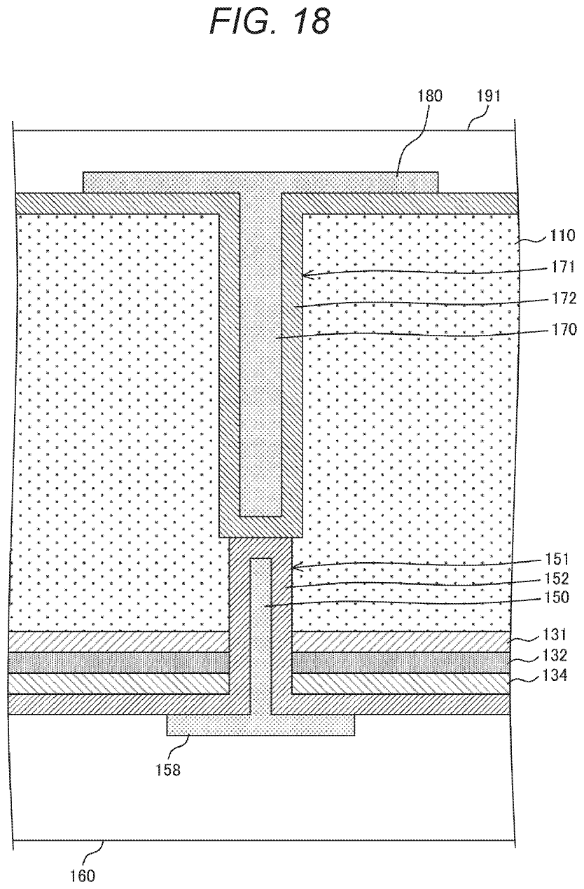

FIG. 18 is a cross-sectional view illustrating a configuration example of a light shielding unit according to the fourth embodiment of the present disclosure. Similarly to FIG. 4, the drawing is a schematic cross-sectional view illustrating the configuration example of the light shielding unit at a boundary between the pixels 100. The back surface side light shielding unit 170 is different from the back surface side light shielding unit 170 illustrated in FIG. 4 in that the bottom thereof is formed into a shape in contact with the bottom of the front surface side light shielding unit 150.

A back surface side groove 171 in the drawing is formed to have such a depth that a bottom thereof is in contact with a bottom of a front surface side groove 151. By arranging a light shielding member in such back surface side groove 171 and front surface side groove 151, it is possible to form the front surface side light shielding unit 150 and the back surface side light shielding unit 170 having such shapes that the bottoms thereof are in contact with each other. Note that, an example in which the front surface side light shielding unit 150 and the back surface side light shielding unit 170 in the drawing are in contact with each other via an insulating film 152 and an insulating film 172 is illustrated.

Even with such a simplified configuration, light shielding at a boundary between pixels 100 may be performed by the front surface side light shielding unit 150 and the back surface side light shielding unit 170. Furthermore, in a case where the back surface side groove 171 is formed using wet etching, it is possible to reduce occurrence of defects in a semiconductor substrate 110 in the vicinity of the back surface side groove 171.

Note that, the back surface side light shielding unit 170 in the drawing illustrates an example of being formed to have a wider cross-sectional width than that of the front surface side light shielding unit 150, but the back surface side light shielding unit 170 may be formed to have a narrower cross-sectional width than that of the front surface side light shielding unit 150. Furthermore, the front surface side light shielding unit 150 and the back surface side light shielding unit 170 may be formed to have substantially the same cross-sectional widths.

Since a configuration of the imaging element 1 other than this is similar to the configuration of the imaging element 1 described in the first embodiment of the present disclosure, the description thereof is omitted.

As described above, in the imaging element 1 of the fourth embodiment of the present disclosure, the front surface side light shielding unit 150 and the back surface side light shielding unit 170 having such shapes that the bottoms thereof are in contact with each other are arranged at the boundary between the pixels 100. Therefore, a shape of the back surface side light shielding unit 170 may be simplified.

### 5. Fifth Embodiment

The imaging element 1 of the first embodiment described above performs the rolling shutter type imaging. In contrast, an imaging element 1 of a fifth embodiment of the present disclosure is different from that of the above-described first embodiment in that global shutter type imaging is performed in which exposure is simultaneously performed in all pixels 100 arranged in a pixel array unit 10.

[Circuit Configuration of Pixel]

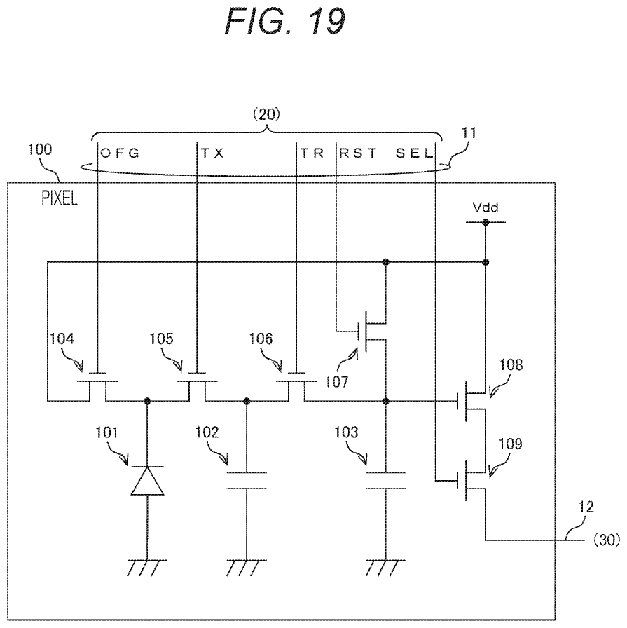

FIG. 19 is a diagram illustrating a configuration example of the pixel according to the fifth embodiment of the present disclosure. Similarly to FIG. 2, the drawing is a circuit diagram illustrating a configuration example of the pixel 100. The pixel 100 is different from the pixel 100 in FIG. 2 in further including a second charge holding unit 102 and MOS transistors 104 and 105. Furthermore, a signal line OFG and a signal line TX are further arranged in a signal line 11.

A cathode of a photoelectric conversion unit 101 is connected to a source of the MOS transistor 104 and a source of the MOS transistor 105. A drain of the MOS transistor 104 is connected to a power supply line Vdd, and a gate thereof is connected to the signal line OFG. A gate of the MOS transistor 105 is connected to the signal line TX, and a drain thereof is connected to one end of the second charge holding unit 102 and a source of a MOS transistor 106. The other end of the second charge holding unit 102 is grounded. Since connections of the circuit other than them are similar to those in the circuit diagram in FIG. 2, the description thereof is omitted.

The MOS transistor 104 is a transistor that resets the photoelectric conversion unit 101 by discharging a charge held by the photoelectric conversion unit 101 to the power supply line Vdd. The reset of the photoelectric conversion unit 101 by the MOS transistor 104 is controlled by a signal transmitted by the signal line OFG. The MOS transistor 105 is a transistor that transfers the charge generated by photoelectric conversion of the photoelectric conversion unit 101 to the second charge holding unit 102. The transfer of the charge by the MOS transistor 105 is controlled by a signal transmitted by the signal line TX. The second charge holding unit 102 is a capacitor that holds the charge transferred by the MOS transistor 105. Note that, the MOS transistor 106 in the drawing transfers the charge held by the second charge holding unit 102 to a charge holding unit 103.

Generation of an image signal by the pixel 100 in the drawing may be performed as follows. First, the MOS transistor 104 is brought into conduction to reset the photoelectric conversion unit 101. The charge generated by the photoelectric conversion after the reset is finished is accumulated in the photoelectric conversion unit 101. After a predetermined period elapses, MOS transistors 106 and 107 are brought into conduction to reset the second charge holding unit 102. Next, the MOS transistor 105 is brought into conduction. Therefore, the charge generated by the photoelectric conversion unit 101 is transferred to and held by the second charge holding unit 102. The operation from the reset of the photoelectric conversion unit 101 to the transfer of the charge by the MOS transistor 105 is simultaneously performed in all the pixels 100 arranged in the pixel array unit 10. That is, global reset, which is simultaneous reset in all the pixels 100, and simultaneous charge transfer in all the pixels 100 are executed. Therefore, the global shutter is implemented. Note that, a period from the reset of the photoelectric conversion unit 101 to the transfer of the charge by the MOS transistor 105 corresponds to an exposure period.

Next, the MOS transistor 107 is brought into conduction again to reset the charge holding unit 103. Next, the MOS transistor 106 is brought into conduction and the charge held by the second charge holding unit 102 is transferred to and held by the charge holding unit 103. Therefore, a MOS transistor 108 generates the image signal corresponding to the charge held by the charge holding unit 103. Next, a MOS transistor 109 is brought into conduction, so that the image signal generated by the MOS transistor 108 is output to a signal line 12. The operation from the reset of the first charge holding unit 103 to the output of the image signal described above is sequentially performed for the pixels 100 arranged in each row of the pixel array unit 10. The image signals in the pixels 100 in all the rows of the pixel array unit 10 are output, so that a frame being the image signal for one screen is generated and output from the imaging element 1.

By generating and outputting the image signal in the pixel 100 in parallel in the above-described exposure period, time required for imaging and transferring the image signal may be shortened. Furthermore, by simultaneously performing exposure in all the pixels 100 of the pixel array unit 10, it is possible to prevent occurrence of frame distortion and improve an image quality. In this manner, the second charge holding unit 102 is used to temporarily hold the charge generated by the photoelectric conversion unit 101 when performing the global shutter.

[Configuration of Pixel]

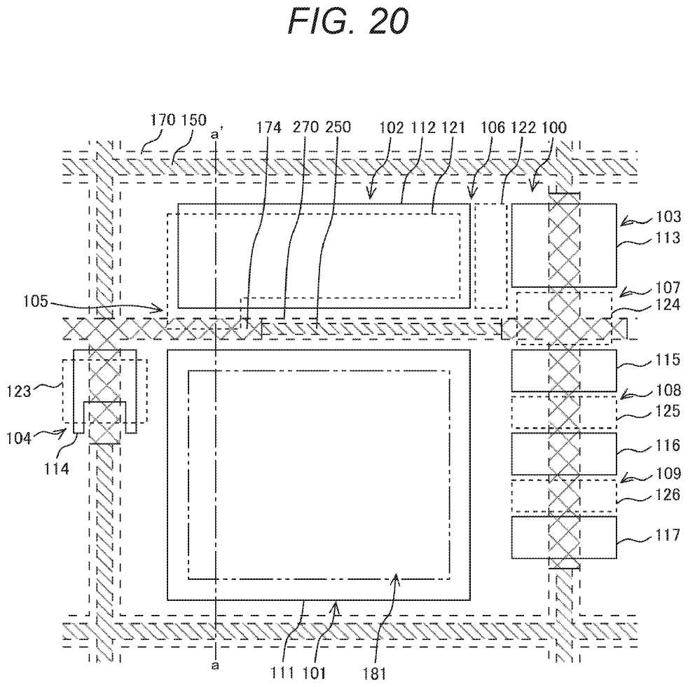

FIG. 20 is a plane view illustrating a configuration example of the pixel according to the fifth embodiment of the present disclosure. The drawing is a plan view illustrating a configuration example of the pixel 100, and is a diagram schematically illustrating arrangement of elements such as the photoelectric conversion unit 101 illustrated in FIG. 19. Furthermore, the drawing is a diagram illustrating the configuration of the pixel 100 as seen from a back surface side of a semiconductor substrate 110, which is a light receiving surface irradiated with incident light. In the drawing, a solid line region represents a semiconductor region formed in the semiconductor substrate 110. A broken line region represents a gate of the MOS transistors 104 to 109 illustrated in FIG. 19. A dotted line region represents a back surface side light shielding unit 170. A dotted line region with oblique hatching represents a front surface side light shielding unit 150. A dotted line region with shaded hatching represents a non-penetrating back surface side light shielding unit 174 to be described later. A two-dot chain line rectangle represents a region of an opening 181 of a light shielding film 180. Furthermore, between the photoelectric conversion unit 101 and the second charge holding unit 102, an in-pixel front surface side light shielding unit 250 and an in-pixel back surface side light shielding unit 270 to be described later are arranged.

In the pixel 100 in the drawing, a semiconductor region 111 of the photoelectric conversion unit 101 is arranged in the semiconductor substrate 110 in the central portion. A semiconductor region 112 of the second charge holding unit 102 is arranged adjacent to an upper side in the drawing of the semiconductor region 111. A gate 121 of the MOS transistor 105 illustrated in FIG. 19 is arranged in the vicinity of the semiconductor region 112. The MOS transistor 105 is the MOS transistor including the semiconductor regions 111 and 112 as a source region and a drain region, respectively. A gate 122 of the MOS transistor 106 is arranged adjacent to a right side in the drawing of the semiconductor region 112, and a semiconductor region 113 of the charge holding unit 103 is arranged adjacent to the gate 122. The MOS transistor 106 is the MOS transistor including the semiconductor regions 112 and 113 as a source region and a drain region, respectively.

A gate 124 of the MOS transistor 107 is arranged adjacent to a lower side in the drawing of the semiconductor region 113, and a semiconductor region 115 is arranged adjacent to the gate 124. The MOS transistor 107 is the MOS transistor including the semiconductor regions 113 and 115 as a source region and a drain region, respectively. A gate 125 of the MOS transistor 108 is arranged adjacent to a lower side in the drawing of the semiconductor region 115, and a semiconductor region 116 is arranged adjacent to the gate 125. The MOS transistor 108 is the MOS transistor including the semiconductor regions 115 and 116 as a drain region and a source region, respectively. A gate 126 of the MOS transistor 109 is arranged adjacent to a lower side in the drawing of the semiconductor region 116, and a semiconductor region 117 is arranged adjacent to the gate 126. The MOS transistor 109 is the MOS transistor including the semiconductor regions 116 and 117 as a drain region and a source region, respectively.

Note that, the semiconductor region 113 and the gate 125 of the MOS transistor 108 are connected to each other by wiring not illustrated. Furthermore, a gate 123 of the MOS transistor 104 and a semiconductor region 114 are arranged adjacent to a left side in the drawing of the semiconductor region 111. The MOS transistor 104 is the MOS transistor including the semiconductor regions 111 and 114 as a source region and a drain region, respectively.

Note that, the charge holding unit 103 and the MOS transistors 107 to 109 in the drawing are used in common by the pixel 100 adjacent to a right side of the pixel 100 in the drawing. The MOS transistor 104 in the drawing is used in common by the pixel 100 adjacent to a left side of the pixel 100 in the drawing.

The in-pixel front surface side light shielding unit 250 is a light shielding unit arranged between the photoelectric conversion unit 101 and the second charge holding unit 102, the light shielding unit formed into the same shape as that of the front surface side light shielding unit 150.

The in-pixel back surface side light shielding unit 270 is a light shielding unit arranged between the photoelectric conversion unit 101 and the second charge holding unit 102, the light shielding unit formed into the same shape as that of the back surface side light shielding unit 170.

By arranging the in-pixel front surface side light shielding unit 250 and the in-pixel back surface side light shielding unit 270, it is possible to shield light between the photoelectric conversion unit 101 and the second charge holding unit 102 in the pixel 100. In combination with the front surface side light shielding unit 150 and the back surface side light shielding unit 170 arranged between the photoelectric conversion units 101 of the adjacent pixels 100, light leaking from the photoelectric conversion unit 101 to the second charge holding unit 102 may be reduced. In the pixel 100 adopting the global shutter type, the charge is held by the second charge holding unit 102 for a relatively long period. When the second charge holding unit 102 is irradiated with incident light, the charge by photoelectric conversion is generated to be held by the second charge holding unit 102. Therefore, noise is generated in the image signal. By arranging the in-pixel front surface side light shielding unit 250 and the in-pixel back surface side light shielding unit 270 described above, it is possible to prevent light from leaking to the second charge holding unit 102 and reduce the noise of the image signal.

The non-penetrating back surface side light shielding unit 174 is a light shielding unit embedded on the back surface side of the semiconductor substrate 110 and having a shape not to penetrate the semiconductor substrate 110. As illustrated in FIG. 19, the MOS transistor 105 is arranged between the photoelectric conversion unit 101 and the second charge holding unit 102, and the charge of the photoelectric conversion unit 101 is transferred to the second charge holding unit 102. A channel region, which is a transfer path of this charge, is formed in the vicinity of the front surface side of the semiconductor substrate 110. In order to secure the channel region of the MOS transistor 105, the non-penetrating back surface side light shielding unit 174 is arranged. Furthermore, the non-penetrating back surface side light shielding unit 174 may also be arranged in the semiconductor substrate 110 in a region where the charge holding unit 102, the MOS transistor 104, and the MOS transistors 107 to 109, which are commonly used by the adjacent pixel 100, are arranged. Note that, the second charge holding unit 102 is an example of a charge holding unit recited in claims.

[Cross-Sectional Configuration of Pixel]

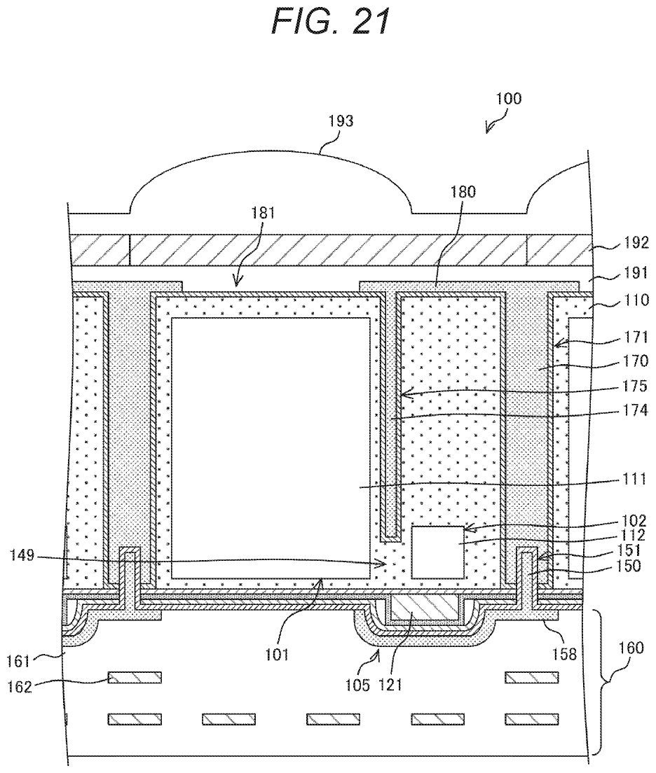

FIG. 21 is a cross-sectional view illustrating a configuration example of the pixel according to the fifth embodiment of the present disclosure. The drawing is the cross-sectional view taken along line a-a′ in FIG. 20, and is a schematic cross-sectional view illustrating a configuration example of the pixel 100 similarly to FIG. 3. The pixel 100 in the drawing is different from the pixel 100 in FIG. 3 in a following point. The second charge holding unit 102 and the MOS transistor 105 are arranged in place of the charge holding unit 103 and the MOS transistor 106 in FIG. 3. The second charge holding unit 102 includes the semiconductor region 112 as described above. The MOS transistor 105 is provided with the gate 121, and transfers the charge in the semiconductor region 111 to the semiconductor region 112. The non-penetrating back surface side light shielding unit 174 is arranged between the photoelectric conversion unit 101 and the second charge holding unit 102.

The non-penetrating back surface side light shielding unit 174 in the drawing may be formed by arranging a light shielding member in a groove 175 formed on the back surface side of the semiconductor substrate 110 into a shape not to penetrate the semiconductor substrate 110. An opening 149 is formed between a bottom of the non-penetrating back surface side light shielding unit 174 and the front surface side of the semiconductor substrate 110. The channel region of the MOS transistor 105 is arranged in the opening 149.

A light shielding film 158 in the drawing may be coupled to the front surface side light shielding unit 150 and formed into a shape to cover the gate 121 of the MOS transistor 105. Furthermore, the light shielding film 180 in the drawing is arranged on an entire surface on the back surface side of the semiconductor substrate 110 except for the opening 181. The second charge holding unit 102 is shielded from light by the light shielding films 158 and 180, the front surface side light shielding unit 150, the back surface side light shielding unit 170, and the non-penetrating back surface side light shielding unit 174. Therefore, leakage of light to the second charge holding unit 102 may be reduced, and mixing of noise may be reduced. Note that, the non-penetrating back surface side light shielding unit 174 in the drawing illustrates an example of being formed to have a narrower cross-sectional width than that of the back surface side light shielding unit 170, but this may be formed to have the same cross-sectional width as that of the back surface side light shielding unit 170.

[Manufacturing Method of Imaging Element]

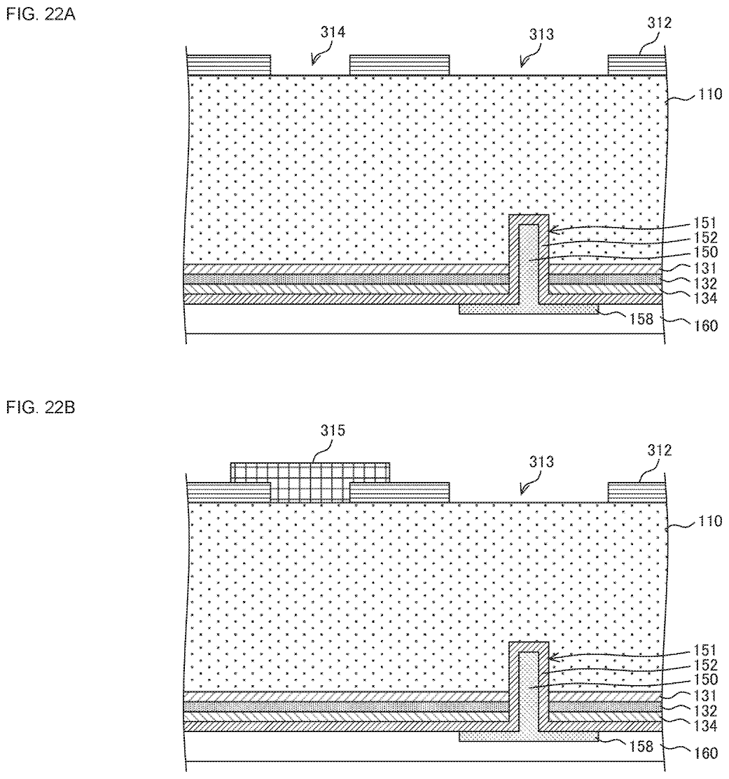

FIGS. 22 to 24 are diagrams illustrating an example of a manufacturing method of the imaging element according to the fifth embodiment of the present disclosure. FIGS. 22 to 24 are diagrams illustrating an example of manufacturing steps of the pixel 100 portion of the imaging element 1. For the sake of convenience, the illustration of the semiconductor region 111 and the like is omitted.

First, the semiconductor region 111 and the like and the insulating film 131 and the like are formed by applying steps from A of FIG. 5 to G of FIG. 7. Next, the front surface side light shielding unit 150 and the in-pixel front surface side light shielding unit 250 (not illustrated) are formed to form a wiring region 160. Next, a support substrate is bonded, the semiconductor substrate 110 is inverted upside down, and the back surface side is ground to thin the semiconductor substrate 110. Next, a hard mask 312 is arranged on the back surface side of the semiconductor substrate 110. The hard mask 312 may include, for example, SiO₂. Furthermore, the hard mask 312 is provided with openings 313 and 314 in regions where a back surface side groove 171 and a groove 175 are formed, respectively (A of FIG. 22). Note that, the opening 313 is also arranged in a region where the in-pixel back surface side light shielding unit 270 is arranged.

Next, a resist 315 having a shape to cover a region where the non-penetrating back surface side light shielding unit 174 is arranged out of the opening 314 of the hard mask 312 is arranged (B of FIG. 22).

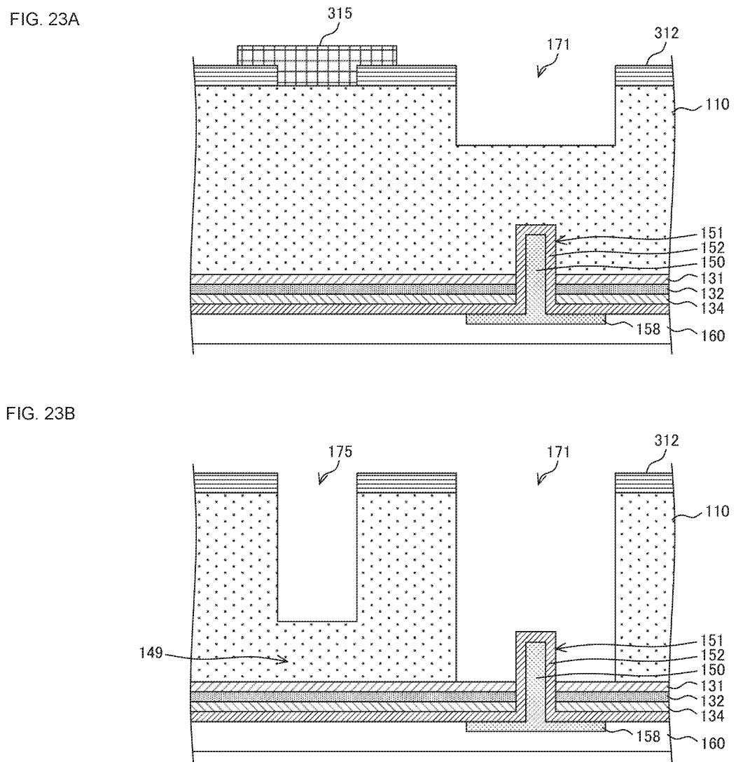

Next, the semiconductor substrate 110 adjacent to the opening 313 is etched using the hard mask 312 and the resist 315 as masks to form the back surface side groove 171 having a depth not to penetrate the semiconductor substrate 110 (C of FIG. 23).

Next, the resist 315 is removed, and the back surface side of the semiconductor substrate 110 is further etched. Therefore, the back surface side groove 171 having a depth to penetrate the semiconductor substrate 110 and the groove 175 having a depth not to penetrate the semiconductor substrate 110 may be formed (D of FIG. 23). Note that, the back surface side groove 171 is also formed in a region where the in-pixel back surface side light shielding unit 270 is arranged.

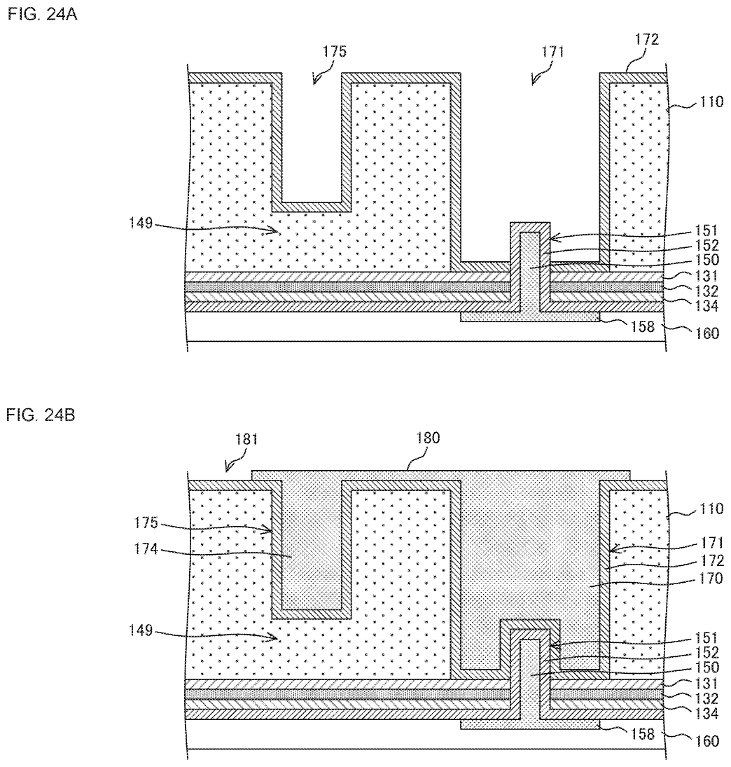

Next, the hard mask 312 is removed. This may be performed by wet etching. Before the wet etching, a resist is arranged in the back surface side groove 171 and the groove 175. This is to protect the back surface side groove 171 and the groove 175. After the hard mask 312 is etched, the resist in the back surface side groove 171 and the groove 175 is removed. Next, an insulating film 172 is arranged on the back surface side of the semiconductor substrate 110 including the back surface side groove 171 and the groove 175 (E of FIG. 24).

Next, a light shielding member is arranged in the back surface side groove 171 and the groove 175 to form the back surface side light shielding unit 170, the non-penetrating back surface side light shielding unit 174, and the in-pixel back surface side light shielding unit 270 (not illustrated), and form the light shielding film 180 (F of FIG. 24).

By the above-described steps, the front surface side light shielding unit 150, the in-pixel front surface side light shielding unit 250, the back surface side light shielding unit 170, the in-pixel back surface side light shielding unit 270, and the non-penetrating back surface side light shielding unit 174 may be formed.

Since a configuration of the imaging element 1 other than this is similar to the configuration of the imaging element 1 described in the first embodiment of the present disclosure, the description thereof is omitted.

As described above, the imaging element 1 of the fifth embodiment of the present disclosure is provided with the pixel 100 including the second charge holding unit 102 and adopting the global shutter type. By arranging the front surface side light shielding unit 150 and the back surface side light shielding unit 170 at the boundary between the pixels 100, it is possible to reduce crosstalk caused by the adjacent pixel 100. Furthermore, by arranging the in-pixel front surface side light shielding unit 250 and the in-pixel back surface side light shielding unit 270 between the photoelectric conversion unit 101 and the second charge holding unit 102, it is possible to reduce light leakage to the second charge holding unit 102 and reduce the noise of the image signal.

### 6. Sixth Embodiment

The imaging element 1 of the fifth embodiment described above uses the back surface side light shielding unit 170 and the non-penetrating back surface side light shielding unit 174 formed to have different depths. In contrast, an imaging element 1 of a sixth embodiment of the present disclosure is different from that of the fifth embodiment described above in using a back surface side light shielding unit 170 formed to have the same depth as that of a non-penetrating back surface side light shielding unit 174.

[Configuration of Light Shielding Unit]

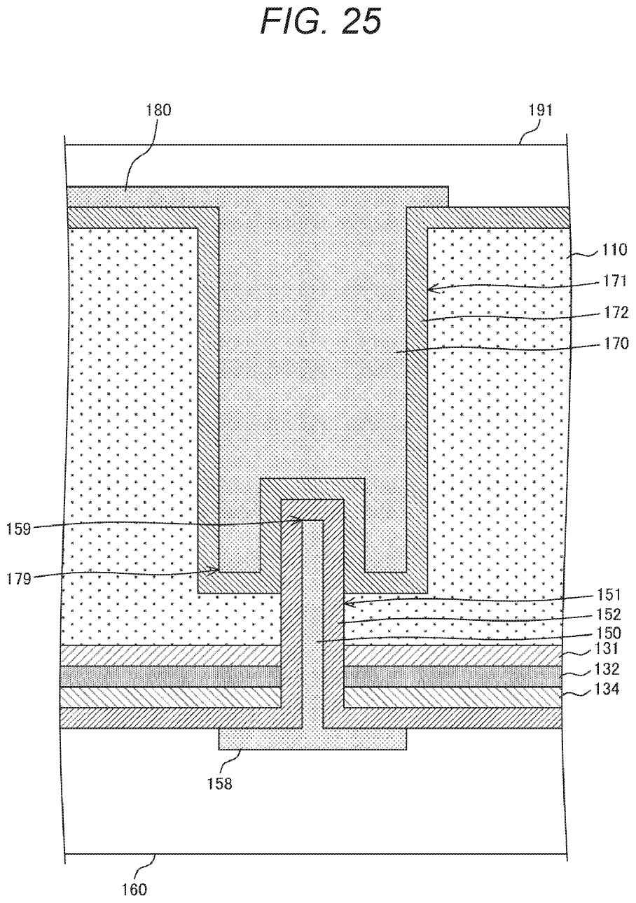

FIG. 25 is a cross-sectional view illustrating a configuration example of a light shielding unit according to the sixth embodiment of the present disclosure. The drawing is a schematic cross-sectional view illustrating the configuration example of the light shielding unit at a boundary between pixels 100. The light shielding unit is different from the light shielding unit illustrated in FIG. 21 in that the back surface side light shielding unit 170 is formed to have a depth not to penetrate a semiconductor substrate 110, and a front surface side light shielding unit 150 is formed across a deep region on a front surface side of the semiconductor substrate 110.

The back surface side light shielding unit 170 in the drawing is formed into a shape not to penetrate the semiconductor substrate 110 and is formed to have the same depth as that of the non-penetrating back surface side light shielding unit 174 illustrated in FIG. 21. Furthermore, an in-pixel back surface side light shielding unit 270 not illustrated is also formed to have the same depth as that of the non-penetrating back surface side light shielding unit 174. Therefore, a groove 175 in which the non-penetrating back surface side light shielding unit 174 is arranged and a back surface side groove 171 may be simultaneously formed.

The front surface side light shielding unit 150 in the drawing is formed into a shape deeper than the front surface side light shielding unit 150 in FIG. 21, and formed into a shape in which a bottom 159 is fitted into a recess formed on a bottom 179 of the back surface side light shielding unit 170. Note that, an in-pixel front surface side light shielding unit 250 is also formed into a shape similar to that of the front surface side light shielding unit 150 in the drawing.

Since a configuration of the imaging element 1 other than this is similar to the configuration of the imaging element 1 described in the fifth embodiment of the present disclosure, the description thereof is omitted.

As described above, a manufacturing step of the imaging element 1 of the sixth embodiment of the present disclosure may be simplified by forming the back surface side light shielding unit 170 and the in-pixel back surface side light shielding unit 270 to have the same depth as that of the non-penetrating back surface side light shielding unit 174.

### 7. Seventh Embodiment

In the imaging element 1 of the sixth embodiment described above, one front surface side light shielding unit 150 is used. In contrast, an imaging element 1 of a seventh embodiment of the present disclosure is different from that of the sixth embodiment described above in using two front surface side light shielding units 150.

[Configuration of Light Shielding Unit]

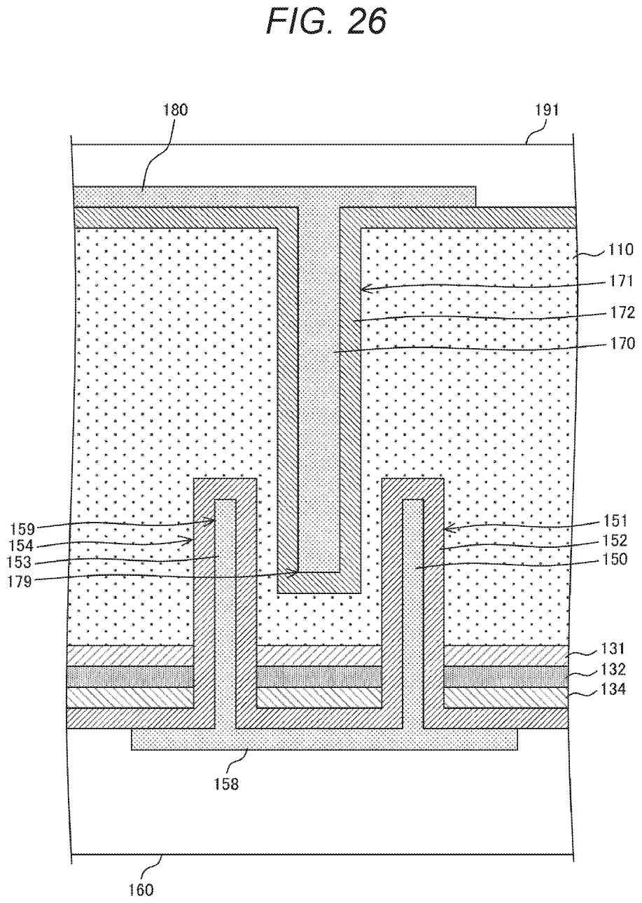

FIG. 26 is a cross-sectional view illustrating a configuration example of a light shielding unit according to the seventh embodiment of the present disclosure. Similarly to FIG. 25, the drawing is a schematic cross-sectional view illustrating the configuration example of the light shielding unit at a boundary between pixels 100. The light shielding unit is different from the light shielding unit illustrated in FIG. 25 in that a front surface side light shielding unit 153 is further arranged on a front surface side of a semiconductor substrate 110, and a back surface side light shielding unit 170 is arranged between the front surface side light shielding units 150 and 153.

The front surface side light shielding unit 153 in the drawing is a light shielding unit arranged in parallel with the front surface side light shielding unit 150, similarly to the front surface side light shielding unit 153 illustrated in FIG. 10. Furthermore, the front surface side light shielding units 150 and 153 in the drawing are formed to have a depth similar to that of the front surface side light shielding unit 150 in the FIG. 25. The back surface side light shielding unit 170 in the drawing is formed to have a narrow cross section similar to that of the back surface side light shielding unit 170 illustrated in FIG. 10. Furthermore, the back surface side light shielding unit 170 in the drawing is formed to have the same depth as that of a non-penetrating back surface side light shielding unit 174, similarly to the back surface side light shielding unit 170 in FIG. 25. Therefore, a groove 175 in which the non-penetrating back surface side light shielding unit 174 is arranged and a back surface side groove 171 may be simultaneously formed.

Since a configuration of the imaging element 1 other than this is similar to the configuration of the imaging element 1 described in the sixth embodiment of the present disclosure, the description thereof is omitted.

As described above, the imaging element 1 of the seventh embodiment of the present disclosure may widen a region of the pixel 100 adopting a global shutter type by arranging the back surface side light shielding unit 170 having a narrow width between the two front surface side light shielding units 150 and 153.

### 8. Eighth Embodiment

In the imaging element 1 of the fifth embodiment described above, the back surface side light shielding unit 170 is arranged in the well region of the semiconductor substrate 110. In contrast, an imaging element 1 of an eighth embodiment of the present disclosure is different from that of the fifth embodiment described above in that a solid phase diffusion layer is arranged adjacent to a back surface side light shielding unit 170.

[Configuration of Pixel]

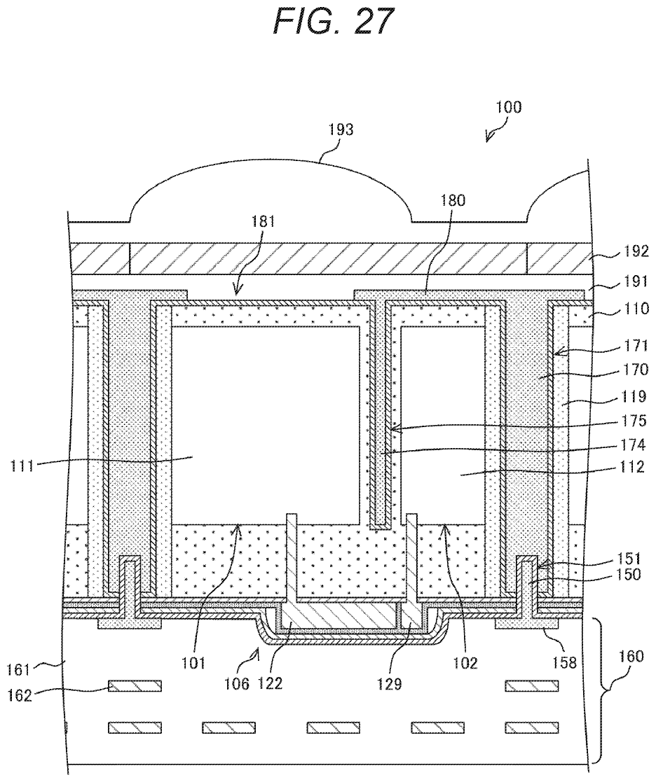

FIG. 27 is a diagram illustrating a configuration example of a pixel according to the eighth embodiment of the present disclosure. Similarly to FIG. 21, the drawing is a schematic cross-sectional view illustrating a configuration example of a pixel 100. The pixel 100 in the drawing is different from the pixel 100 in FIG. 21 in a following point. A solid phase diffusion layer 119 is arranged between semiconductor regions 111 and 112 and a back surface side light shielding unit 170. Furthermore, the semiconductor regions 111 and 112 are separated from a front surface side of a semiconductor substrate, and a MOS transistor 106 configured as a vertical transistor is arranged.

Similarly to the solid phase diffusion layer 119 in FIG. 12, the solid phase diffusion layer 119 is arranged adjacent to a back surface side light shielding unit 170. The semiconductor region 111 of a photoelectric conversion unit 101 is arranged adjacent to the solid phase diffusion layer 119 and arranged in a deep region from the front surface side of the semiconductor substrate 110, similarly to the semiconductor region 111 in FIG. 12.

The semiconductor region 112 of a second charge holding unit 102 in the drawing is arranged adjacent to the solid phase diffusion layer 119 and arranged in the deep region from the front surface side of the semiconductor substrate 110, similarly to the semiconductor region 111 in the drawing. By being arranged adjacent to the solid phase diffusion layer 119, a saturation charge amount may be improved.

The MOS transistor 106 in the drawing is configured as the vertical transistor and is provided with a gate 122 and a gate 129. The gate 122 is formed into a shape embedded at a position to reach the semiconductor region 111 from the front surface side of the semiconductor substrate 110, and the gate 129 is formed into a shape embedded at a position to reach the semiconductor region 112 from the front surface side of the semiconductor substrate 110. By applying a control signal to the gates 122 and 129, a channel from the semiconductor region 111 to the semiconductor region 112 via the front surface side of the semiconductor substrate 110 is formed. A charge in the semiconductor region 111 may be transferred to the semiconductor region 112.

A back surface side groove 171 in the drawing may be formed by etching to remove a filling member 118 illustrated in F of FIG. 14 from a back surface side of the semiconductor substrate 110. The etching of the filling member 118 may be performed simultaneously with etching when forming a groove 175 illustrated in D of FIG. 23.

Since a configuration of the imaging element 1 other than this is similar to the configuration of the imaging element 1 described in the fifth embodiment of the present disclosure, the description thereof is omitted.

As described above, the imaging element 1 of the eighth embodiment of the present disclosure may improve a capacity of the photoelectric conversion unit 101 and the second charge holding unit 102 by arranging the solid phase diffusion layer 119 in the pixel 100 adopting a global shutter type.

### 9. Ninth Embodiment

The imaging element 1 of the first embodiment described above is provided with the front surface side light shielding unit 150 and the back surface side light shielding unit 170. In contrast, an imaging element 1 of a ninth embodiment of the present disclosure is different from that of the first embodiment described above in including a light shielding unit in a different shape.

Since a circuit configuration of a pixel 100 in the imaging element 1 in the ninth embodiment of the present disclosure is similar to the circuit configuration illustrated in FIG. 2, the description thereof is omitted.

[Cross-Sectional Configuration of Pixel]

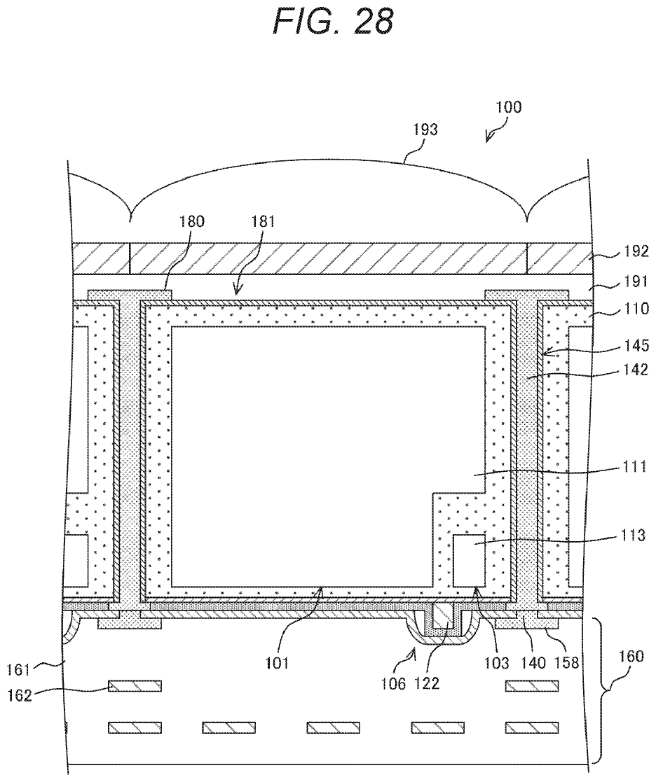

FIG. 28 is a cross-sectional view illustrating a configuration example of the pixel according to the ninth embodiment of the present disclosure. Similarly to FIG. 3, the drawing is a schematic cross-sectional view illustrating the configuration example of the pixel 100. The pixel 100 is different from the pixel 100 in FIG. 3 in including a front surface insulating film light shielding unit 140 and a semiconductor substrate light shielding unit 142 in place of the front surface side light shielding unit 150 and the back surface side light shielding unit 170.

The front surface insulating film light shielding unit 140 is arranged on an insulating film 134 at a boundary between the pixels 100 to shield incident light. The front surface insulating film may be formed by arranging a light shielding member in a groove (groove 141) formed on the insulating film 134. The light shielding member may include a metal material similar to that of a light shielding film 158. Furthermore, the front surface insulating film light shielding unit 140 may be coupled to the light shielding film 158. The front surface insulating film light shielding unit 140 may include the same material as that of the light shielding film 158. Hereinafter, the front surface insulating film light shielding unit 140 and the light shielding film 158 including W are assumed. Note that, the insulating film 134 is an insulating film arranged between a semiconductor substrate 110 and a wiring region 160 as described above, the insulating film arranged on a front surface side of the semiconductor substrate 110. The insulating film 134 is an example of a front surface insulating film recited in claims.

The semiconductor substrate light shielding unit 142 is formed into a shape to penetrate the semiconductor substrate 110 at the boundary between the pixels 100 to shield the incident light. Furthermore, the semiconductor substrate light shielding unit 142 is formed into a shape in contact with a bottom of the front surface insulating film light shielding unit 140. The semiconductor substrate light shielding unit 142 may be formed by arranging a light shielding member in a penetrating groove 145, which is a groove that penetrates the semiconductor substrate 110. Furthermore, the semiconductor substrate light shielding unit 142 may be coupled to a light shielding film 180, and may include the same material as that of the light shielding film 180. Hereinafter, the semiconductor substrate light shielding unit 142 and the light shielding film 180 including W are assumed.

[Configuration of Light Shielding Unit]

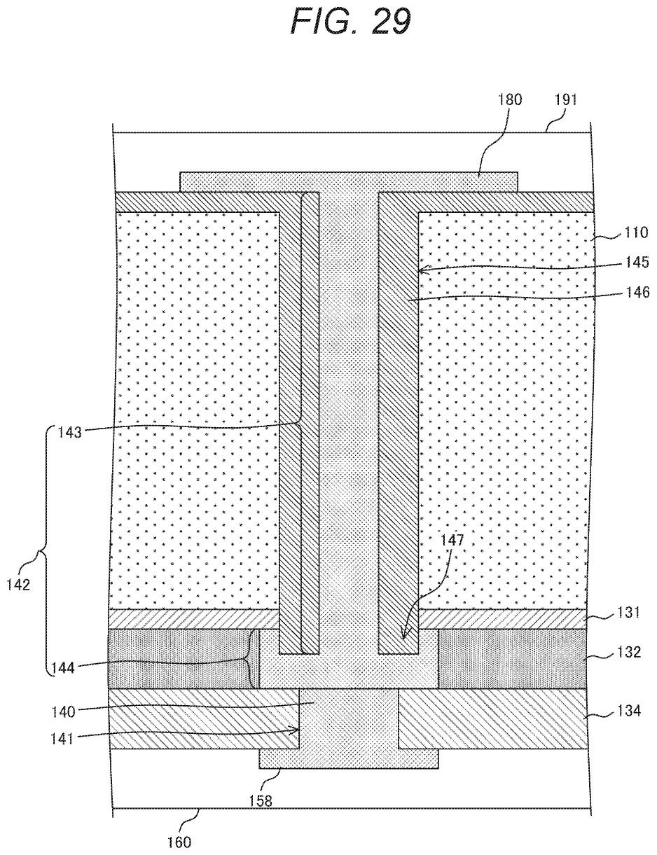

FIG. 29 is a cross-sectional view illustrating a configuration example of the light shielding unit according to the ninth embodiment of the present disclosure. The drawing is a schematic cross-sectional view illustrating a configuration example of the front surface insulating film light shielding unit 140 and the semiconductor substrate light shielding unit 142 at the boundary between the pixels 100.

The insulating films 131, 132, and 134 are sequentially stacked to be arranged between the front surface side of the semiconductor substrate 110 and the wiring region 160. An SiO₂ film may be used as the insulating film 131 and the insulating film 134. An SiN film may be used as the insulating film 132. In this manner, the insulating film 132 is an insulating film arranged between the semiconductor substrate 110 and the insulating film 134, the insulating film arranged on a lower layer of the insulating film 134. The insulating film 132 is an example of a lower layer insulating film recited in claims.

As illustrated in the drawing, the front surface insulating film light shielding unit 140 is arranged in the groove 141 formed on the insulating film 134. As described above, the front surface insulating film light shielding unit 140 is formed on the insulating film arranged between the semiconductor substrate 110 and the wiring region 160. In addition to the insulating film 134, an insulating layer 161 on a lowermost layer of the wiring region 160 may also be added to this insulating film.

The semiconductor substrate light shielding unit 142 in the drawing is arranged in a region of the semiconductor substrate 110 and the insulating films 131 and 132. The semiconductor substrate light shielding unit 142 includes a first semiconductor substrate light shielding unit 143 and a second semiconductor substrate light shielding unit 144.

The first semiconductor substrate light shielding unit 143 is arranged in the penetrating groove 145 that penetrates the semiconductor substrate 110. The penetrating groove 145 may be formed from a back surface side of the semiconductor substrate 110. The penetrating groove 145 in the drawing illustrates an example of being formed to have a depth to penetrate the semiconductor substrate 110 and the insulating film 131 and reach the region of the insulating film 132. Furthermore, an insulating film 146 is arranged between the penetrating groove 145 and the first semiconductor substrate light shielding unit 143 in the drawing. The insulating film 146 may include, for example, SiO₂. The insulating film 146 in the drawing illustrates an example of being formed into a shape that a bottom thereof reaches the region of the insulating film 132. Note that, by arranging the insulating film 146, it is possible to prevent etching of the semiconductor substrate 110 when etching the insulating film 132 described later. Note that, a fixed charge film illustrated in FIG. 4 may be arranged between the penetrating groove 145 and the insulating film 146.

The second semiconductor substrate light shielding unit 144 is arranged in the region of the insulating film 132. The second semiconductor substrate light shielding unit 144 is a light shielding unit arranged in a region where the insulating film 132 in the vicinity of a bottom of the first semiconductor substrate light shielding unit 143 is removed. Hereinafter, the region where the insulating film 132 in the vicinity of the bottom of the first semiconductor substrate light shielding unit 143 is removed is referred to as a lower layer insulating film removed region. The second semiconductor substrate light shielding unit 144 is a light shielding unit formed in the lower layer insulating film removed region.

The insulating film 132 may be removed for forming the lower layer insulating film removed region by etching the insulating film 132 via the above-described penetrating groove 145. For example, wet etching may be applied to the etching. In the etching, by arranging the insulating film 132 having a selection ratio higher than that of the insulating films 131 and 134, the insulating film 132 in the vicinity of the penetrating groove 145 may be easily removed. The lower layer insulating film removed region may be easily formed. As described above, the insulating films 131 and 134 include SiO₂, and the insulating film 132 includes SiN. In this case, the insulating film 132 in the vicinity of the penetrating groove 145 may be selectively removed by etching using hot phosphoric acid. At that time, a bottom surface of the front surface insulating film light shielding unit 140 has a shape exposed to the lower layer insulating film removed region.

After the lower layer insulating film removed region is formed by performing the above-described etching, a light shielding member is embedded from the penetrating groove 145 on the back surface side of the semiconductor substrate 110. For example, the first semiconductor substrate light shielding unit 143 and the second semiconductor substrate light shielding unit 144 may be formed by arranging W in the lower layer insulating film removed region and the penetrating groove 145 by sputtering and CVD. Furthermore, the bottom surface of the front surface insulating film light shielding unit 140 exposed to the lower layer insulating film removed region and the second semiconductor substrate light shielding unit 144 are coupled to each other.

A cross-sectional width of the second semiconductor substrate light shielding unit 144 may be made wider than that of the penetrating groove 145. At that time, the penetrating groove 145 is formed to have a depth to reach a region of the second semiconductor substrate light shielding unit 144, and the insulating film 146 is arranged adjacent to an inner wall thereof. Therefore, it is possible to form into a shape in which the bottoms of the first semiconductor substrate light shielding unit 143 and the insulating film 146 are fitted to a recess 147 formed in the second semiconductor substrate light shielding unit 144.

[Effect of Light Shielding Unit]

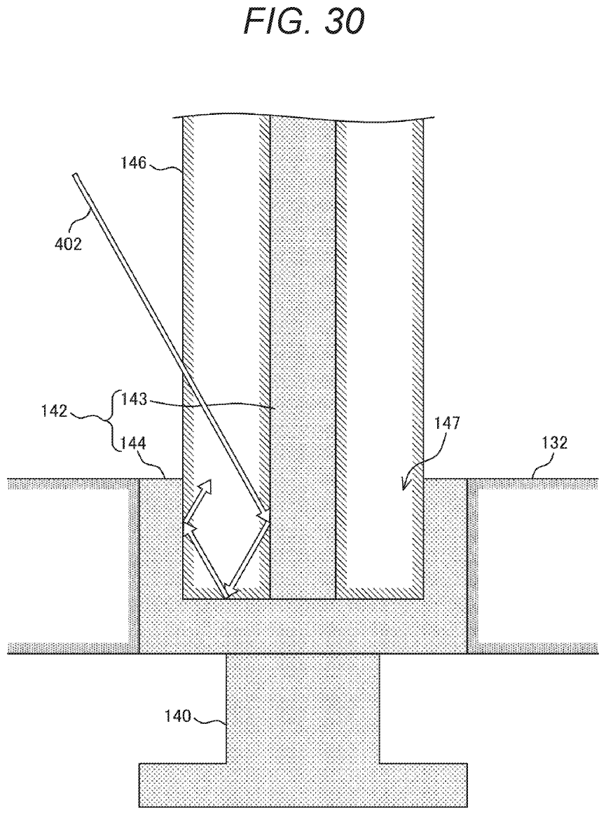

FIG. 30 is a cross-sectional view illustrating an example of light shielding according to the ninth embodiment of the present disclosure. The drawing is a diagram illustrating a simplified configuration of the insulating film 132, the front surface insulating film light shielding unit 140, the semiconductor substrate light shielding unit 142 (the first semiconductor substrate light shielding unit 143 and the second semiconductor substrate light shielding unit 144), and the insulating film 146, the diagram illustrating a state of light shielding. As described above, the bottoms of the first semiconductor substrate light shielding unit 143 and the insulating film 146 are formed into shapes fitted into the recess 147 formed in the second semiconductor substrate light shielding unit 144.

The first semiconductor substrate light shielding unit 143, the second semiconductor substrate light shielding unit 144, and the front surface insulating film light shielding unit 140 are coupled to each other, and light shielding ability at the boundary between the pixels 100 may be improved. As illustrated in the drawing, incident light 402 incident on the bottom of the first semiconductor substrate light shielding unit 143 is reflected by wall surfaces of the recess 147 of the first semiconductor substrate light shielding unit 143 and the second semiconductor substrate light shielding unit 144, and leakage to the adjacent pixels 100 may be prevented. Furthermore, the wall forming the recess 147 of the second semiconductor substrate light shielding unit 144 has a shape interposed between the insulating film 132 and the insulating film 146, and peeling of W forming the second semiconductor substrate light shielding unit 144 may be prevented.

[Manufacturing Method of Imaging Element]

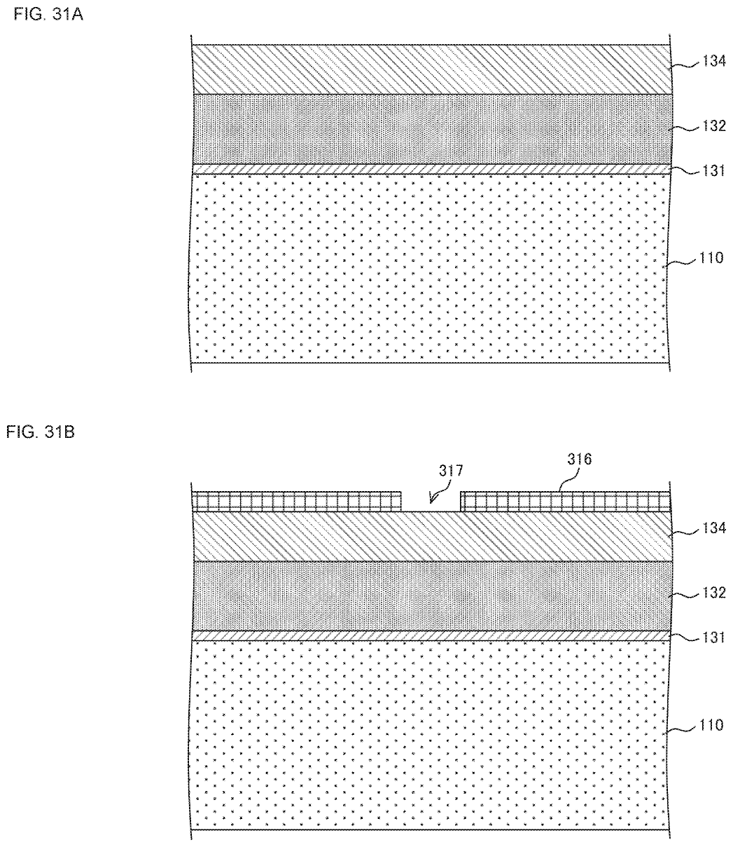

FIGS. 31 to 36 are diagrams illustrating an example of a manufacturing method of the imaging element according to the ninth embodiment of the present disclosure. FIGS. 31 to 36 are diagrams illustrating an example of manufacturing steps of the pixel 100 portion of the imaging element 1. For the sake of convenience, the illustration of the semiconductor region 111 and the like is omitted.

First, the semiconductor region 111 and the like are formed in the semiconductor substrate 110. Next, the insulating films 131, 132, and 134 are formed. The insulating film 131 may be formed by depositing an SiO₂ film by thermal oxidation, for example. The insulating film 132 may be formed by depositing an SiN film by CVD, for example. The insulating film 134 may be formed by depositing an SiO₂ film by CVD, for example (A of FIG. 31).

Next, a resist 316 is arranged on the front surface side of the semiconductor substrate 110. In the resist 316, an opening 317 is arranged in a region where the groove 141 is formed (B of FIG. 31).

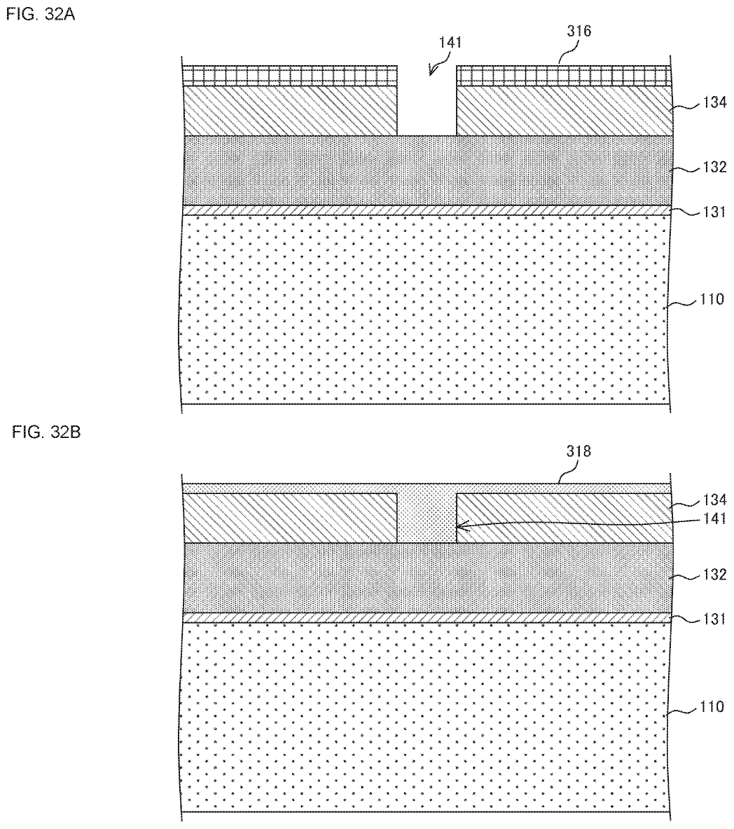

Next, using the resist 316 as a mask, the insulating film 134 adjacent to the opening 317 is etched to form the groove 141. Dry etching may be applied to the etching (C of FIG. 32).

Next, the resist 316 is removed and a film 318 of a light shielding member is arranged on the front surface side of the semiconductor substrate 110. The film 318 of the light shielding member may be arranged by depositing a W film by CVD and sputtering. Therefore, the front surface insulating film light shielding unit 140 may be formed (D of FIG. 23). Note that, this step corresponds to a front surface insulating film light shielding unit forming step.

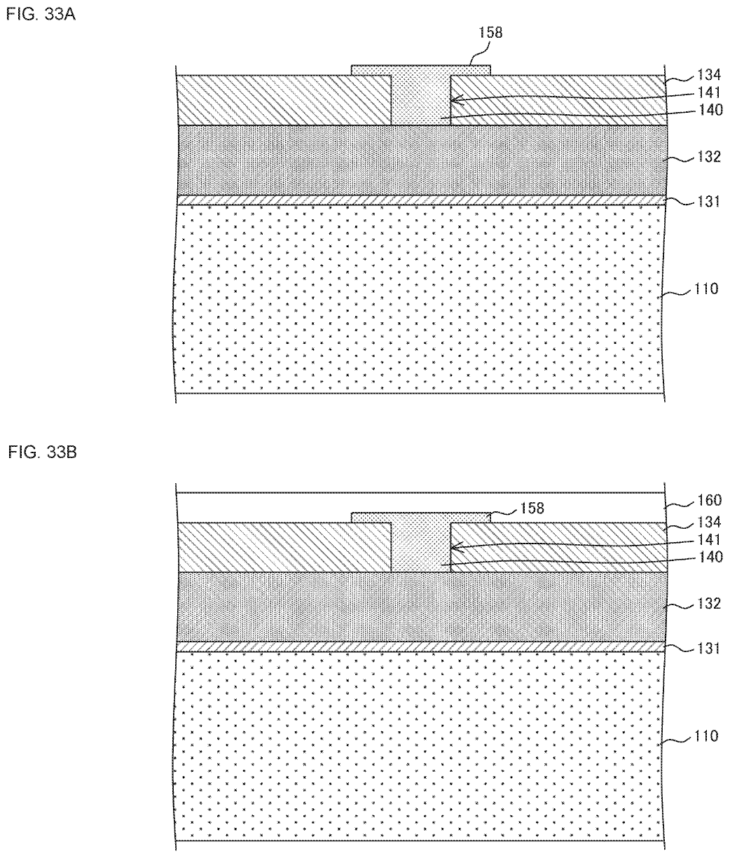

Next, the film 318 of the light shielding member is processed to form the light shielding film 158 (E of FIG. 33). Next, the wiring region 160 is formed on the front surface side of the semiconductor substrate 110 (F of FIG. 24).

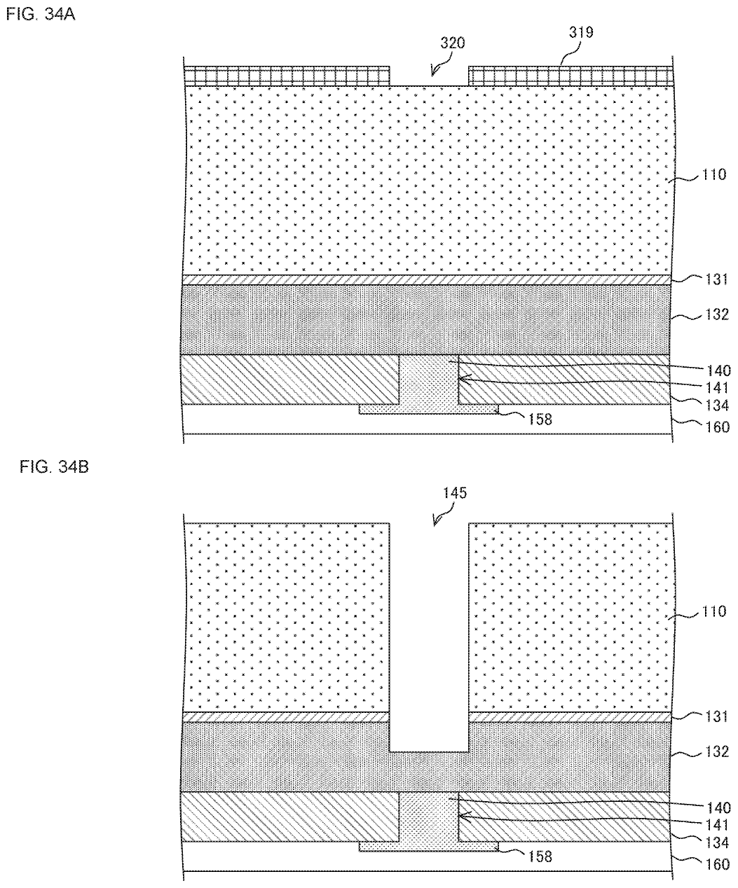

Next, a support substrate (not illustrated) is bonded adjacent to the wiring region 160, the semiconductor substrate 110 is inverted upside down, and the back surface side is ground to thin the semiconductor substrate 110. Next, a resist 319 is arranged on the back surface side of the semiconductor substrate 110. In the resist 319, an opening 320 is arranged in a region where the penetrating groove 145 is formed (G of FIG. 34).

Next, using the resist 319 as a mask, the semiconductor substrate 110 and the insulating film 131 are etched to form the penetrating groove 145. At that time, a part of the insulating film 132 is further etched. Dry etching may be applied to the etching, for example (H of FIG. 34).

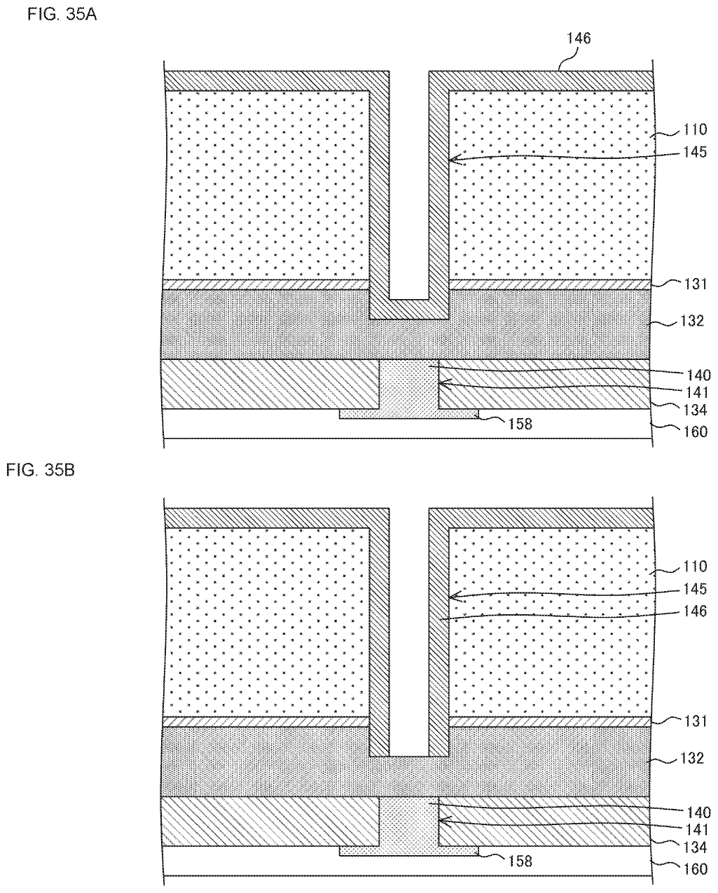

Next, the insulating film 146 is arranged on the back surface side of the semiconductor substrate 110 including the penetrating groove 145. This may be arranged by depositing an SiO₂ film by ALD, for example (I of FIG. 35).

Next, the insulating film 146 adjacent to the bottom surface of the penetrating groove 145 is removed. This may be performed by anisotropic dry etching (J of FIG. 35). By this step, it is possible to cover only the side surface of the penetrating groove 145 with the insulating film 146.

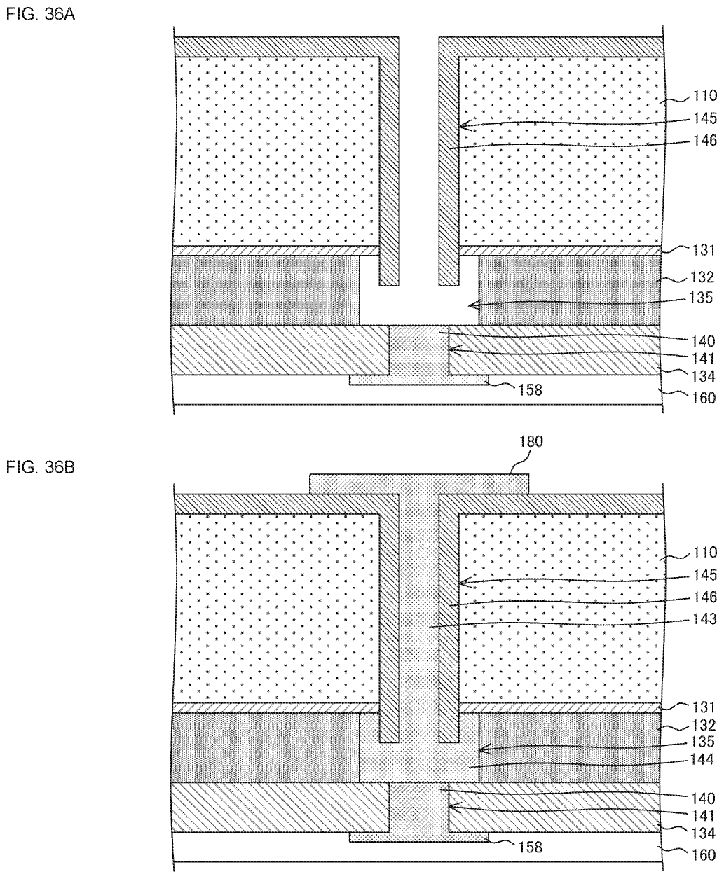

Next, the insulating film 132 is etched via the penetrating groove 145, and the insulating film 132 in the vicinity of the penetrating groove 145 is removed. The etching may be performed by wet etching. In the wet etching, a chemical solution that elutes SiN forming the insulating film 132 and does not elute SiO₂ forming the insulating films 131, 134, and 146 is used. Furthermore, by managing etching time, it is possible to etch the insulating film 132 in a desired range. Since the wet etching is isotropic etching, the insulating film 132 around the penetrating groove 145 is etched to be removed. Therefore, the lower layer insulating film removed region 135 may be formed (K of FIG. 36).

Next, a film of a light shielding member is arranged on the back surface side of the semiconductor substrate 110 including the penetrating groove 145 and the lower layer insulating film removed region 135 to form the semiconductor substrate light shielding unit 142 (the first semiconductor substrate light shielding unit 143 and the second semiconductor substrate light shielding unit 144). This may be performed by depositing a W film by sputtering and CVD. This step corresponds to a semiconductor substrate light shielding unit forming step. Next, the film of the light shielding member is processed to form the light shielding film 180 (L of FIG. 36).

By the above-described steps, the front surface insulating film light shielding unit 140 and the semiconductor substrate light shielding unit 142 may be formed.

The front surface insulating film light shielding unit 140 having a shape embedded in the insulating film 134 on the front surface side of the semiconductor substrate 110 is arranged, and by forming the penetrating groove 145 from the back surface side of the semiconductor substrate 110 to arrange the semiconductor substrate light shielding unit 142, this is coupled to the front surface insulating film light shielding unit 140. The insulating film 132 is etched in dry etching when forming the penetrating groove 145. However, a region of the dry etching is limited to a part of the insulating film 132. The remaining insulating film 132 is etched by wet etching. Dry etching of SiN forming the insulating film 132 is reduced, and damage to the semiconductor substrate 110 may be reduced. Furthermore, since the bottom of the front surface insulating film light shielding unit 140 is not etched at the time of dry etching for forming the penetrating groove 145, contamination of the semiconductor substrate 110 by the light shielding member (W) forming the front surface insulating film light shielding unit 140 may be prevented. As a result, occurrence of crystal defects in the semiconductor substrate 110 may be reduced, and noise caused by the crystal defects may be reduced.

Since a configuration of the imaging element 1 other than this is similar to the configuration of the imaging element 1 described in the first embodiment of the present disclosure, the description thereof is omitted.

As described above, the imaging element 1 of the ninth embodiment of the present disclosure may shield the incident light incident from the adjacent pixel 100 by arranging the front surface insulating film light shielding unit 140 and the semiconductor substrate light shielding unit 142 at the boundary between the pixels 100. Occurrence of crosstalk may be reduced.

### 10. Tenth Embodiment

In the imaging element 1 of the ninth embodiment described above, the lower layer insulating film removed region is formed by etching the insulating film 132. In contrast, an imaging element 1 of a tenth embodiment of the present disclosure is different from that of the ninth embodiment described above in including an etching suppression unit adjacent to the insulating film 132, which serves as the lower layer insulating film removed region.

[Configuration of Light Shielding Unit]

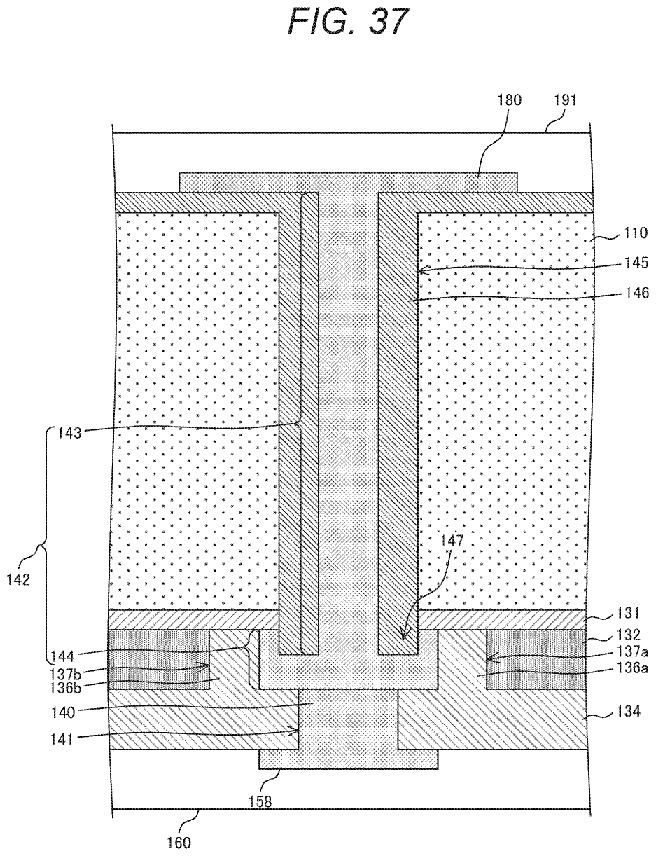

FIG. 37 is a cross-sectional view illustrating a configuration example of a light shielding unit according to the tenth embodiment of the present disclosure. The drawing is a schematic cross-sectional view illustrating a configuration example of the front surface insulating film light shielding unit 140 and the semiconductor substrate light shielding unit 142 at the boundary between the pixels 100. The pixel 100 is different from the pixel 100 in FIG. 29 in that an etching suppression unit 136 is arranged between a second semiconductor substrate light shielding unit 144 and the insulating film 132.

The etching suppression unit 136 suppresses etching at the time of etching for forming a lower layer insulating film removed region 135 on an insulating film 132. The etching suppression unit 136 may include a member having a lower selection ratio in the etching than that of the insulating film 132. Such etching suppression unit 136 is referred to as an etching stopper. The etching suppression unit 136 is arranged adjacent to a region of the insulating film 132 forming the lower layer insulating film removed region 135, and separates the region of the insulating film 132, which serves as the lower layer insulating film removed region 135, by etching.

The drawing illustrates an example of two groove-shaped etching suppression units 136a and 136b arranged on the insulating film 132 at the boundary between the pixels 100. The etching suppression units 136a and 136b are arranged in two grooves 137a and 137b formed in parallel on the insulating film 132 at the boundary between the pixels 100, respectively. The etching suppression units 136a and 136b may include, for example, SiO₂. Furthermore, the etching suppression units 136a and 136b may include the same member as that of an insulating film 134, and may be formed simultaneously with the insulating film 134.

The etching suppression units 136a and 136b are arranged, and etching is performed via a penetrating groove 145. A region of the insulating film 132 to be etched is a region separated by the etching suppression units 136a and 136b. It is not necessary to manage and the like etching time illustrated in K of FIG. 36, and formation of the lower layer insulating film removed region 135 may be simplified.

[Manufacturing Method of Imaging Element]

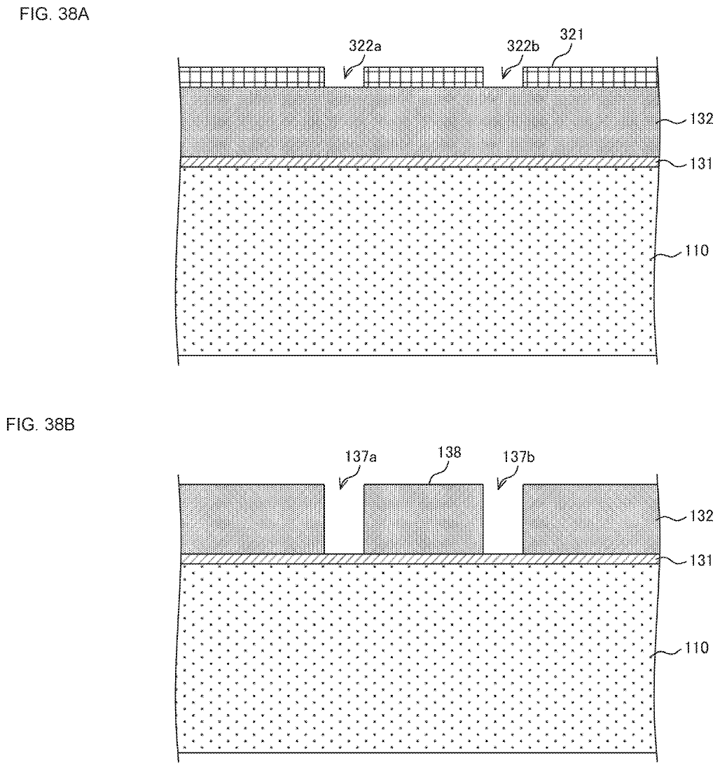

FIGS. 38 to 40 are diagrams illustrating an example of a manufacturing method of the imaging element according to the tenth embodiment of the present disclosure. FIGS. 38 to 40 are diagrams illustrating an example of manufacturing steps of the pixel 100 portion of the imaging element 1. For the sake of convenience, the illustration of the semiconductor region 111 and the like is omitted.

First, an insulating film 131 and the insulating film 132 are formed on a front surface side of a semiconductor substrate 110. Next, a resist 321 is arranged on the front surface side of the semiconductor substrate 110. In the resist 321, openings 322a and 322b are arranged in regions where the above-described grooves 137a and 137b are formed, respectively (A in FIG. 38).

Next, using the resist 321 as a mask, the insulating film 132 is etched to form the grooves 137a and 137b. Dry etching may be applied to the etching. Next, the resist 321 is removed (B of FIG. 38).

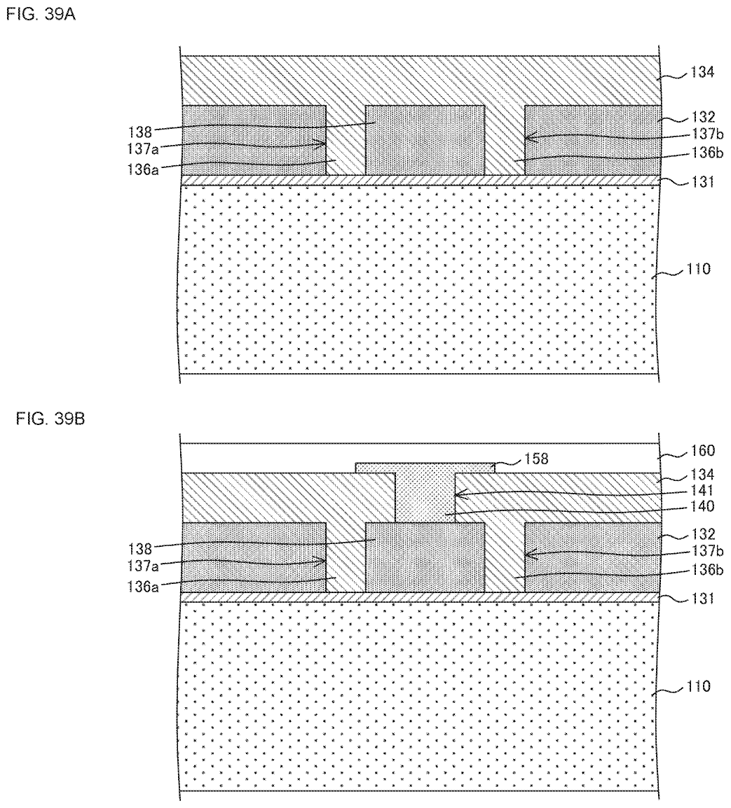

Next, the insulating film 134 is arranged on the front surface side of the semiconductor substrate 110. At that time, the member forming the insulating film 134 is arranged in the grooves 137a and 137b. Therefore, the etching suppression units 136a and 136b may be formed (C of FIG. 39).

Next, the front surface insulating film light shielding unit 140, a light shielding film 158, and a wiring region 160 are arranged on the front surface side of the semiconductor substrate 110 (D of FIG. 39).

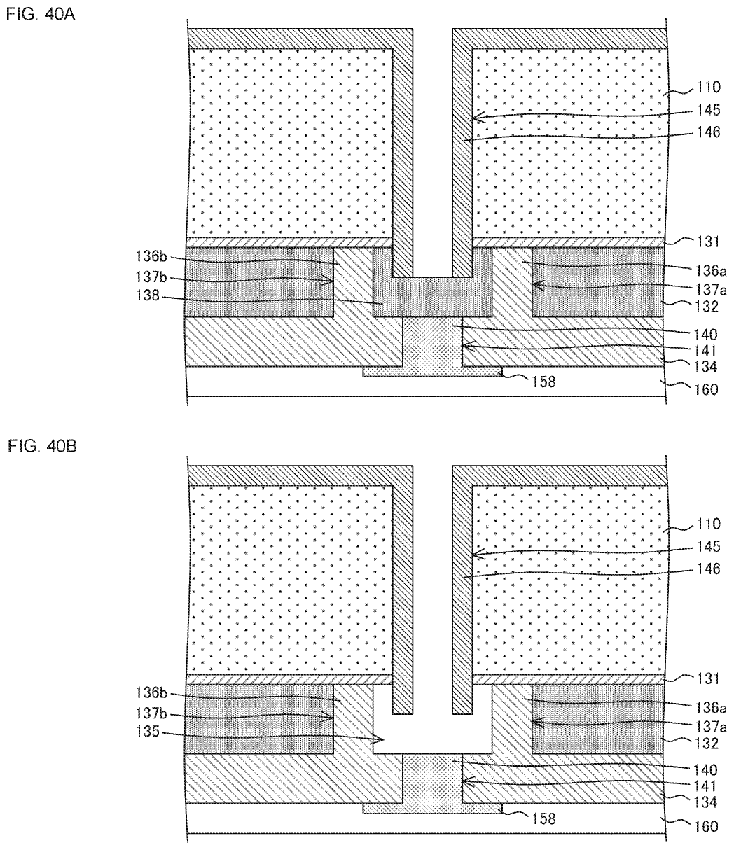

Next, by applying the steps illustrated in FIGS. 34 and 35, the penetrating groove 145 and an insulating film 146 are arranged on a back surface side of the semiconductor substrate 110, and the insulating film 146 adjacent to a bottom surface of the penetrating groove 145 is removed (E of FIG. 40).

Next, the etching is performed via the penetrating groove 145, and the insulating film 132 between the etching suppression units 136a and 136b is removed. The etching may be performed by wet etching by heat phosphoric acid. Therefore, the lower layer insulating film removed region 135 may be formed (F of FIG. 40).

Next, a film of a light shielding member is arranged on the back surface side of the semiconductor substrate 110 including the penetrating groove 145 and the lower layer insulating film removed region 135 to form a first semiconductor substrate light shielding unit 143 and the second semiconductor substrate light shielding unit 144. Next, the film of the light shielding member is processed to form a light shielding film 180.

By the above-described steps, the front surface insulating film light shielding unit 140 and the semiconductor substrate light shielding unit 142 may be formed.

Since a configuration of the imaging element 1 other than this is similar to the configuration of the imaging element 1 described in the ninth embodiment of the present disclosure, the description thereof is omitted.

As described above, in the imaging element 1 of the tenth embodiment of the present disclosure, the etching suppression unit 136 is arranged and the insulating film 132 is etched. The etching region for forming the lower layer insulating film removed region 135 may be limited, and the manufacturing step of the imaging element may be simplified.

### 11. Eleventh Embodiment

The imaging element 1 of the ninth embodiment described above performs the rolling shutter type imaging. In contrast, an imaging element 1 of an eleventh embodiment of the present disclosure is different from that of the ninth embodiment described above in performing imaging of a global shutter type.

Since a circuit configuration of a pixel 100 in the imaging element 1 of the eleventh embodiment of the present disclosure is similar to the circuit configuration illustrated in FIG. 19, the description thereof is omitted.

[Configuration of Pixel]

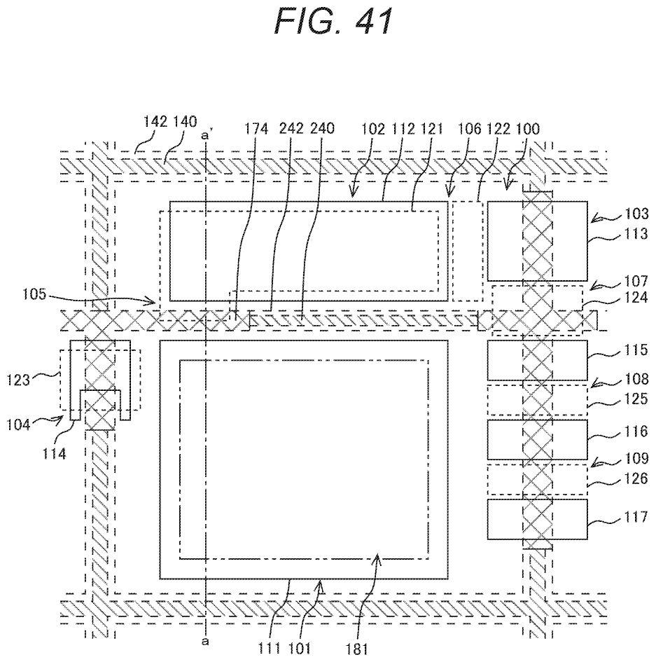

FIG. 41 is a plane view illustrating a configuration example of the pixel according to the eleventh embodiment of the present disclosure. Similarly to FIG. 20, the drawing is a plane view illustrating a configuration example of the pixel 100. The pixel 100 in the drawing is different from the pixel 100 in FIG. 20 in a following point. The pixel 100 in the drawing is provided with a front surface insulating film light shielding unit 140 and a semiconductor substrate light shielding unit 142 in place of a front surface side light shielding unit 150 and a back surface side light shielding unit 170. Furthermore, the pixel 100 in the drawing is provided with an in-pixel front surface insulating film light shielding unit 240 and an in-pixel semiconductor substrate light shielding unit 242 in place of an in-pixel front surface side light shielding unit 250 and an in-pixel back surface side light shielding unit 270.

Here, the in-pixel front surface insulating film light shielding unit 240 is a light shielding unit arranged between a photoelectric conversion unit 101 and a second charge holding unit 102, and is a light shielding unit formed into the same shape as that of the front surface insulating film light shielding unit 140. Furthermore, the in-pixel semiconductor substrate light shielding unit 242 is a light shielding unit arranged between the photoelectric conversion unit 101 and the second charge holding unit 102, and is a light shielding unit formed into the same shape as that of the semiconductor substrate light shielding unit 142.

Since a plane configuration of the pixel 100 other than this is similar to the plane configuration of the pixel 100 illustrated in FIG. 20, the description thereof is omitted.

[Cross-Sectional Configuration of Pixel]

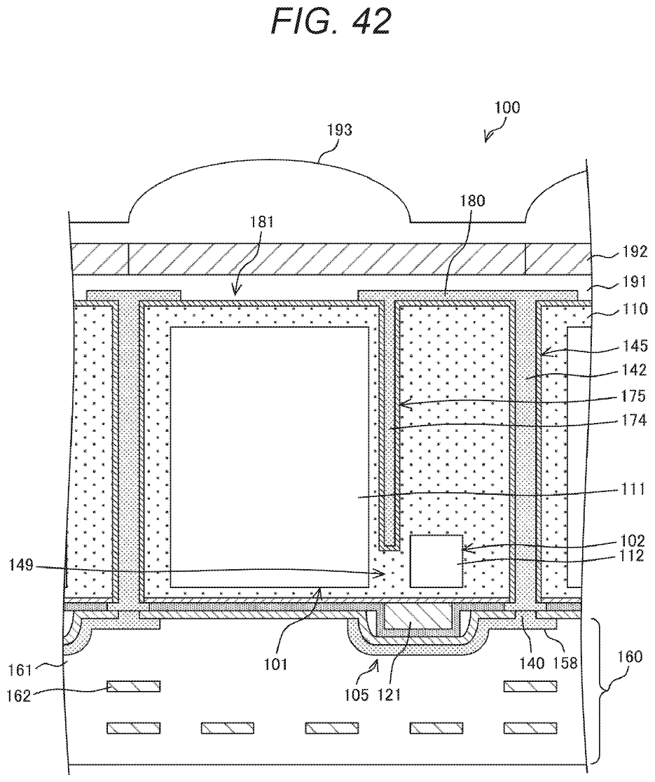

FIG. 42 is a cross-sectional view illustrating a configuration example of the pixel according to the eleventh embodiment of the present disclosure. The drawing is the cross-sectional view taken along line a-a′ in FIG. 41, and is a schematic cross-sectional view illustrating a configuration example of the pixel 100 similarly to FIG. 21. As described above, the pixel 100 is different from the pixel 100 in FIG. 21 in that the front surface insulating film light shielding unit 140 and the semiconductor substrate light shielding unit 142 are arranged in place of the front surface side light shielding unit 150 and the back surface side light shielding unit 170 at the boundary between the pixels 100.

Note that, in the semiconductor substrate 110 in the vicinity of a channel region of a MOS transistor 105, a non-penetrating back surface side light shielding unit 174 is arranged, and an opening 149 is formed. The non-penetrating back surface side light shielding unit 174 in the drawing illustrates an example of being formed to have a narrower cross-sectional width than that of the semiconductor substrate light shielding unit 142 (first semiconductor substrate light shielding unit 143).

Since a cross-sectional configuration of the pixel 100 other than this is similar to the cross-sectional configuration of the pixel 100 illustrated in FIG. 21, the description thereof is omitted.

[Manufacturing Method of Imaging Element]

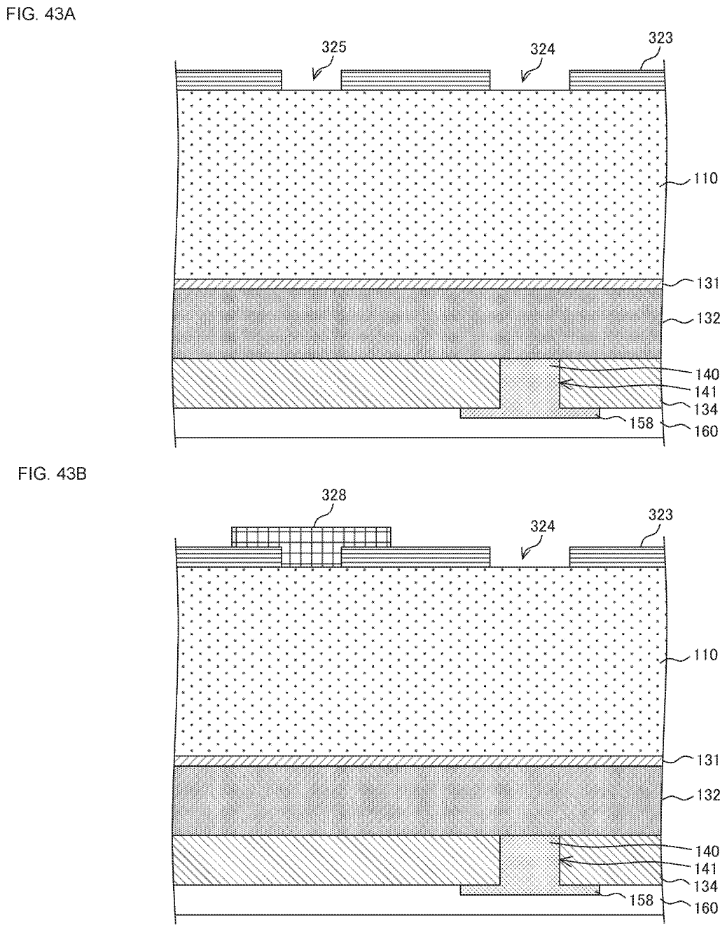

FIGS. 43 to 47 are diagrams illustrating an example of a manufacturing method of the imaging element according to the eleventh embodiment of the present disclosure. FIGS. 43 to 47 are diagrams illustrating an example of manufacturing steps of the pixel 100 portion of the imaging element 1. For the sake of convenience, the illustration of the semiconductor region 111 and the like is omitted.

First, insulating films 131, 132, and 134, the front surface insulating film light shielding unit 140, the in-pixel front surface insulating film light shielding unit 240 (not illustrated), a light shielding film 158, and a wiring region 160 are formed on the front surface side of the semiconductor substrate 110 by applying the steps illustrated in FIGS. 31 to 33. Next, the semiconductor substrate 110 is inverted upside down, and a back surface side thereof is ground to thin the semiconductor substrate 110. Next, a hard mask 323 is arranged on the back surface side of the semiconductor substrate 110. The hard mask 323 may include, for example, SiO₂. Furthermore, on the hard mask 323, openings 324 and 325 are arranged in regions where a penetrating groove 145 and a groove 175 are formed, respectively. As illustrated in the drawing, the opening 325 is formed to have a narrower width than that of the opening 324 (A of FIG. 43).

Next, a resist 328 having a shape to cover the region where the non-penetrating back surface side light shielding unit 174 is arranged of the hard mask 323 is arranged (B of FIG. 43).

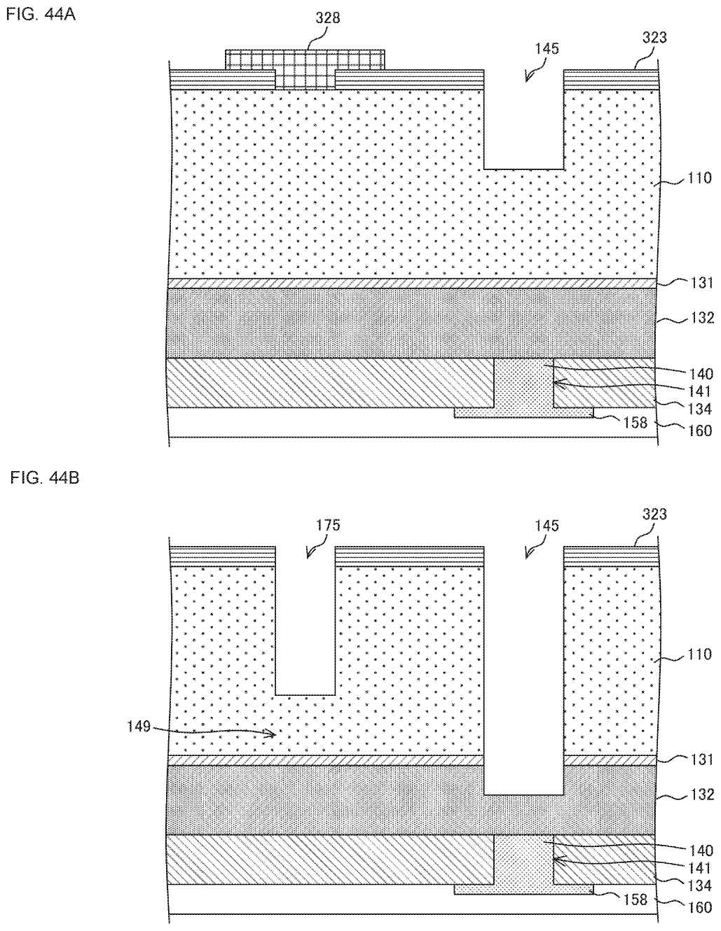

Next, the semiconductor substrate 110 adjacent to the opening 324 is etched using the hard mask 323 and the resist 328 as masks to form the penetrating groove 145 having a depth not to penetrate the semiconductor substrate 110 (C of FIG. 44).

Next, the resist 328 is removed, and the back surface side of the semiconductor substrate 110 is further etched. Therefore, the penetrating groove 145 having a depth to penetrate the semiconductor substrate 110 and the insulating film 131 to reach the region of the insulating film 132, and the groove 175 having a depth not to penetrate the semiconductor substrate 110 are formed (D of FIG. 44). Note that, the penetrating groove 145 is also formed in a region where the in-pixel semiconductor substrate light shielding unit 242 is arranged.

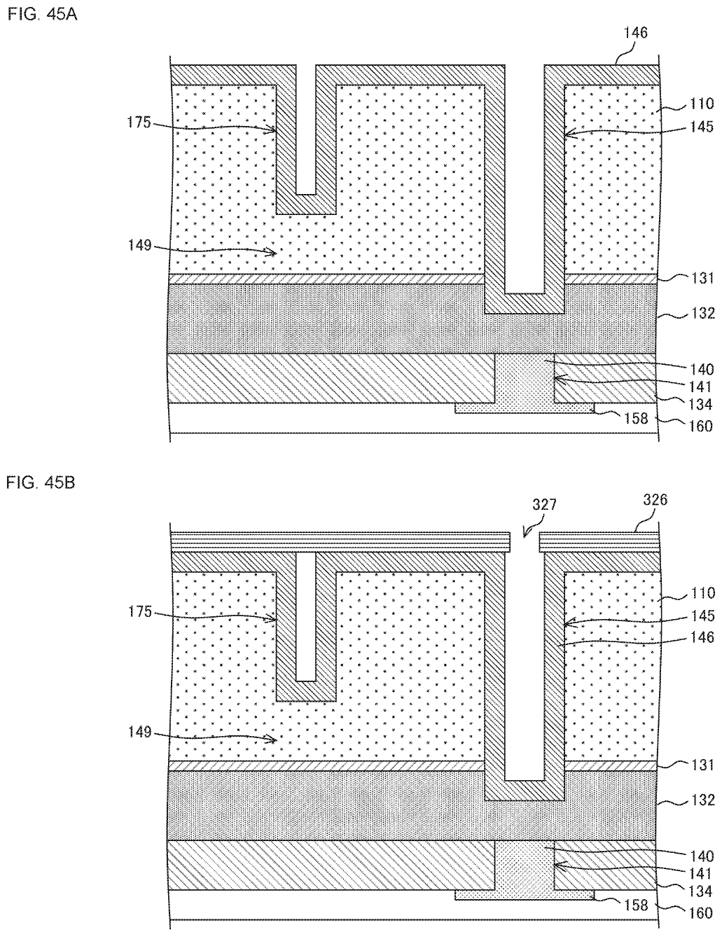

Next, the hard mask 323 is removed by applying the step described in E in FIG. 24. Next, an insulating film 146 is arranged on the back surface side of the semiconductor substrate 110 including the penetrating groove 145 and the groove 175 (E of FIG. 45).

Next, a protective film 326 is arranged on the back surface side of the semiconductor substrate 110. The protective film 326 is a film that protects the groove 175 and closes the opening of the groove 175. Note that, an opening 327 is arranged on the protective film 326 in the region where the penetrating groove 145 is arranged. The protective film 326 may include, for example, SiN. Furthermore, by applying a depositing method having a low step covering property to formation of the protective film 326, it is possible to close only the narrow groove 175. Sputtering may be applied to the depositing method, for example (F of FIG. 45).

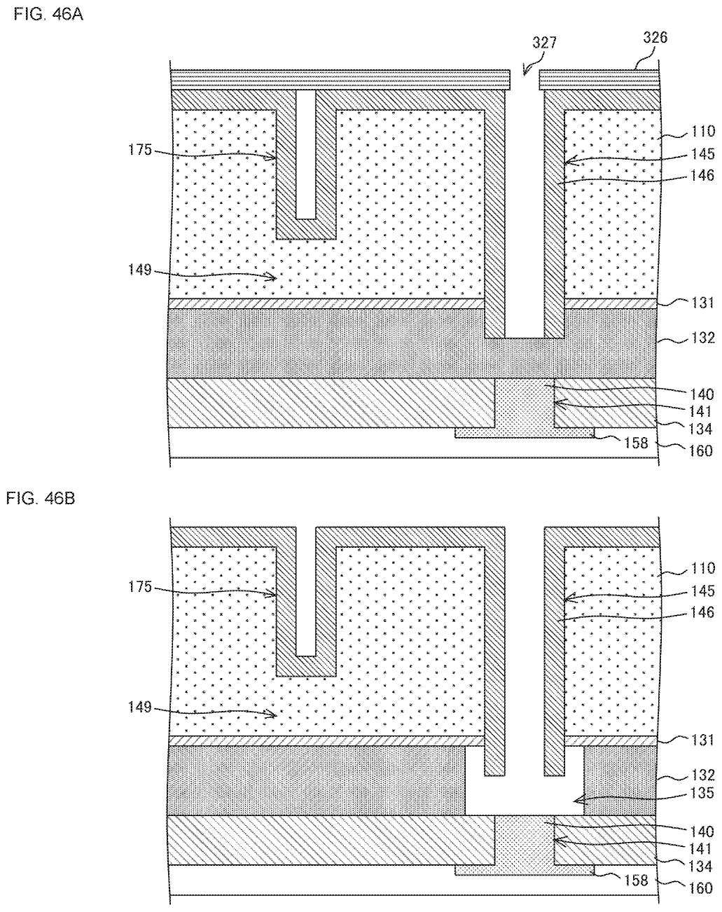

Next, dry etching is performed via the opening 327 of the protective film 326 to remove the insulating film 146 on a bottom surface of the penetrating groove 145 (G of FIG. 46).

Next, wet etching of the insulating film 132 is performed via the penetrating groove 145, and a lower layer insulating film removed region 135 is formed. At the time of the wet etching, the protective film 326 is also removed (H of FIG. 46).

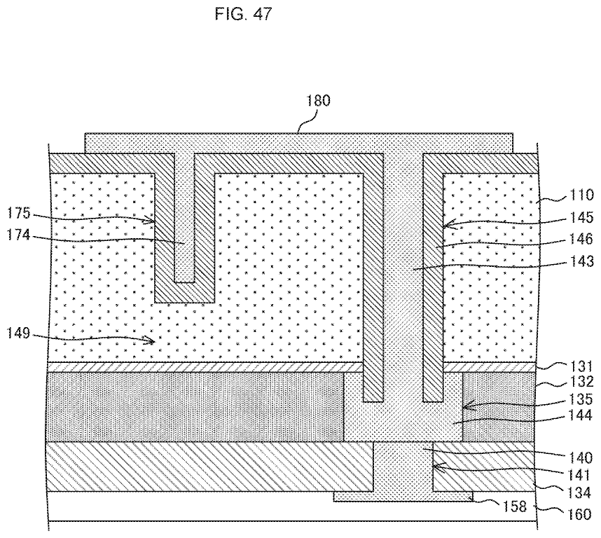

Next, a light shielding member is arranged on the back surface side of the semiconductor substrate 110 including the penetrating groove 145, the lower layer insulating film removed region 135, and the groove 175 to form the first semiconductor substrate light shielding unit 143, the second semiconductor substrate light shielding unit 144, and the non-penetrating back surface side light shielding unit 174. At that time, the in-pixel semiconductor substrate light shielding unit 242 (not illustrated) is also formed. Next, the light shielding member arranged on the back surface side of the semiconductor substrate 110 is processed to form a light shielding film 180 (I of FIG. 47).

By the above-described steps, the front surface insulating film light shielding unit 140, the in-pixel front surface insulating film light shielding unit 240, the semiconductor substrate light shielding unit 142, and the in-pixel semiconductor substrate light shielding unit 242 may be formed.

By making the cross-sectional width of the non-penetrating back surface side light shielding unit 174 narrower than the cross-sectional width of the semiconductor substrate light shielding unit 142, the groove 175 for arranging the non-penetrating back surface side light shielding unit 174 may be selectively closed when the protective film 326 is formed. Since the protective film 326 does not close the penetrating groove 145 in which the semiconductor substrate light shielding unit 142 is arranged, the step of etching the insulating film 146 on the bottom surface of the penetrating groove 145 may be simplified. Furthermore, by using the protective film 326 including the same member as that of the insulating film 132, the protective film 326 may be removed when etching the insulating film 132, and the manufacturing step may be further simplified.

Since a configuration of the imaging element 1 other than this is similar to the configuration of the imaging element 1 described in the ninth embodiment of the present disclosure, the description thereof is omitted.

As described above, the imaging element 1 of the eleventh embodiment of the present disclosure is provided with the pixel 100 adopting the global shutter type. By arranging the front surface insulating film light shielding unit 140 and the semiconductor substrate light shielding unit 142 at the boundary between the pixels 100, it is possible to reduce crosstalk caused by the adjacent pixel 100. Furthermore, by arranging the in-pixel front surface insulating film light shielding unit 240 and the in-pixel semiconductor substrate light shielding unit 242 between the photoelectric conversion unit 101 and the second charge holding unit 102, it is possible to reduce light leakage to the second charge holding unit 102 and reduce noise of the image signal.

### 12. Twelfth Embodiment

The imaging element 1 of the eleventh embodiment described above uses the non-penetrating back surface side light shielding unit 174 having a cross-sectional width narrower than that of the semiconductor substrate light shielding unit 142. In contrast, an imaging element 1 of a twelfth embodiment of the present disclosure is different from that of the eleventh embodiment described above in using a non-penetrating back surface side light shielding unit 174 having substantially the same cross-sectional width as that of the semiconductor substrate light shielding unit 142.

[Cross-Sectional Configuration of Pixel]

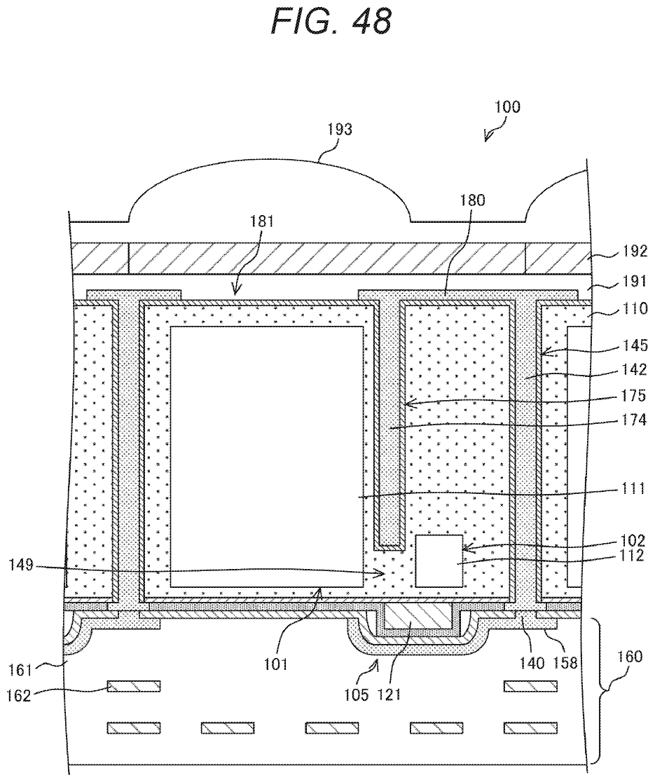

FIG. 48 is a cross-sectional view illustrating a configuration example of a pixel according to the twelfth embodiment of the present disclosure. Similarly to FIG. 42, the drawing is a schematic cross-sectional view illustrating a configuration example of a pixel 100. The pixel 100 is different from the pixel 100 in FIG. 42 in that a cross-sectional width of the non-penetrating back surface side light shielding unit 174 is substantially the same as a cross-sectional width of a semiconductor substrate light shielding unit 142.

Since the non-penetrating back surface side light shielding unit 174 in the drawing is formed to have substantially the same width as that of the semiconductor substrate light shielding unit 142, it is possible to improve light shielding ability of the non-penetrating back surface side light shielding unit 174 with respect to a second charge holding unit 102.

[Manufacturing Method of Imaging Element]

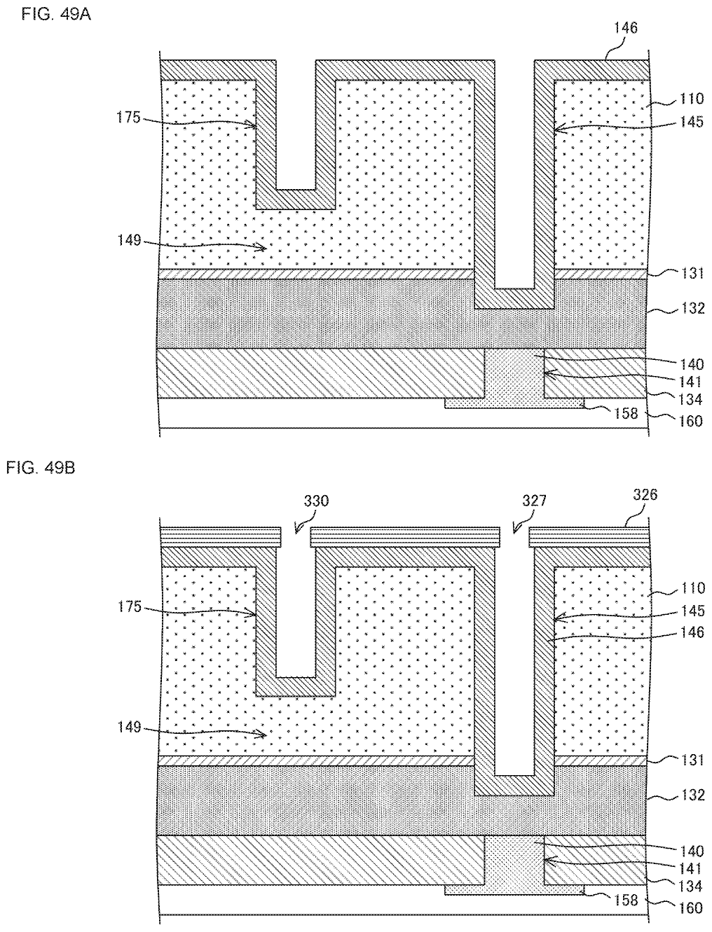

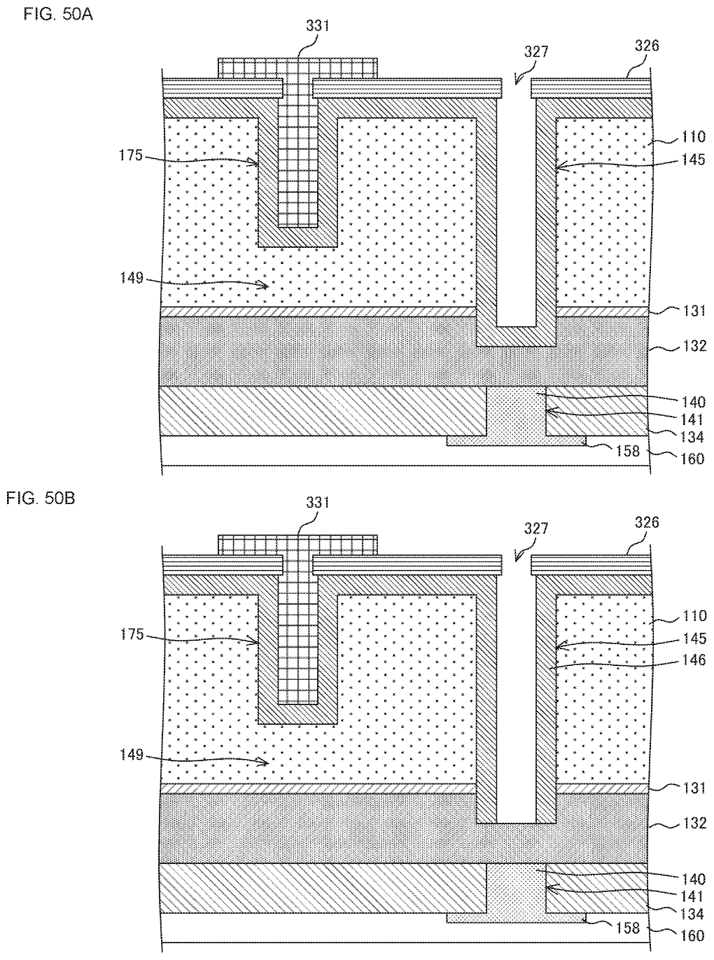

FIGS. 49 and 50 are diagrams illustrating an example of a manufacturing method of the imaging element according to the twelfth embodiment of the present disclosure. FIGS. 49 and 50 are diagrams illustrating an example of manufacturing steps of the pixel 100 portion of the imaging element 1. First, a penetrating groove 145 and a groove 175 are formed by applying steps from A of FIG. 43 to E of FIG. 45 and an insulating film 146 is arranged. At that time, in A of FIG. 43, an opening 325 of a hard mask 323 is formed to have the same width as that of an opening 324. Therefore, the groove 175 having substantially the same width as the that of the penetrating groove 145 illustrated in A of FIG. 49 may be formed (A of FIG. 49).

Next, a protective film 326 is arranged on the back surface side of the semiconductor substrate 110. An opening 330 is arranged on the protective film 326 in a region where the groove 175 is arranged. This is because, unlike the groove 175 illustrated in F of FIG. 45, the groove 175 of the drawing is formed to be wide (B of FIG. 49).

Next, a resist 331 having a shape to cover the region where the groove 175 is arranged on the back surface side of the semiconductor substrate 110 is arranged (C of FIG. 50).

Next, dry etching is performed via an opening 327 of the protective film 326 to remove the insulating film 146 on a bottom surface of the penetrating groove 145 (D of FIG. 46).

Thereafter, the resist 331 is removed, and steps subsequent to H of FIG. 46 are applied, so that the pixel 100 provided with the non-penetrating back surface side light shielding unit 174 having a cross-sectional width substantially the same as the cross-sectional width of the semiconductor substrate light shielding unit 142 may be formed.

Since a configuration of the imaging element 1 other than this is similar to the configuration of the imaging element 1 described in the eleventh embodiment of the present disclosure, the description thereof is omitted.

As described above, the imaging element 1 of the twelfth embodiment of the present disclosure is provided with the non-penetrating back surface side light shielding unit 174 having the cross-sectional width substantially the same as the cross-sectional width of the semiconductor substrate light shielding unit 142. Therefore, the light shielding ability with respect to the second charge holding unit 102 may be improved.

Note that, the configuration of the pixel 100 of the second embodiment may be combined with other embodiments. Specifically, the front surface side light shielding units 150 and 153 and the back surface side light shielding unit 170 in FIGS. 10 and 11 may be applied to the pixel 100 in FIG. 21.

Furthermore, the configuration of the pixel 100 of the fourth embodiment may be combined with other embodiments. Specifically, the front surface side light shielding unit 150 and the back surface side light shielding unit 170 in FIG. 18 may be applied to the pixel 100 in FIG. 21.

Furthermore, the configuration of the pixel 100 of the tenth embodiment may be combined with other embodiments. Specifically, the etching suppression unit 136 in FIG. 37 may be applied to the pixel 100 in FIGS. 42 and 48.

### 13. Application Example to Camera

The technology according to the present disclosure (present technology) may be applied to various products. For example, the present technology may be implemented as an imaging element mounted on an imaging device such as a camera.

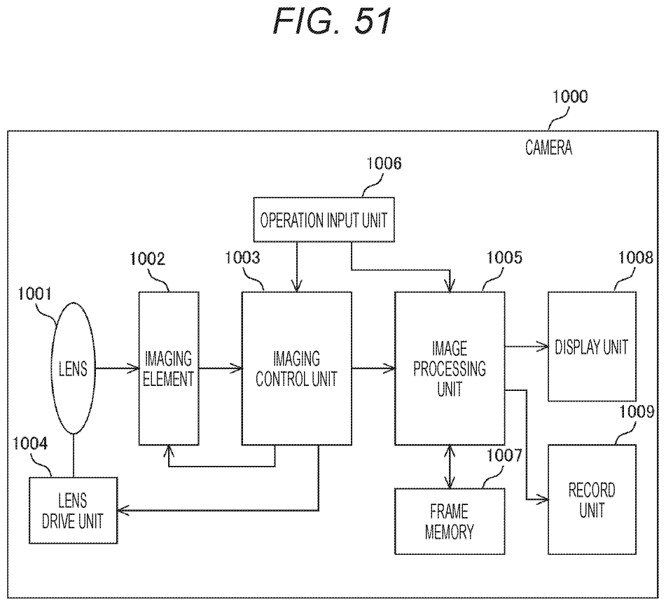

FIG. 51 is a block diagram illustrating a schematic configuration example of a camera, which is an example of an imaging device to which the present technology may be applied. A camera 1000 in the drawing is provided with a lens 1001, an imaging element 1002, an imaging control unit 1003, a lens drive unit 1004, an image processing unit 1005, an operation input unit 1006, a frame memory 1007, a display unit 1008, and a record unit 1009.

The lens 1001 is an imaging lens of the camera 1000. The lens 1001 condenses light from a subject and allows the same to be incident on the imaging element 1002 to be described later to form an image of the subject.

The imaging element 1002 is a semiconductor element that images the light from the subject condensed by the lens 1001. The imaging element 1002 generates an analog image signal corresponding to applied light and converts the same into a digital image signal to output.

The imaging control unit 1003 controls imaging by the imaging element 1002. The imaging control unit 1003 controls the imaging element 1002 by generating a control signal and outputting the same to the imaging element 1002. Furthermore, the imaging control unit 1003 may perform autofocus in the camera 1000 on the basis of the image signal output from the imaging element 1002. Here, the autofocus is a system that detects a focal position of the lens 1001 to automatically adjust. As the autofocus, a method of detecting the focal position by detecting an image plane phase difference by a phase difference pixel arranged in the imaging element 1002 (image plane phase difference autofocus) may be used. Furthermore, a method of detecting a position in which contrast of an image is the highest as the focal position (contrast autofocus) may also be applied. The imaging control unit 1003 adjusts a position of the lens 1001 via the lens drive unit 1004 on the basis of the detected focal position and performs the autofocus. Note that, the imaging control unit 1003 may include, for example, a digital signal processor (DSP) equipped with firmware.

The lens drive unit 1004 drives the lens 1001 on the basis of control of the imaging control unit 1003. The lens drive unit 1004 may drive the lens 1001 by changing the position of the lens 1001 using a built-in motor.

The image processing unit 1005 processes the image signal generated by the imaging element 1002. This processing includes, for example, demosaicing of generating an image signal of a lacking color among the image signals corresponding to red, green, and blue for each pixel, noise reduction of removing noise of the image signal, encoding of the image signal and the like. The image processing unit 1005 may include, for example, a microcomputer equipped with firmware.

The operation input unit 1006 receives an operation input from a user of the camera 1000. As the operation input unit 1006, for example, a push button or a touch panel may be used. The operation input received by the operation input unit 1006 is transmitted to the imaging control unit 1003 and the image processing unit 1005. Thereafter, processing according to the operation input, for example, processing such as imaging of the subject is started.

The frame memory 1007 is a memory that stores a frame, which is the image signal for one screen. The frame memory 1007 is controlled by the image processing unit 1005 and holds the frame in the course of the image processing.

The display unit 1008 displays an image processed by the image processing unit 1005. As the display unit 1008, for example, a liquid crystal panel may be used.

The record unit 1009 records the image processed by the image processing unit 1005. As the record unit 1009, for example, a memory card or a hard disk may be used.

The camera to which the present disclosure may be applied is described above. The present technology may be applied to the imaging element 1002 among the configurations described above. Specifically, the imaging element 1 illustrated in FIG. 1 may be applied to the imaging element 1002. By applying the imaging element 1 to the imaging element 1002, occurrence of crosstalk is reduced, and deterioration in image quality of the image generated by the camera 1000 may be prevented. Note that, the image processing unit 1005 is an example of a processing circuit. The camera 1000 is an example of the imaging device.

Note that, the camera is herein described as an example, but the technology according to the present disclosure may be applied to, for example, a monitoring device and the like in addition to this. Furthermore, the present disclosure may be applied to a semiconductor device in a form of a semiconductor module in addition to an electronic device such as a camera. Specifically, the technology according to the present disclosure may be applied to an imaging module, which is a semiconductor module in which the imaging element 1002 and the imaging control unit 1003 in FIG. 51 are enclosed in one package.

Finally, the description of each of the above-described embodiments is an example of the present disclosure, and the present disclosure is not limited to the above-described embodiments. For this reason, it goes without saying that various changes may be made according to a design and the like without departing from the technical idea according to the present disclosure in addition to the respective embodiments described above.

Furthermore, the effects described in this specification are illustrative only and are not limitative. Furthermore, there may also be another effect.

Furthermore, the drawings in the above-described embodiments are schematic, and dimensional ratios and the like of the respective units do not necessarily coincide with actual ones. Furthermore, it goes without saying that dimensional relationships and ratios are partly different between the drawings.

Note that, the present technology may also have a following configuration.

(1) An imaging element provided with:

a pixel provided with a photoelectric conversion unit that is arranged in a semiconductor substrate on a front surface side of which a wiring region is formed and performs photoelectric conversion of incident light applied from a back surface side of the semiconductor substrate;

a front surface side light shielding unit that is embedded on the front surface side of the semiconductor substrate at a boundary between pixels and shields the incident light; and

a back surface side light shielding unit that is embedded on the back surface side of the semiconductor substrate at the boundary between the pixels and is formed to have such a depth that a bottom of the back surface side light shielding unit is arranged between the front surface side of the semiconductor substrate and a bottom of the front surface side light shielding unit to shield the incident light.

(2) The imaging element according to (1) described above, in which

the front surface side light shielding unit is formed by arranging a light shielding member in a front surface side groove, which is a groove formed on the front surface side of the semiconductor substrate.

(3) The imaging element according to (2) described above, in which the light shielding member includes metal.

(4) The imaging element according to (2) or (3) described above, further provided with:

an insulating film arranged between the front surface side groove and the light shielding member.

(5) The imaging element according to any one of (2) to (4) described above, further provided with:

an insulating film including a silicon compound arranged on the front surface side of the semiconductor substrate, in which

the groove is formed to penetrate the insulating film.

(6) The imaging element according to any one of (1) to (5) described above, in which

the back surface side light shielding unit is formed into a shape to penetrate the semiconductor substrate.

(7) The imaging element according to any one of (1) to (6) described above, in which

the back surface side light shielding unit is formed by arranging a light shielding member in a back surface side groove, which is a groove formed on the back surface side of the semiconductor substrate.

(8) The imaging element according to (7) described above, in which

the light shielding member includes metal.

(9) The imaging element according to (7) described above, further provided with:

an insulating film arranged between the back surface side groove and the light shielding member.

(10) The imaging element according to (7) described above, in which

the back surface side groove is formed by performing wet etching on the back surface side of the semiconductor substrate.

(11) The imaging element according to (7) described above, in which

the back surface side groove is formed by etching a filling member arranged to penetrate the semiconductor substrate from the back surface side.

(12) The imaging element according to (11) described above, in which

the filling member includes polycrystalline silicon.

(13) The imaging element according to any one of (1) to (12) described above, in which

the back surface side light shielding unit is formed to have a wider cross-sectional width at the bottom than a cross-sectional width at the bottom of the front surface side light shielding unit.

(14) The imaging element according to (13) described above, in which

the back surface side light shielding unit includes a groove-shaped recess at the bottom, and

the front surface side light shielding unit is formed to have a shape in which the bottom of the front surface side light shielding unit is fitted into the recess.

(15) The imaging element according to any one of (1) to (12) described above, provided with:

two front surface side light shielding units, in which

the back surface side light shielding unit is arranged between the two front surface side light shielding units.

(16) The imaging element according to any one of (1) to (15) described above, further provided with:

a holding unit that holds a charge generated by the photoelectric conversion;

an in-pixel front surface side light shielding unit that is embedded on the front surface side of the semiconductor substrate at a boundary between the photoelectric conversion unit and the holding unit and shields the incident light; and

an in-pixel back surface side light shielding unit that is embedded on the back surface side of the semiconductor substrate at the boundary between the photoelectric conversion unit and the holding unit and is formed to have such a depth that a bottom of the in-pixel back surface side light shielding unit is arranged between the front surface side of the semiconductor substrate and a bottom of the in-pixel front surface side light shielding unit to shield the incident light.

(17) An imaging element provided with:

a pixel provided with a photoelectric conversion unit that is arranged in a semiconductor substrate on a front surface side of which a wiring region is formed and performs photoelectric conversion of incident light applied from a back surface side of the semiconductor substrate;

a front surface side light shielding unit that is embedded on the front surface side of the semiconductor substrate at a boundary between pixels and shields the incident light; and

a back surface side light shielding unit that is embedded on the back surface side of the semiconductor substrate at the boundary between the pixels and is formed to have a depth in contact with a bottom of the front surface side light shielding unit to shield the incident light.

(18) The imaging element according to (17) described above, in which

the back surface side light shielding unit is in contact with the bottom of the front surface side light shielding unit via an insulating film.

(19) An imaging element provided with:

a pixel provided with a photoelectric conversion unit that is arranged in a semiconductor substrate on a front surface side of which a wiring region is formed and performs photoelectric conversion of incident light applied from a back surface side of the semiconductor substrate;

a front surface insulating film, which is an insulating film arranged between the semiconductor substrate and the wiring region;

a front surface insulating film light shielding unit that is arranged on the front surface insulating film at a boundary between pixels and shields the incident light; and

a semiconductor substrate light shielding unit that penetrates the semiconductor substrate at the boundary between the pixels and is formed into a shape in contact with a bottom of the front surface insulating film light shielding unit to shield the incident light.

(20) The imaging element according to (19) described above, further provided with:

a lower layer insulating film, which is an insulating film arranged between the semiconductor substrate and the front surface insulating film, in which

the semiconductor substrate light shielding unit is provided with a first semiconductor substrate light shielding unit arranged in a penetrating groove formed in the semiconductor substrate, and a second semiconductor substrate light shielding unit arranged in a lower layer insulating film removed region formed by removing the lower layer insulating film in a vicinity of a bottom of the penetrating groove.

(21) The imaging element according to (20) described above, in which

the first semiconductor substrate light shielding unit is obtained by arranging a light shielding member in the penetrating groove, and

the second semiconductor substrate light shielding unit is obtained by arranging a light shielding member in the lower layer insulating film removed region.

(22) The imaging element according to (20) or (21) described above, in which

the lower layer insulating film removed region is formed by removing the lower layer insulating film by etching via the penetrating groove.

(23) The imaging element according to (22) described above, further provided with:

an etching suppression unit that is arranged on the lower layer insulating film and suppresses the etching.

(24) The imaging element according to (23) described above, in which

the etching suppression unit includes a same member as a member of the front surface insulating film.

(25) The imaging element according to any one of (20) to (24) described above, in which

the lower layer insulating film includes a silicon compound.

(26) The imaging element according to any one of (20) to (25), in which

the second semiconductor substrate light shielding unit is formed to have a wider cross-sectional width than a cross-sectional width of the penetrating groove.

(27) The imaging element according to any one of (20) to (26) described above, further provided with:

an insulating film arranged between the penetrating groove and the light shielding member.

(28) The imaging element according to (27) described above, in which

the second semiconductor substrate light shielding unit is formed to have a wider cross-sectional width than a cross-sectional width of the penetrating groove, and

the insulating film is formed into such a shape that a bottom of the insulating film is fitted into a recess formed in the second semiconductor substrate light shielding unit.

(29) The imaging element according to any one of (19) to (28) described above, further provided with:

a holding unit that holds a charge generated by the photoelectric conversion;

an in-pixel front surface insulating film light shielding unit that is arranged on the front surface insulating film at a boundary between the photoelectric conversion unit and the holding unit and shields the incident light; and

an in-pixel semiconductor substrate light shielding unit that penetrates the semiconductor substrate at the boundary between the photoelectric conversion unit and the holding unit and is formed into a shape in contact with a bottom of the in-pixel front surface insulating film light shielding unit to shield the incident light.

(30) The imaging element according to (29) described above, in which

the in-pixel semiconductor substrate light shielding unit is formed to have a cross section narrower in width than a cross section of the semiconductor substrate light shielding unit.

(31) An imaging device provided with:

a pixel provided with a photoelectric conversion unit that is arranged in a semiconductor substrate on a front surface side of which a wiring region is formed and performs photoelectric conversion of incident light applied from a back surface side of the semiconductor substrate;

a front surface side light shielding unit that is embedded on the front surface side of the semiconductor substrate at a boundary between pixels and shields the incident light;

a back surface side light shielding unit that is embedded on the back surface side of the semiconductor substrate at the boundary between the pixels and is formed to have such a depth that a bottom of the back surface side light shielding unit is arranged between the front surface side of the semiconductor substrate and a bottom of the front surface side light shielding unit to shield the incident light; and

a processing circuit that processes an image signal generated on the basis of the photoelectric conversion.

(32) An imaging device provided with:

a pixel provided with a photoelectric conversion unit that is arranged in a semiconductor substrate on a front surface side of which a wiring region is formed and performs photoelectric conversion of incident light applied from a back surface side of the semiconductor substrate;

a front surface insulating film, which is an insulating film arranged between the semiconductor substrate and the wiring region;

a front surface insulating film light shielding unit that is arranged on the front surface insulating film at a boundary between pixels and shields the incident light;

a semiconductor substrate light shielding unit that is formed into a shape to penetrate the semiconductor substrate at the boundary between the pixels and in contact with a bottom of the front surface insulating film light shielding unit to shield the incident light; and

a processing circuit that processes an image signal generated on the basis of the photoelectric conversion.

(33) A manufacturing method of an imaging element provided with:

a front surface side light shielding unit forming step of forming a front surface side light shielding unit that is embedded on a front surface side of a semiconductor substrate at a boundary between pixels each provided with a photoelectric conversion unit that is arranged in the semiconductor substrate on the front surface side of which a wiring region is formed and performs photoelectric conversion of incident light applied from a back surface side of the semiconductor substrate to shield the incident light; and

a back surface side light shielding unit forming step of forming a back surface side light shielding unit that is embedded on the back surface side of the semiconductor substrate at the boundary between the pixels to shield the incident light to have such a depth that a bottom of the back surface side light shielding unit is arranged between the front surface side of the semiconductor substrate and a bottom of the front surface side light shielding unit.

(34) A manufacturing method of an imaging element provided with:

a front surface insulating film light shielding unit forming step of forming a front surface insulating film light shielding unit arranged on the front surface insulating film at a boundary between pixels each provided with a photoelectric conversion unit that is arranged in a semiconductor substrate on a front surface side of which a front surface insulating film and a wiring region are sequentially formed and performs photoelectric conversion of incident light applied from a back surface side of the semiconductor substrate; and

a semiconductor substrate light shielding unit forming step of forming a semiconductor substrate light shielding unit that is formed into a shape to penetrate the semiconductor substrate at the boundary between the pixels and in contact with a bottom of the front surface insulating film light shielding unit to shield the incident light.

### REFERENCE SIGNS LIST

1, 1002 Imaging element
10 Pixel array unit
30 Column signal processing unit
100 Pixel
101 Photoelectric conversion unit
102 Second charge holding unit
103 Charge holding unit
110 Semiconductor substrate
118 Filling member
119 Solid phase diffusion layer
131, 132, 134, 146, 152, 172 Insulating film
135 Lower layer insulating film removed region
136, 136a, 136b Etching suppression unit
140 Front surface insulating film light shielding unit
141, 157 Groove
142 Semiconductor substrate light shielding unit
143 First semiconductor substrate light shielding unit
144 Second semiconductor substrate light shielding unit
145 Penetrating groove
147, 279 Recess
150, 153 Front surface side light shielding unit
151, 154 Front surface side groove
158, 180 Light shielding film
160 Wiring region
170 Back surface side light shielding unit
171 Back surface side groove
240 In-pixel front surface insulating film light shielding unit
242 In-pixel semiconductor substrate light shielding unit
250 In-pixel front surface side light shielding unit
270 In-pixel back surface side light shielding unit
1000 Camera
1005 Image processing unit

1. An imaging element comprising:
a pixel provided with a photoelectric conversion unit that is arranged in a semiconductor substrate on a front surface side of which a wiring region is formed and performs photoelectric conversion of incident light applied from a back surface side of the semiconductor substrate;
a front surface side light shielding unit that is embedded on the front surface side of the semiconductor substrate at a boundary between pixels and shields the incident light; and
a back surface side light shielding unit that is embedded on the back surface side of the semiconductor substrate at the boundary between the pixels and is formed to have such a depth that a bottom of the back surface side light shielding unit is arranged between the front surface side of the semiconductor substrate and a bottom of the front surface side light shielding unit to shield the incident light.

2. The imaging element according to claim 1, wherein
the front surface side light shielding unit is formed by arranging a light shielding member in a front surface side groove, which is a groove formed on the front surface side of the semiconductor substrate.

3. The imaging element according to claim 2, wherein
the light shielding member includes metal.

4. The imaging element according to claim 2, further comprising:
an insulating film arranged between the front surface side groove and the light shielding member.

5. The imaging element according to claim 2, further comprising:
an insulating film including a silicon compound arranged on the front surface side of the semiconductor substrate, wherein
the groove is formed to penetrate the insulating film.

6. The imaging element according to claim 1, wherein
the back surface side light shielding unit is formed into a shape to penetrate the semiconductor substrate.

7. The imaging element according to claim 1, wherein
the back surface side light shielding unit is formed by arranging a light shielding member in a back surface side groove, which is a groove formed on the back surface side of the semiconductor substrate.

8. The imaging element according to claim 7, wherein
the light shielding member includes metal.

9. The imaging element according to claim 7, further comprising:
an insulating film arranged between the back surface side groove and the light shielding member.

10. The imaging element according to claim 9, wherein
the back surface side groove is formed by performing wet etching on the back surface side of the semiconductor substrate.

11. The imaging element according to claim 7, wherein
the back surface side groove is formed by etching a filling member arranged to penetrate the semiconductor substrate from the back surface side.

12. The imaging element according to claim 11, wherein
the filling member includes polycrystalline silicon.

13. The imaging element according to claim 1, wherein
the back surface side light shielding unit is formed to have a wider cross-sectional width at the bottom than a cross-sectional width at the bottom of the front surface side light shielding unit.

14. The imaging element according to claim 13, wherein
the back surface side light shielding unit includes a groove-shaped recess at the bottom, and
the front surface side light shielding unit is formed to have a shape in which the bottom of the front surface side light shielding unit is fitted into the recess.

15. The imaging element according to claim 1, comprising:
two front surface side light shielding units, wherein
the back surface side light shielding unit is arranged between the two front surface side light shielding units.

16. The imaging element according to claim 1, further comprising:
a holding unit that holds a charge generated by the photoelectric conversion;
an in-pixel front surface side light shielding unit that is embedded on the front surface side of the semiconductor substrate at a boundary between the photoelectric conversion unit and the holding unit and shields the incident light; and
an in-pixel back surface side light shielding unit that is embedded on the back surface side of the semiconductor substrate at the boundary between the photoelectric conversion unit and the holding unit and is formed to have such a depth that a bottom of the in-pixel back surface side light shielding unit is arranged between the front surface side of the semiconductor substrate and a bottom of the in-pixel front surface side light shielding unit to shield the incident light.

17. An imaging element comprising:
a pixel provided with a photoelectric conversion unit that is arranged in a semiconductor substrate on a front surface side of which a wiring region is formed and performs photoelectric conversion of incident light applied from a back surface side of the semiconductor substrate;
a front surface side light shielding unit that is embedded on the front surface side of the semiconductor substrate at a boundary between pixels and shields the incident light; and
a back surface side light shielding unit that is embedded on the back surface side of the semiconductor substrate at the boundary between the pixels and is formed to have a depth in contact with a bottom of the front surface side light shielding unit to shield the incident light.

18. The imaging element according to claim 17, wherein
the back surface side light shielding unit is in contact with the bottom of the front surface side light shielding unit via an insulating film.

19. An imaging element comprising:
a pixel provided with a photoelectric conversion unit that is arranged in a semiconductor substrate on a front surface side of which a wiring region is formed and performs photoelectric conversion of incident light applied from a back surface side of the semiconductor substrate;
a front surface insulating film, which is an insulating film arranged between the semiconductor substrate and the wiring region;
a front surface insulating film light shielding unit that is arranged on the front surface insulating film at a boundary between pixels and shields the incident light; and
a semiconductor substrate light shielding unit that is formed into a shape to penetrate the semiconductor substrate at the boundary between the pixels and in contact with a bottom of the front surface insulating film light shielding unit to shield the incident light.

20. The imaging element according to claim 19, further comprising:
a lower layer insulating film, which is an insulating film arranged between the semiconductor substrate and the front surface insulating film, wherein
the semiconductor substrate light shielding unit is provided with a first semiconductor substrate light shielding unit arranged in a penetrating groove formed in the semiconductor substrate, and a second semiconductor substrate light shielding unit arranged in a lower layer insulating film removed region formed by removing the lower layer insulating film in a vicinity of a bottom of the penetrating groove.

21. The imaging element according to claim 20, wherein
the first semiconductor substrate light shielding unit is obtained by arranging a light shielding member in the penetrating groove, and
the second semiconductor substrate light shielding unit is obtained by arranging a light shielding member in the lower layer insulating film removed region.

22. The imaging element according to claim 20, wherein
the lower layer insulating film removed region is formed by removing the lower layer insulating film by etching via the penetrating groove.

23. The imaging element according to claim 22, further comprising:
an etching suppression unit that is arranged on the lower layer insulating film and suppresses the etching.

24. The imaging element according to claim 23, wherein
the etching suppression unit includes a same member as a member of the front surface insulating film.

25. The imaging element according to claim 20, wherein
the lower layer insulating film includes a silicon compound.

26. The imaging element according to claim 20, wherein
the second semiconductor substrate light shielding unit is formed to have a wider cross-sectional width than a cross-sectional width of the penetrating groove.

27. The imaging element according to claim 20, further comprising:
an insulating film arranged between the penetrating groove and the light shielding member.

28. The imaging element according to claim 27, wherein
the second semiconductor substrate light shielding unit is formed to have a wider cross-sectional width than a cross-sectional width of the penetrating groove, and
the insulating film is formed into such a shape that a bottom of the insulating film is fitted into a recess formed in the second semiconductor substrate light shielding unit.

29. The imaging element according to claim 19, further comprising:
a holding unit that holds a charge generated by the photoelectric conversion;
an in-pixel front surface insulating film light shielding unit that is arranged on the front surface insulating film at a boundary between the photoelectric conversion unit and the holding unit and shields the incident light; and
an in-pixel semiconductor substrate light shielding unit that is formed into a shape to penetrate the semiconductor substrate at the boundary between the photoelectric conversion unit and the holding unit and in contact with a bottom of the in-pixel front surface insulating film light shielding unit to shield the incident light.

30. The imaging element according to claim 29, wherein
the in-pixel semiconductor substrate light shielding unit is formed to have a cross section narrower in width than a cross section of the semiconductor substrate light shielding unit.
